(19) United States
(12) Patent Application Publication
(10) Pub. No.: US 2023/0284518 A1
(43) Pub. Date: Sep. 7, 2023

(54) ORGANIC LIGHT-EMITTING DEVICE

(71) Applicants: Samsung Electronics Co., Ltd., Suwon-si (KR); Samsung SDI Co., Ltd., Yongin-si (KR); Ewha University-Industry Collaboration Foundation, Seoul (KR)

(72) Inventors: Sooghang IHN, Hwaseong-si (KR); Youngmin YOU, Seoul (KR); Changho NOH, Suwon-si (KR); Jongsoo KIM, Suwon-si (KR); Joonghyuk KIM, Seoul (KR); Namheon LEE, Suwon-si (KR)

(21) Appl. No.: 18/175,064

(22) Filed: Feb. 27, 2023

Related U.S. Application Data
(63) Continuation of application No. 15/871,430, filed on Jan. 15, 2018, now Pat. No. 11,594,689.

(30) Foreign Application Priority Data
Jan. 16, 2017 (KR) 10-2017-0007033
Jan. 11, 2018 (KR) 10-2018-0003976

(51) Int. Cl. H10K 85/30; H10K 50/11; H10K 85/60

(52) U.S. Cl. CPC H10K 85/342; H10K 50/11; H10K 85/654; H10K 85/657; H10K 85/6572; H10K 85/346; H10K 2101/10

(57) ABSTRACT

An organic light-emitting device including a first electrode, a second electrode facing the first electrode, and an organic layer disposed between the first electrode and the second electrode, wherein the organic layer includes an emission layer, wherein the emission layer includes a host and a dopant, and wherein the organic light-emitting device satisfies predetermined conditions described in the specification.

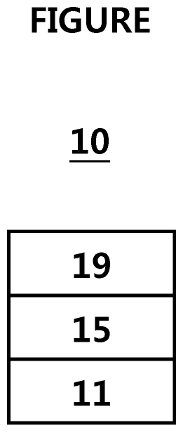

### CROSS-REFERENCE TO RELATED APPLICATION

This application is continuation of U.S. application Ser. No. 15/871,430, filed Jan. 15, 2018, which claims priority to Korean Patent Application No. 10-2017-0007033, filed on Jan. 16, 2017, and Korean Patent Application No. 10-2018-0003976, filed on Jan. 11, 2018, in the Korean Intellectual Property Office, and all the benefits accruing therefrom under 35 U.S.C. § 119, the contents of which are incorporated herein in their entirety by reference.

### BACKGROUND

### 1. Field

The present disclosure relates to an organic light-emitting device.

### 2. Description of the Related Art

Organic light-emitting devices (OLEDs) are self-emission devices that have wide viewing angles, high contrast ratios, short response times, and excellent brightness, driving voltage, and response speed characteristics, and that produce full-color images.

A typical OLED includes an anode, a cathode, and an organic layer disposed between the anode and the cathode, wherein the organic layer includes an emission layer. A hole transport region may be disposed between the anode and the emission layer, and an electron transport region may be disposed between the emission layer and the cathode. Holes provided from the anode may move toward the emission layer through the hole transport region, and electrons provided from the cathode may move toward the emission layer through the electron transport region. Carriers, such as holes and electrons, recombine in the emission layer to produce excitons. These excitons transit from an excited state to a ground state, thereby generating light.

Various types of organic light emitting devices are known. However, there still remains a need in OLEDs having low driving voltage, high efficiency, high brightness, and long lifespan.

### SUMMARY

Provided is an organic light-emitting device including a host and a dopant satisfying predetermined conditions so as to have long lifespan.

Additional aspects will be set forth in part in the description which follows and, in part, will be apparent from the description, or may be learned by practice of the presented embodiments.

According to an aspect of an embodiment, an organic light-emitting device includes:
a first electrode;
a second electrode facing the first electrode; and
an organic layer disposed between the first electrode and the second electrode, wherein the organic layer includes an emission layer,
wherein the emission layer includes a host and a dopant,
1) the dopant includes a phosphorescent dopant, and
i) Conditions 1, 2, 3, and 4 are all satisfied;
ii) when Conditions 1 and 4 are satisfied and at least one of Conditions 2 and 3 is not satisfied, Condition 5-1 is satisfied;
iii) when at least one of Conditions 1 and 4 are not satisfied and Conditions 2 and 3 are satisfied, Condition 6-1 is satisfied; or
iv) when at least one of Conditions 1 and 4 is not satisfied and at least one of Conditions 2 and 3 is not satisfied, Conditions 5-1 and 6-1 are both satisfied, or
2) the dopant includes a fluorescent dopant, and
i) Conditions 1, 2, 3, and 4 are all satisfied;
ii) when Conditions 1 and 4 are satisfied and at least one of Conditions 2 and 3 is not satisfied, Condition 5-2 is satisfied;
iii) when at least one of Conditions 1 and 4 is not satisfied and Conditions 2 and 3 are satisfied, Condition 6-2 is satisfied; or
iv) when at least one of Conditions 1 and 4 is not satisfied and at least one of Conditions 2 and 3 is not satisfied, Conditions 5-2 and 6-2 are both satisfied:

E*_{ox,dopant}≥E_{red,host} Condition 1

E*_{red,dopant}≤E_{ox,host} Condition 2

E_{ox,dopant}≥E*_{red,host} Condition 3

E_{red,dopant}≤E*_{ox,host} Condition 4

T1_{dopant}−0.4 eV<|E_{red,host}−E_{ox,dopant}|<T1_{dopant}+0.3 eV Condition 5-1

T1_{dopant}−0.4 eV<|E_{red,dopant}−E_{ox,host}|<T1_{dopant}+0.3 eV Condition 6-1

S1_{dopant}−0.4 eV<|E_{red,host}−E_{ox,dopant}|<S1_{dopant}+0.3 eV Condition 5-2

S1_{dopant}−0.4 eV<|E_{red,dopant}−E_{ox,host}|<S1_{dopant}+0.3 eV Condition 6-2
wherein, “E*_{ox,dopant}” represents an excited-state oxidation potential (electron volts, eV) of the dopant,
“E*_{red,dopant}” represents an excited-state reduction potential (eV) of the dopant,
“E_{ox,dopant}” represents a ground-state oxidation potential (eV) of the dopant,
“E_{red,dopant}” represents a ground-state reduction potential (eV) of the dopant,
“E*_{red,host}” represents an excited-state reduction potential (eV) of the host,
“E*_{ox,host}” represents an excited-state oxidation potential (eV) of the host,
“E_{red,host}” represents a ground-state reduction potential (eV) of the host,
“E_{ox,host}” represents a ground-state oxidation potential (eV) of the host,
E*_{ox,dopant} is identical to E_{ox,dopant}−T1_{dopant},
E*_{red,dopant} is identical to E_{red,dopant}+T1_{dopant},
E*_{ox,host} is identical to E_{ox,host}−S1ₕₒₛₜ,
E*_{red,host} is identical to E_{red,host}+S1ₕₒₛₜ,
“T1_{dopant}” represents the lowest triplet energy level (eV) of the dopant,
“S1_{dopant}” represents the lowest singlet energy level (eV) of the dopant,
“S1ₕₒₛₜ” represents the lowest singlet energy level (eV) of the host,
E_{ox,dopant} and E_{ox,host} are measured by using cyclic voltammetry (CV),
E_{red,dopant} and E_{red,host} are measured by using differential pulse voltammetry,
T1_{dopant} and S1_{dopant} are calculated from a photoluminescence (PL) spectrum of the dopant in solution, and
S1ₕₒₛₜ is calculated from a PL spectrum of the host in solution,
wherein “eV” denotes “electron volts”.

### BRIEF DESCRIPTION OF THE DRAWING

These and/or other aspects will become apparent and more readily appreciated from the following description of the embodiments, taken in conjunction with the FIGURE which is a schematic cross-sectional view of an organic light-emitting device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present disclosure. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly in contact with the other element or intervening elements may be present therebetween. In contrast, when an element is referred to as being “directly on” another element, there are no intervening elements present.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise.

The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

In an embodiment, an organic light-emitting device is provided. The organic light-emitting device may include:
a first electrode;
a second electrode facing the first electrode; and
an organic layer disposed between the first electrode and the second electrode,
wherein the organic layer includes an emission layer, and
wherein the emission layer may include a host and a dopant.

In an embodiment, the dopant may include a phosphorescent dopant. In some embodiments, the dopant may be a phosphorescent dopant.

In the organic light-emitting device in which the dopant includes a phosphorescent dopant,
i) Conditions 1, 2, 3, and 4 may all be satisfied;
ii) when Conditions 1 and 4 may be satisfied and at least one of Conditions 2 and 3 is not satisfied, Condition 5-1 may be satisfied;
iii) when at least one of Conditions 1 and 4 may not be satisfied and Conditions 2 and 3 are satisfied, Condition 6-1 may be satisfied; or
iv) when at least one of Conditions 1 and 4 may not be satisfied and at least one of Conditions 2 and 3 is not satisfied, Conditions 5-1 and 6-1 may both be satisfied.

In one or more embodiments, the dopant may include a fluorescent dopant. In some embodiments, the dopant may be a fluorescent dopant.

In the organic light-emitting device in which the dopant includes a fluorescent dopant,
i) Conditions 1, 2, 3, and 4 may all be satisfied;
ii) when Conditions 1 and 4 may be satisfied and at least one of Conditions 2 and 3 is not satisfied, Condition 5-2 may be satisfied;
iii) when at least one of Conditions 1 and 4 may not be satisfied and Conditions 2 and 3 are satisfied, Condition 6-2 may be satisfied, or
iv) when at least one of Conditions 1 and 4 may not be satisfied and at least one of Conditions 2 and 3 is not satisfied, Conditions 5-2 and 6-2 may both be satisfied.

E*_{ox,dopant}≥E_{red,host} Condition 1

E*_{red,dopant}≤E_{ox,host} Condition 2

E_{ox,dopant}≥E*_{red,host} Condition 3

E_{red,dopant}≤E*_{ox,host} Condition 4

T1_{dopant}−0.4 eV<|E_{red,host}−E_{ox,dopant}|<T1_{dopant}+0.3 eV

(for example, T1_{dopant}−0.3 eV<|E_{red,host}−E_{ox,dopant}|<T1_{dopant}+0.3 eV) Condition 5-1

T1_{dopant}−0.4 eV<|E_{red,dopant}−E_{ox,host}|<T1_{dopant}+0.3 eV

(for example, T1_{dopant}−0.3 eV<|E_{red,dopant}−E_{ox,host}|<T1_{dopant}+0.3 eV) Condition 6-1

S1_{dopant}−0.4 eV<|E_{red,host}−E_{ox,dopant}|<S1_{dopant}+0.3 eV

(for example, S1_{dopant}−0.3 eV<|E_{red,host}−E_{ox,dopant}|<S1_{dopant}+0.3 eV) Condition 5-2

S1_{dopant}−0.4 eV<|E_{red,dopant}−E_{ox,host}|<S1_{dopant}+0.3 eV

(for example, S1_{dopant}−0.3 eV<|E_{red,dopant}−E_{ox,host}|<S1_{dopant}+0.3 eV), Condition 6-2
wherein “eV” denotes “electron volts”.

In Conditions 1 to 6-2, “E*_{ox,dopant}” represents an excited-state oxidation potential (expressed in electron volts, eV) of the dopant,
“E*_{red,dopant}” represents an excited-state reduction potential (eV) of the dopant,
“E_{ox,dopant}” represents a ground-state oxidation potential (eV) of the dopant,
“E_{red,dopant}” represents a ground-state reduction potential (eV) of the dopant,
“E*_{red,host}” represents an excited-state reduction potential (eV) of the host,
“E*_{ox,host}” represents an excited-state oxidation potential (eV) of the host,
“E_{red,host}” represents a ground-state reduction potential (eV) of the host,
“E_{ox,host}” represents a ground-state oxidation potential (eV) of the host,
E*_{ox,dopant} may be identical to E_{ox,dopant}−T1_{dopant},
E*_{red,dopant} may be identical to E_{red,dopant}+T1_{dopant},
E*_{ox,host} may be identical to E_{ox,host}−S1ₕₒₛₜ,
E*_{red,host} may be identical to E_{red,host}+S1ₕₒₛₜ,
“T1_{dopant}” represents the lowest triplet energy level (eV) of the dopant,
“S1_{dopant}” represents the lowest singlet energy level (eV) of the dopant,
“S1ₕₒₛₜ” represents the lowest singlet energy level (eV) of the host,
E_{ox,dopant} and E_{ox,host} may be measured by using cyclic voltammetry (CV),
E_{red,dopant} and E_{red,host} may be measured by using differential pulse voltammetry,
T1_{dopant} and S1_{dopant} may be calculated from a photoluminescence (PL) spectrum of the dopant in solution, and
S1ₕₒₛₜ may be calculated from a PL spectrum of the host in solution.

While not wishing to be bound by theory, it is understood that when the organic light-emitting device satisfies Conditions 1, 2, 3, and 4, reduction or oxidation of the host and/or the dopant in the emission layer through electron transfer may be substantially prevented, thereby substantially preventing generation of radical species in the emission layer. Since the radical species may cause various side reactions in the emission layer, the lifespan of the organic light-emitting device may be shortened.

In some embodiments, 1) when the dopant of the organic light-emitting device includes a phosphorescent dopant and at least one of Conditions 5-1 and 6-1 is satisfied in the organic light-emitting device; or 2) when the dopant of the organic light-emitting device includes a fluorescent dopant and at least one of Conditions 5-2 and 6-2 is satisfied in the organic light-emitting device, i) a limited degree of reduction or oxidation of the host and/or the dopant in the emission layer through electron transfer may occur, and ii) even when the reduction or oxidation of the host and/or the dopant in the emission layer through electron transfer occurs, back electron transfer may rapidly occur, which may facilitate rapid restoration of the host and/or the dopant to their/its original state before the reduction or oxidation. Accordingly, the reduction or oxidation of the host and/or the dopant in the emission layer through electron transfer may be substantially prevented and/or limited, thereby substantially preventing and/or limiting generation of radical species in the emission layer. Furthermore, re-excitation of the dopant may also be promoted.

While not wishing to be bound by theory, it is understood that when the organic light-emitting device satisfies the aforementioned conditions, generation of radical species in the emission layer may be substantially prevented and/or minimized, and thus, exciton quenching in the emission layer of the organic light-emitting device and electrochemical degradation and/or photochemical degradation of the host and the dopant in the emission layer may be substantially prevented and/or minimized. Therefore, the organic light-emitting device may have improved lifespan.

In one or more embodiments, the dopant of the organic light-emitting device may include a phosphorescent dopant, and in the organic light-emitting device, at least one of Conditions 5-1 and 6-1 may be satisfied.

In one or more embodiments, the dopant of the organic light-emitting device may include a fluorescent dopant, and in the organic light-emitting device, at least one of Conditions 5-2 and 6-2 may be satisfied.

In one or more embodiments, the dopant of the organic light-emitting device may include a phosphorescent dopant, and in the organic light-emitting device, Conditions 1 and 3 may not be satisfied, and Conditions 2, 4, 5-1, and 6-1 may be satisfied.

In one or more embodiments, the dopant of the organic light-emitting device may include a phosphorescent dopant, and in the organic light-emitting device, Conditions 3 and 6-1 may not be satisfied, and Conditions 1, 2, 4, and 5-1 may be satisfied.
i) The host may include (e.g., consist of) at least one donor compound, ii) the host may include (e.g., consist of) at least one acceptor compound, or iii) the host may include (e.g., consist of) a combination of at least one donor compound and at least one acceptor compound. When the host includes at least one donor compound and at least one acceptor compound, the donor compound and the acceptor compound may form an exciplex.

The donor compound may include at least one selected from a carbazole-including ring, a dibenzofuran-including ring, a dibenzothiophene-including ring, an indenocarbazole-including ring, an indolocarbazole-including ring, a benzofurocarbazole-including ring, a benzothienocarbazole-including ring, an acridine-including ring, a dihydroacridine-including ring, and a tri-indolobenzene-including ring, and
the acceptor compound may include at least one selected from a carbazole-including ring, a dibenzofuran-including ring, a dibenzothiophene-including ring, an indenocarbazole-including ring, an indolocarbazole-including ring, a benzofurocarbazole-including ring, a benzothienocarbazole-including ring, a pyridine-including ring, a pyrimidine-including ring, and a triazine-including ring.

In some embodiments, the acceptor compound may include at least one electron withdrawing group,
wherein the electron withdrawing group may be selected from:
—F, —CFH₂, —CF₂H, —CF₃, —CN, and —NO₂;
a C₁-C₆₀ alkyl group substituted with at least one selected from —F, —CFH₂, —CF₂H, —CF₃, —CN, and —NO₂;
a C₁-C₆₀ heteroaryl group and a monovalent non-aromatic condensed polycyclic heterocyclic group, each including *═N—*′ as a ring-forming moiety; and
a C₁-C₆₀ heteroaryl group and a monovalent non-aromatic condensed polycyclic heterocyclic group, each including *═N—*′ as a ring-forming moiety and each substituted with at least one selected from deuterium, —F, —CFH₂, —CF₂H, —CF₃, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C1-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, and a substituted or unsubstituted monovalent non-aromatic condensed heteropolycyclic group.

In an embodiment, the donor compound may be selected from compounds represented by Formula D-1, and
the acceptor compound may be selected from compounds represented by Formulae A-1 and A-2:

Ar₁-(L₁)ₐ₁-Ar₂ Formula D-1

Ar₁₁-(L₁₁)ₐ₁₁-Ar₁₂ Formula A-1

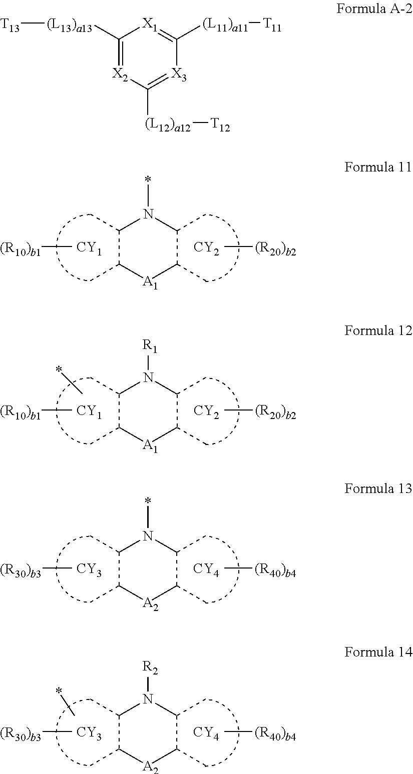

wherein, in Formulae D-1, A-1, A-2, and 11 to 14,
Ar₁ may be groups represented by Formulae 11 and 12,
Ar₂ may be selected from:
groups represented by Formulae 11 and 12, a phenyl group, a naphthyl group, and a benzimidazolyl group; and
a phenyl group, a naphthyl group, and a benzimidazolyl group, each substituted with at least one selected from deuterium, a hydroxyl group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a carbazolyl group, a dibenzofuranyl group, and a dibenzothiophenyl group,
Ar₁₁ and Ar₁₂ may each independently be selected from groups represented by Formulae 13 and 14,
X₁ may be N or C(T₁₄), X₂ may be N or C(T₁₅), and X₃ may be N or C(T₁₆), provided that at least one of X₁ to X₃ is N,
L₁ may be selected from:
a single bond, a phenylene group, a naphthylene group, a fluorenylene group, a carbazolylene group, a dibenzofuranylene group, and a dibenzothiophenylene group; and
a phenylene group, a naphthylene group, a fluorenylene group, a carbazolylene group, a dibenzofuranylene group, and a dibenzothiophenylene group, each substituted with at least one selected from deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, and —Si(Q₁₁)(Q₁₂)(Q₁₃),
L₁₁ to L₁₃ may each independently be selected from:
a single bond, a phenylene group, a pyridinylene group, a pyrimidinylene group, a pyrazinylene group, a pyridazinylene group, a triazinylene group, a naphthylene group, a fluorenylene group, a carbazolylene group, a dibenzofuranylene group, and a dibenzothiophenylene group; and
a phenylene group, a pyridinylene group, a pyrimidinylene group, a pyrazinylene group, a pyridazinylene group, a triazinylene group, a naphthylene group, a fluorenylene group, a carbazolylene group, a dibenzofuranylene group, and a dibenzothiophenylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, —CFH₂, a phenyl group, a phenyl group substituted with a cyano group, a naphthyl group, a pyridinyl group, a pyrimidinyl group, a pyrazinyl group, a pyridazinyl group, a triazinyl group, a fluorenyl group, a carbazolyl group, a dibenzofuranyl group, a dibenzothiophenyl group, and —Si(Q₁₁)(Q₁₂)(Q₁₃),
a1 and a11 to a13 may each independently be an integer selected from 0 to 5; when a1 is 2 or greater, at least two L₁ groups may be identical to or different from each other; when a11 is 2 or greater, at least two L₁₁ groups may be identical to or different from each other; when a12 is 2 or greater, at least two L₁₂ groups may be identical to or different from each other; and when a13 is 2 or greater, at least two L₁₃ groups may be identical to or different from each other,
CY₁ to CY₄ may each independently be selected from a benzene group, a naphthalene group, a fluorene group, a carbazole group, a benzocarbazole group, an indolocarbazole group, a dibenzofuran group, and a dibenzothiophene group,
A₁ may be selected from
a single bond, a C₁-C₄ alkylene group, and a C₂-C₄ alkenylene group; and
a C₁-C₄ alkylene group and a C₂-C₄ alkenylene group, each substituted with at least one selected from deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, and —Si(Q₂₁)(Q₂₂)(Q₂₃),
A₂ may be selected from:
a single bond, a C₁-C₄ alkylene group, and a C₂-C₄ alkenylene group; and
a C₁-C₄ alkylene group and a C₂-C₄ alkenylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, a phenyl group, a naphthyl group, a pyridinyl group, a pyrimidinyl group, a pyrazinyl group, a pyridazinyl group, a triazinyl group, a fluorenyl group, a carbazolyl group, a dibenzofuranyl group, a dibenzothiophenyl group, and —Si(Q₂₁)(Q₂₂)(Q₂₃),
R₁, R₁₀, and R₂₀ may each independently be selected from:
hydrogen, deuterium, a hydroxyl group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;
a C₁-C₂₀ alkyl group and a C₁-C₂₀ alkoxy group, each substituted with at least one selected from deuterium, a hydroxyl group, an amino group, an amidino group, a hydrazine group, a hydrazone group, a carboxylic acid group or a salt thereof, a sulfonic acid group or a salt thereof, a phosphoric acid group or a salt thereof, a phenyl group, a naphthyl group, a fluorenyl group, a carbazolyl group, a dibenzofuranyl group, and a dibenzothiophenyl group;
a phenyl group, a naphthyl group, a fluorenyl group, a carbazolyl group, a dibenzofuranyl group, and a dibenzothiophenyl group;
a phenyl group, a naphthyl group, a fluorenyl group, a carbazolyl group, a dibenzofuranyl group, and a dibenzothiophenyl group, each substituted with at least one selected from deuterium, a hydroxyl group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a carbazolyl group, a dibenzofuranyl group, and a dibenzothiophenyl group; and
—Si(Q₁)(Q₂)(Q₃),
T₁₁ to T₁₆, R₂, R₃₀, and R₄₀ may each independently be selected from hydrogen, deuterium, —F, —Cl, —Br, —I, a hydroxyl group, a cyano group (CN), a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, and —Si(Q₁)(Q₂)(Q₃),
b1 to b4 may each independently be an integer selected from 0 to 10, and
at least one substituent of the substituted C₁-C₆₀ alkyl group, substituted C₂-C₆₀ alkenyl group, substituted C₂-C₆₀ alkynyl group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₇-C₆₀ arylalkyl group, substituted C₁-C₆₀ heteroaryl group, substituted C₁-C₆₀ heteroaryloxy group, substituted C₁-C₆₀ heteroarylthio group, substituted C₂-C₆₀ heteroarylalkyl group, substituted monovalent non-aromatic condensed polycyclic group, and substituted monovalent non-aromatic condensed heteropolycyclic group may be selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C1-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C6-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, and —Si(Q₃₁)(Q₃₂)(Q₃₃),
wherein Q₁ to Q₃, Q₁₁ to Q₁₃, Q₂₁ to Q₂₃, and Q₃₁ to Q₃₃ may each independently be selected from hydrogen, deuterium, a C₁-C₆₀ alkyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

In some embodiments, in Formula D-1, Ar₁ may be selected from groups represented by Formulae 11-1 to 11-8 and 12-1 to 12-8,
in Formula D-1, Ar₂ may be selected from groups represented by Formulae 11-1 to 11-8 and 12-1 to 12-8, a phenyl group, a naphthyl group, and a benzimidazolyl group substituted with a phenyl group, and
in Formula A-1, Ar₁₁ and Ar₁₂ may each independently be selected from groups represented by Formulae 13-1 to 13-8 and 14-1 to 14-8:

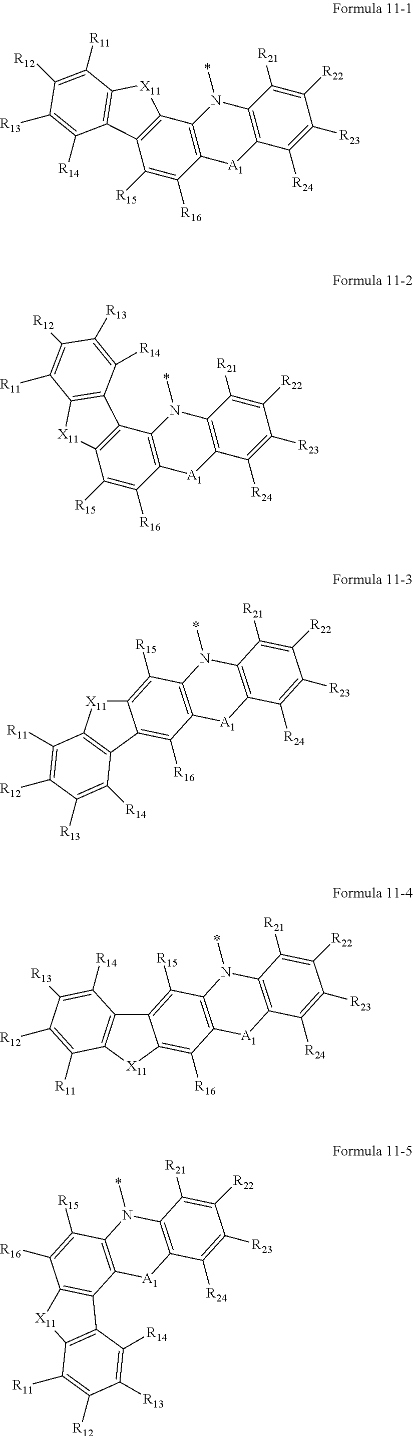

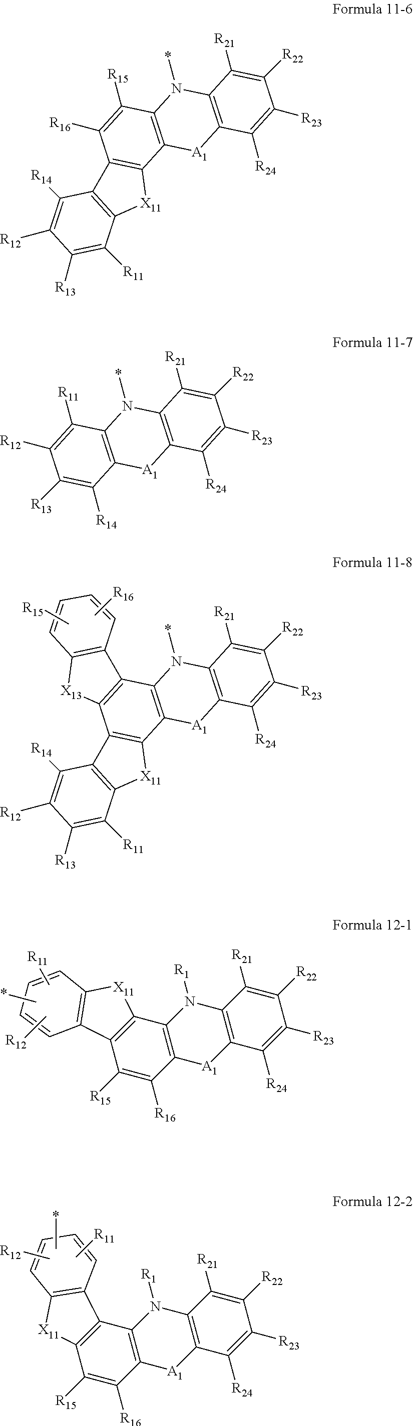

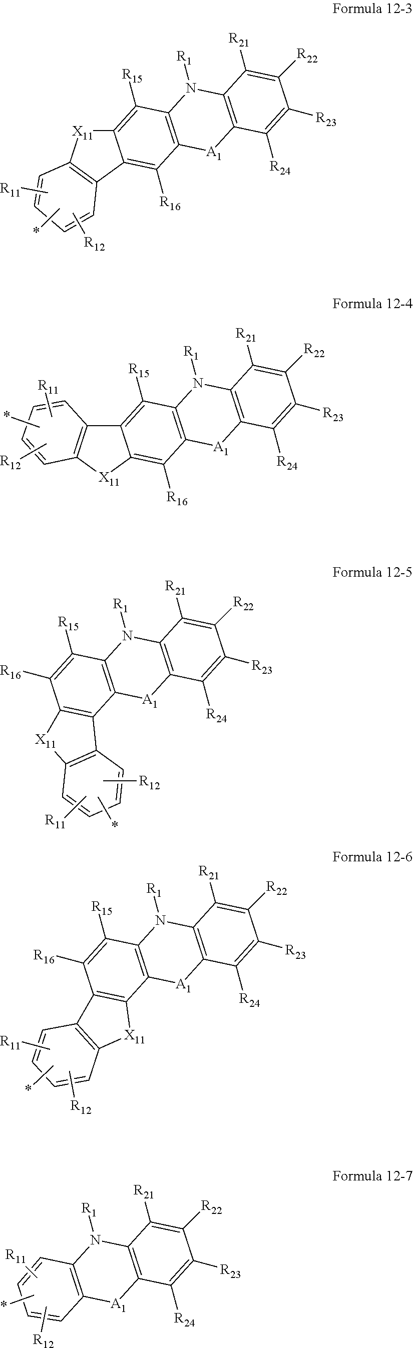

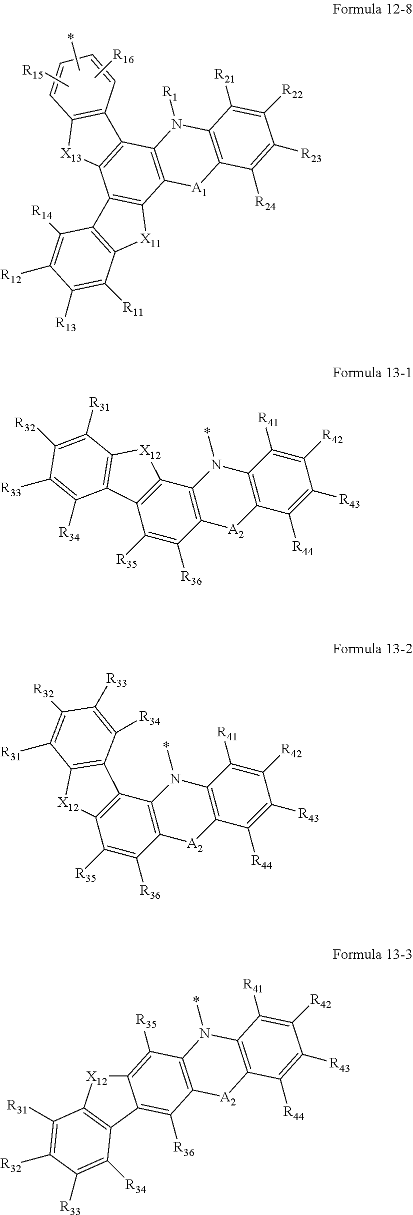

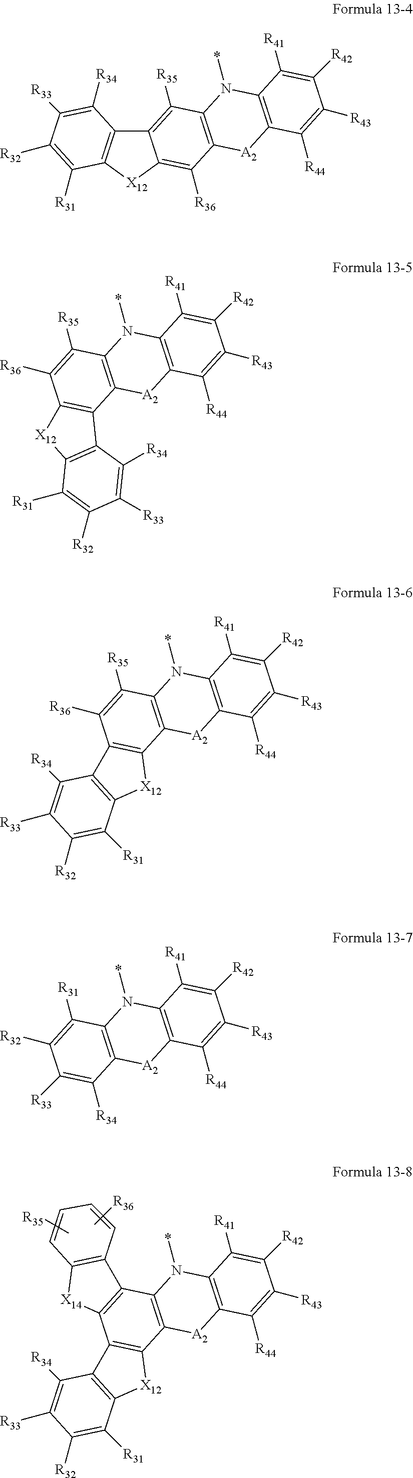

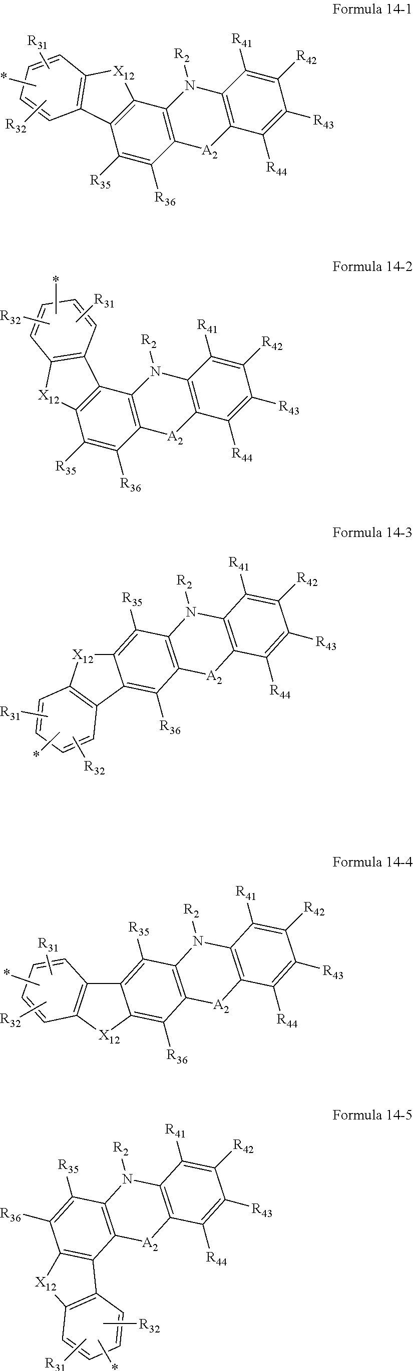

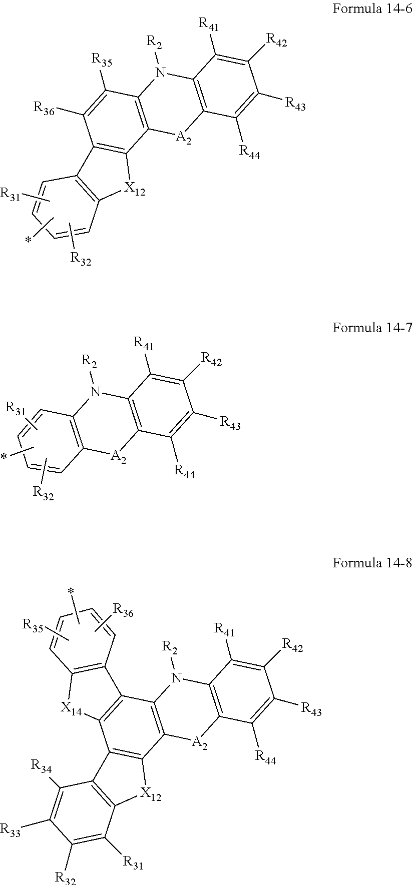

wherein, in Formulae 11-1 to 11-8, 12-1 to 12-8, 13-1 to 13-8, and 14-1 to 14-8,
X₁₁ and X₁₃ may each independently be C(R₁₇)(R₁₈), N(R₁₉), O, or S,
X₁₂ and X₁₄ may each independently be C(R₃₇)(R₃₈), N(R₃₉), O, or S,
R₁, R₂, A₁, and A₂ may be the same as those defined herein,
R₁₁ to R₁₉ may be the same as described herein with reference to R₁₀,
R₂₁ to R₂₄ may be the same as described herein with reference to R₂₀,
R₃₁ to R₃₉ may be the same as described herein with reference to R₃₀,
R₄₁ to R₄₄ may be the same as described herein with reference to R₄₀, and
* indicates a binding site to an adjacent atom.

In some embodiments, in Formulae 11, 12, 11-1 to 11-8, and 12-1 to 12-8, A₁ may be selected from:
a single bond, a C₁-C₂ alkylene group, and a C₂ alkenylene group; and
a C₁-C₂ alkylene group and a C₂ alkenylene group, each substituted with at least one selected from deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, and —Si(Q₂₁)(Q₂₂)(Q₂₃),
in Formulae 13, 14, 13-1 to 13-8, and 14-1 to 14-8, A₂ may be selected from:
a single bond, a C₁-C₂ alkylene group, and a C₂ alkenylene group; and
a C₁-C₂ alkylene group and a C₂ alkenylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, a phenyl group, a naphthyl group, a pyridinyl group, a pyrimidinyl group, a pyrazinyl group, a pyridazinyl group, a triazinyl group, a fluorenyl group, a carbazolyl group, a dibenzofuranyl group, a dibenzothiophenyl group, and —Si(Q₂₁)(Q₂₂)(Q₂₃), and
in Formulae 13, 14, 13-1 to 13-8, and 14-1 to 14-8, R₂, R₃₀ to R₃₉, and R₄₀ to R₄₄ may each independently be selected from:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;
a C₁-C₂₀ alkyl group and a C₁-C₂₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a phenyl group, a naphthyl group, a fluorenyl group, a carbazolyl group, a dibenzofuranyl group, and a dibenzothiophenyl group;
a phenyl group, a pyridinyl group, a pyrimidinyl group, a pyrazinyl group, a pyridazinyl group, a triazinyl group, a naphthyl group, a fluorenyl group, a carbazolyl group, a dibenzofuranyl group, and a dibenzothiophenyl group;
a phenyl group, a pyridinyl group, a pyrimidinyl group, a pyrazinyl group, a pyridazinyl group, a triazinyl group, a naphthyl group, a fluorenyl group, a carbazolyl group, a dibenzofuranyl group, and a dibenzothiophenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a pyridinyl group, a pyrimidinyl group, a pyrazinyl group, a pyridazinyl group, a triazinyl group, a naphthyl group, a fluorenyl group, a carbazolyl group, a dibenzofuranyl group, and a dibenzothiophenyl group; and
—Si(Q₁)(Q₂)(Q₃),
wherein Q₁ to Q₃ and Q₂₁ to Q₂₃ may each independently be selected from hydrogen, a C₁-C₁₀ alkyl group, a C₁-C₁₀ alkoxy group, a phenyl group, and a naphthyl group, but embodiments are not limited thereto.

In an embodiment, in Formula D-1, Ar₁ may be selected from groups represented by Formulae 15-1 to 15-17 and 16-1 to 16-8,
in Formula D-1, Ar₂ may be selected from groups represented by Formulae 15-1 to 15-17 and 16-1 to 16-8, a phenyl group, a naphthyl group, and an imidazolyl group substituted with a phenyl group, and
in Formula A-1, Ar₁₁ and Ar₁₂ may each independently be selected from groups represented by Formulae 17-1 to 17-3, but embodiments are not limited thereto:

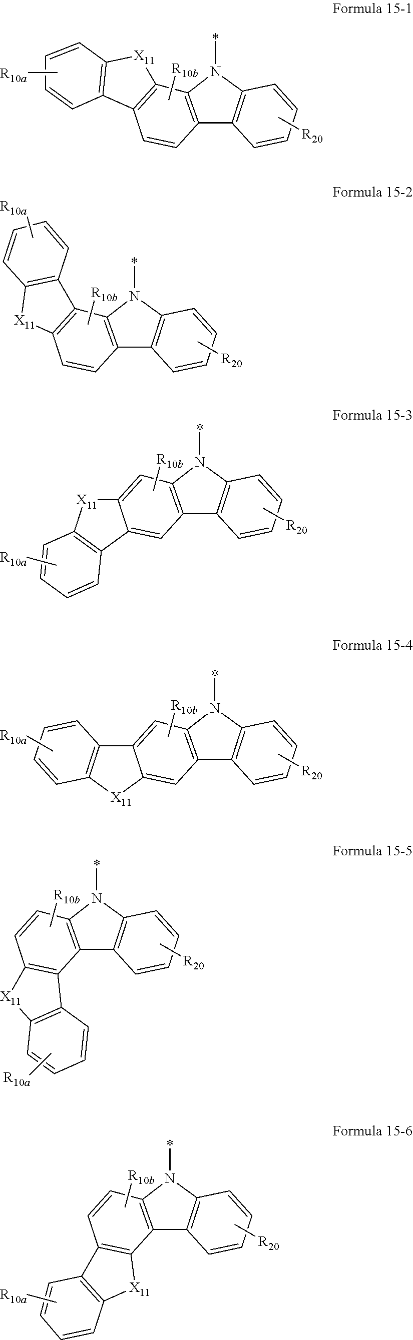

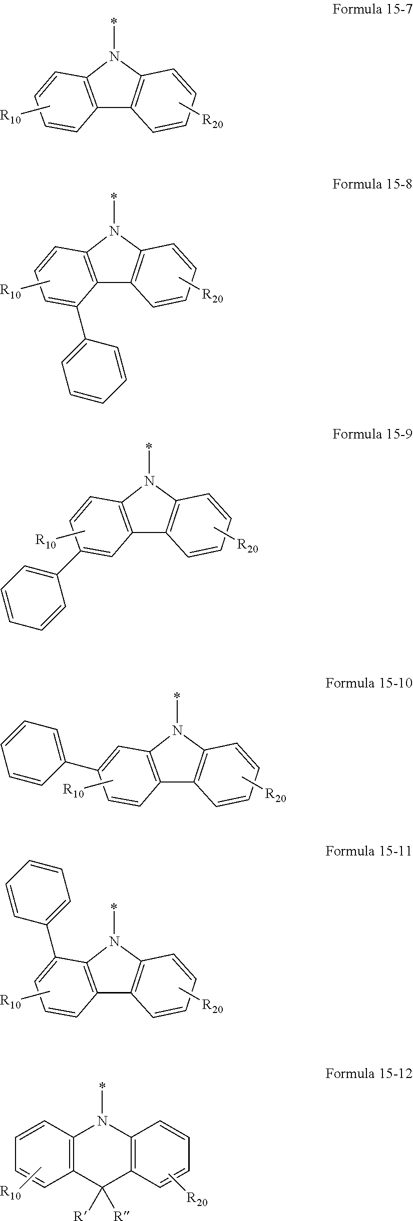

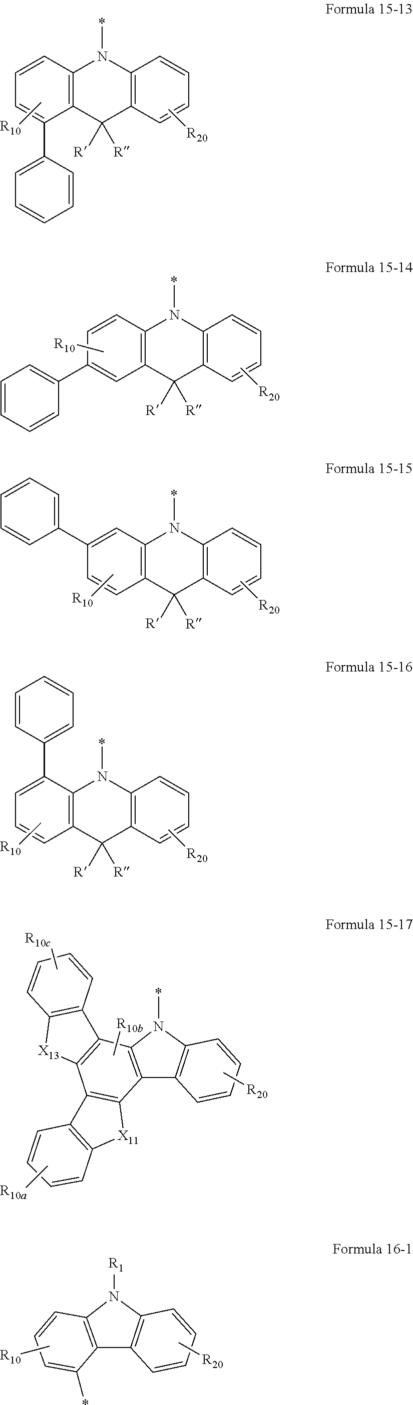

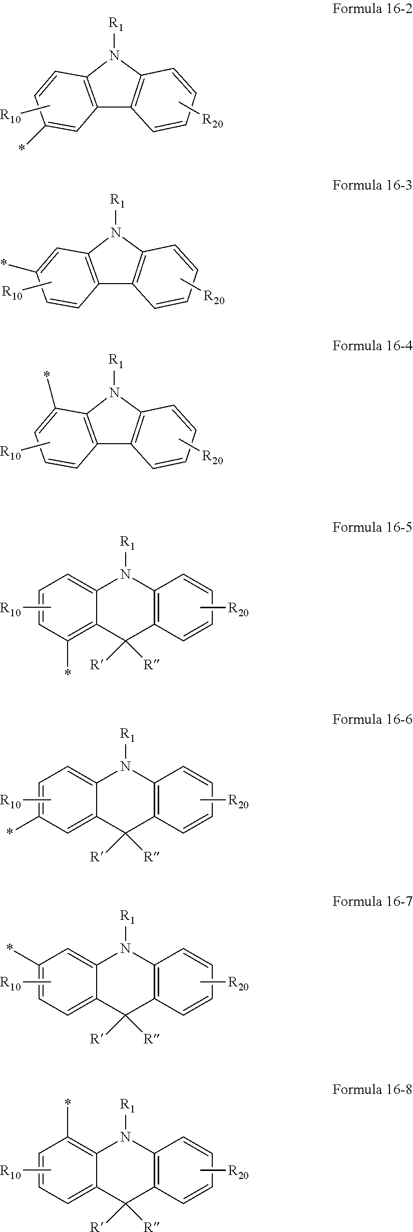

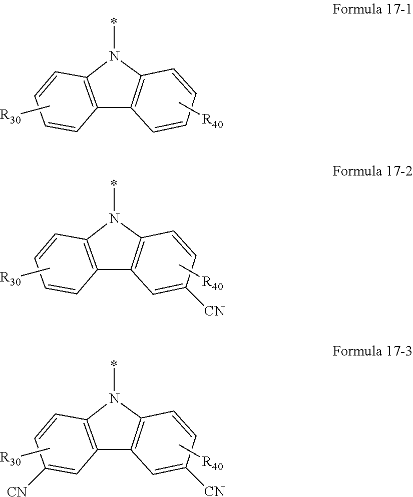

wherein, in Formulae 15-1 to 15-17, 16-1 to 16-18, and 17-1 to 17-3,
X₁₁ and X₁₃ may each independently be C(R₁₇)(R₁₈), N(R₁₉), O, or S,
R′ and R″ may each independently be selected from hydrogen, deuterium, a C₁-C₁₀ alkyl group, a C₁-C₁₀ alkoxy group, a phenyl group, a naphthyl group, a fluorenyl group, a carbazolyl group, a dibenzofuranyl group, and a dibenzothiophenyl group,
R₁, R₁₀, R₂₀, R₃₀, and R₄₀ may be the same as those described herein, and
R₁₀ₐ to R_{10c} may be the same as described herein with reference to R₁₀.

In some embodiments, in Formulae 15-1 to 15-17, 16-1 to 16-18, and 17-1 to 17-3,
R₁, R₁₀, R₁₀ₐ to R_{10c}, and R₂₀ may each independently be selected from hydrogen, deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, and —Si(Q₁)(Q₂)(Q₃), and
R₃₀ and R₄₀ may each independently be selected from:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, and —CFH₂;
a phenyl group, a pyridinyl group, a pyrimidinyl group, a pyrazinyl group, a pyridazinyl group, a triazinyl group, a naphthyl group, a fluorenyl group, a carbazolyl group, a dibenzofuranyl group, and a dibenzothiophenyl group;
a phenyl group, a pyridinyl group, a pyrimidinyl group, a pyrazinyl group, a pyridazinyl group, a triazinyl group, a naphthyl group, a fluorenyl group, a carbazolyl group, a dibenzofuranyl group, and a dibenzothiophenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, —CFH₂, a phenyl group, a pyridinyl group, a pyrimidinyl group, a pyrazinyl group, a pyridazinyl group, a triazinyl group, a naphthyl group, a fluorenyl group, a carbazolyl group, a dibenzofuranyl group, and a dibenzothiophenyl group; and
—Si(Q₁)(Q₂)(Q₃),
wherein Q₁ to Q₃ may each independently be selected from hydrogen, a C₁-C₁₀ alkyl group, a C₁-C₁₀ alkoxy group, a phenyl group, and a naphthyl group, but embodiments are not limited thereto.

In some embodiments,
i) the donor compound may be represented by Formula D-1 in which L₁ is a single bond; or
ii) the donor compound may be selected from compounds represented by Formulae D-1(1) to D-1(52):

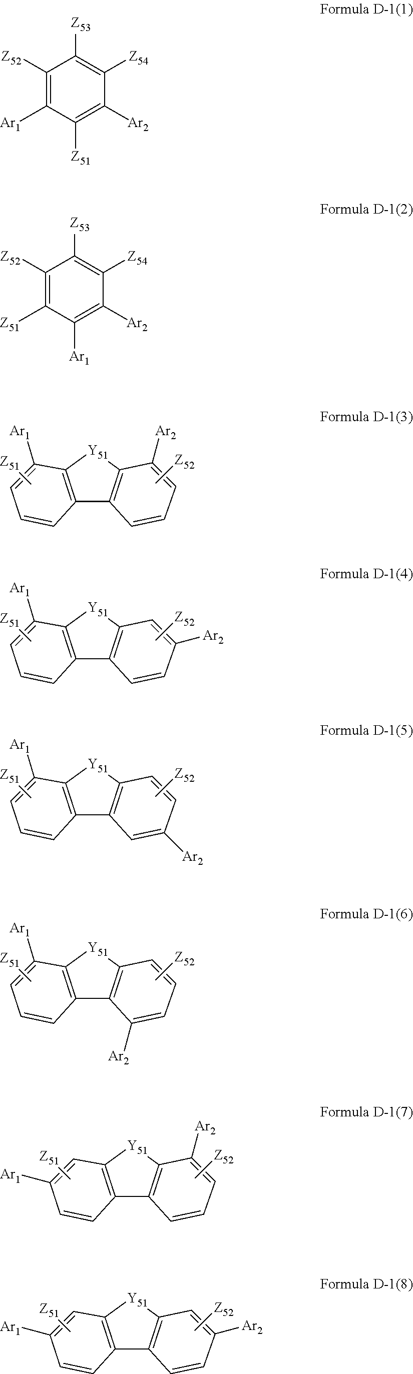

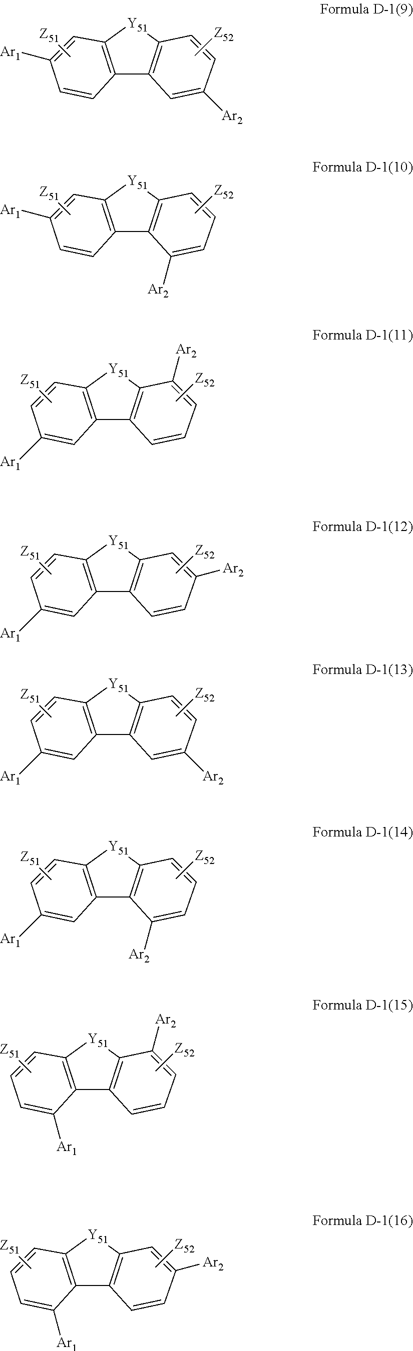

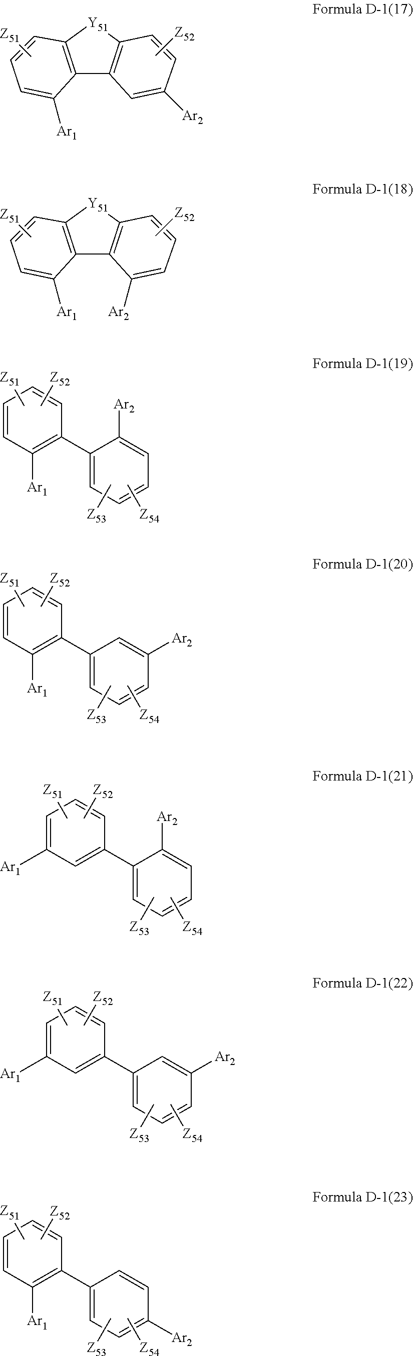

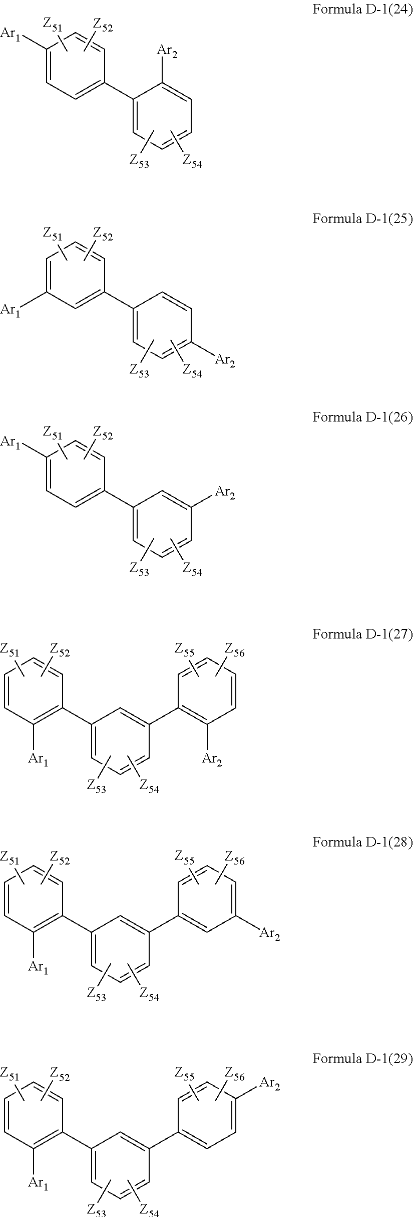

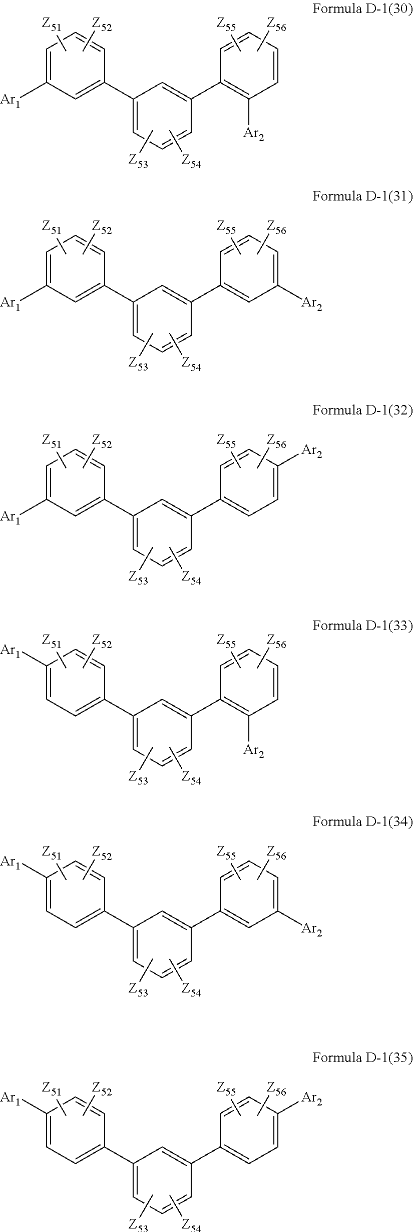

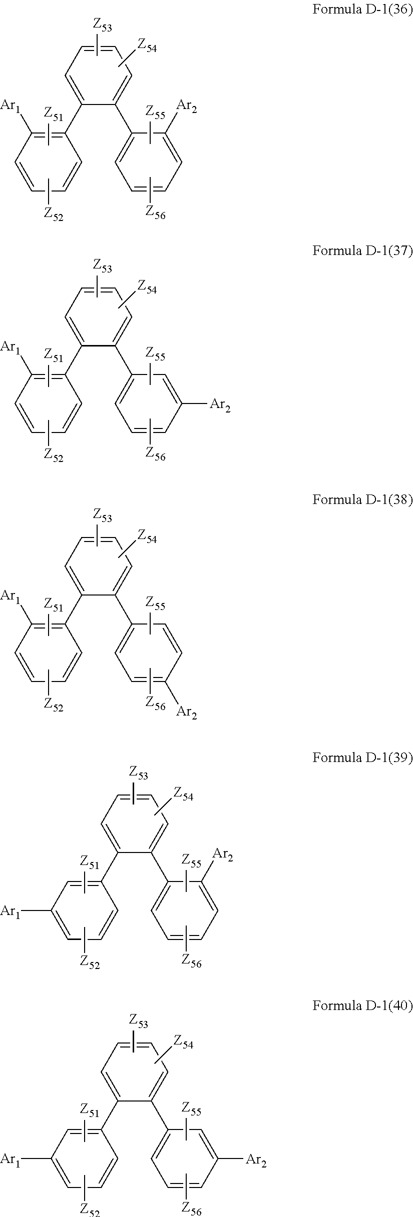

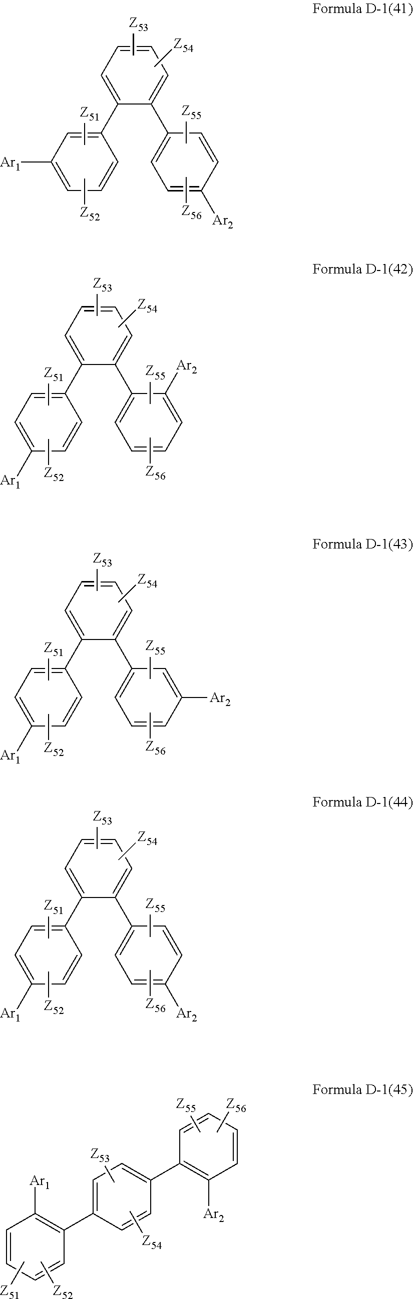

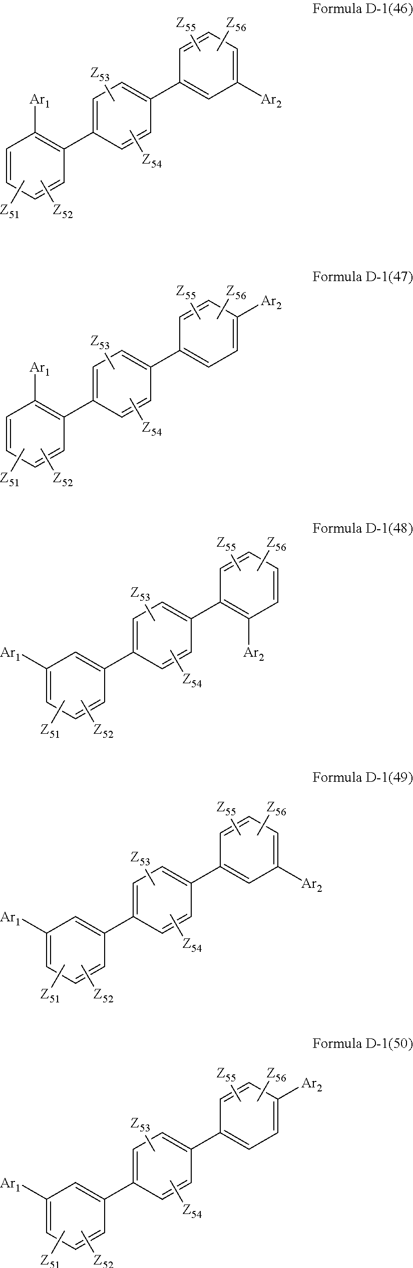

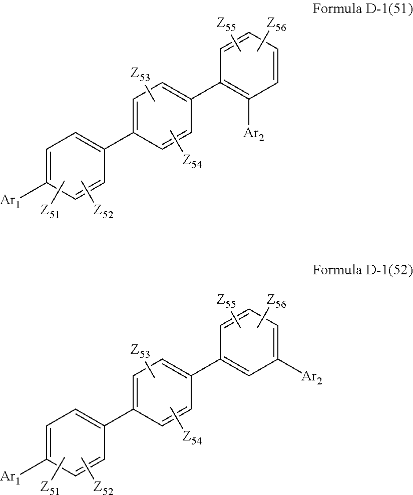

wherein, in Formulae D-1(1) to D-1(52),
Ar₁ and Ar₂ may be the same as those described herein,
Y₅₁ may be C(Z₅₃)(Z₅₄), N(Z₅₅), O, or S, and
Z₅₁ to Z₅₆ may each independently be selected from hydrogen, deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, and —Si(Q₁₁)(Q₁₂)(Q₁₃),
wherein Q₁₁ to Q₁₃ may each independently be selected from hydrogen, a C₁-C₁₀ alkyl group, a C₁-C₁₀ alkoxy group, a phenyl group, and a naphthyl group.

In some embodiments, in Formulae D-1(1) to D-1(52),
Ar₁ may be selected from groups represented by Formulae 11 and 12, and
Ar₂ may be selected from:
groups represented by Formulae 11 and 12, a phenyl group, a naphthyl group, and a benzimidazolyl group; and
a phenyl group, a naphthyl group, and a benzimidazolyl group, each substituted with at least one selected from deuterium, a hydroxyl group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a carbazolyl group, a dibenzofuranyl group, and a dibenzothiophenyl group.

In one or more embodiments, in Formulae D-1(1) to D-1(52),
Ar₁ may be selected from groups represented by Formulae 11-1 to 11-8 and 12-1 to 12-8,
Ar₂ may be selected from groups represented by Formulae 11-1 to 11-8 and 12-1 to 12-8, a phenyl group, a naphthyl group, and a benzimidazolyl group substituted with a phenyl group, but embodiments are not limited thereto.

In Formulae A-1 and A-2, L₁₁ to L₁₃ may each independently be selected from groups represented by Formulae 3-1 to 3-56, and i) at least one L₁₁ in the number of a11, ii) at least one L₁₂ in the number of a12, and iii) at least one L₁₃ in the number of a13 may each independently be selected from groups represented by Formulae 3-15 to 3-56:

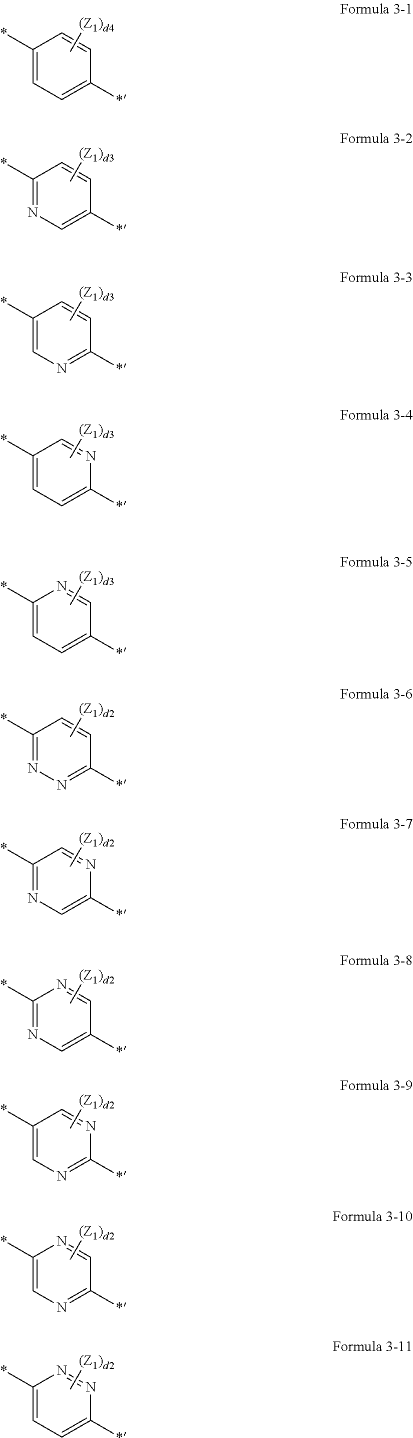

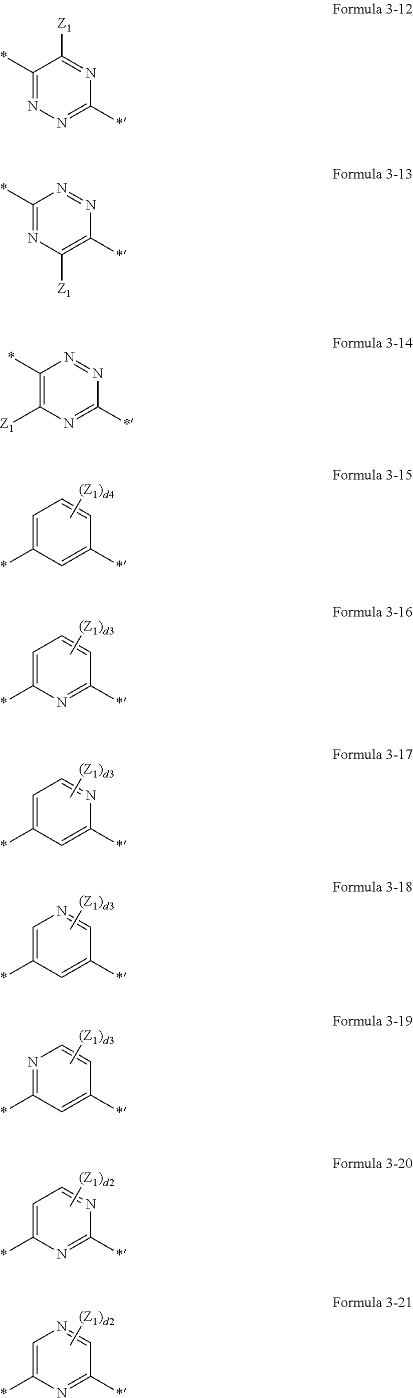

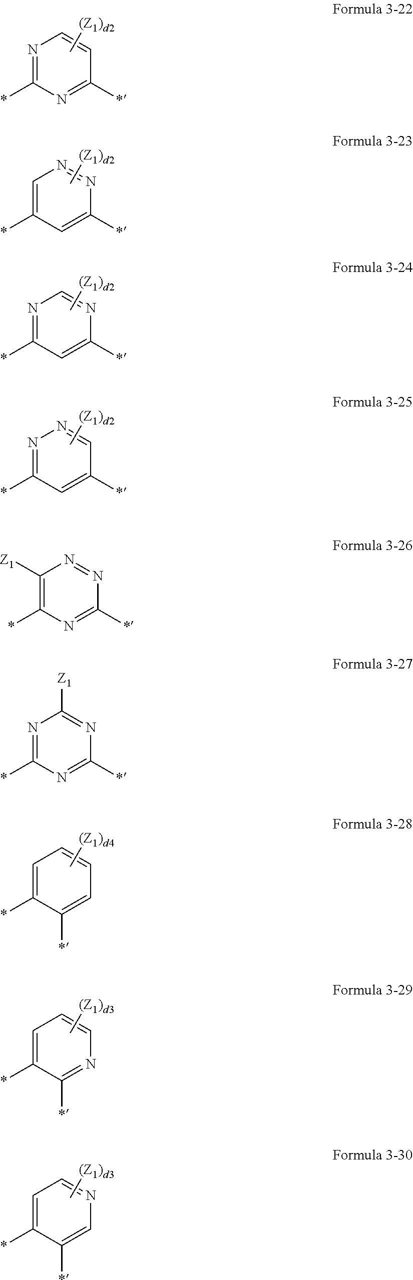

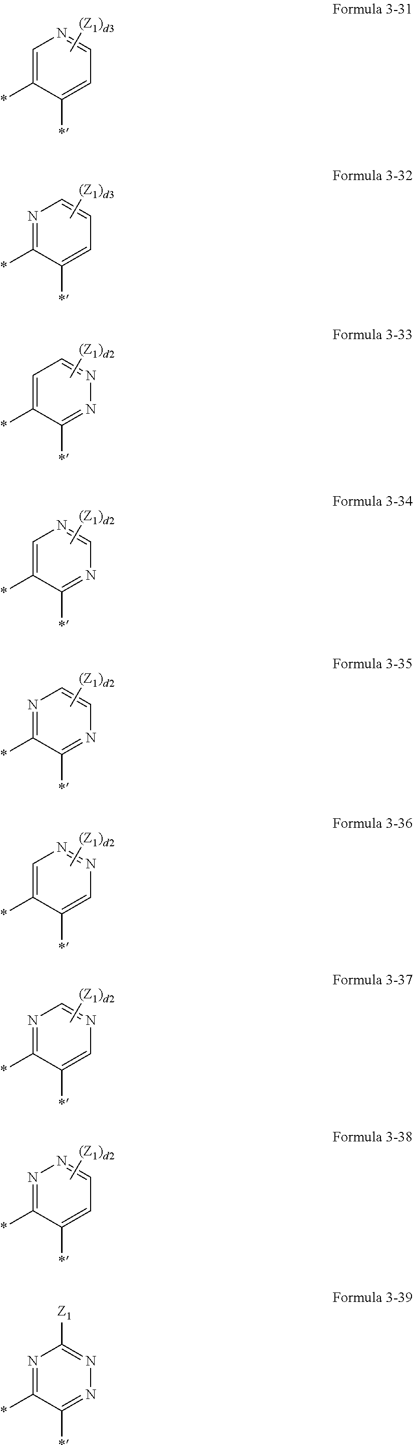

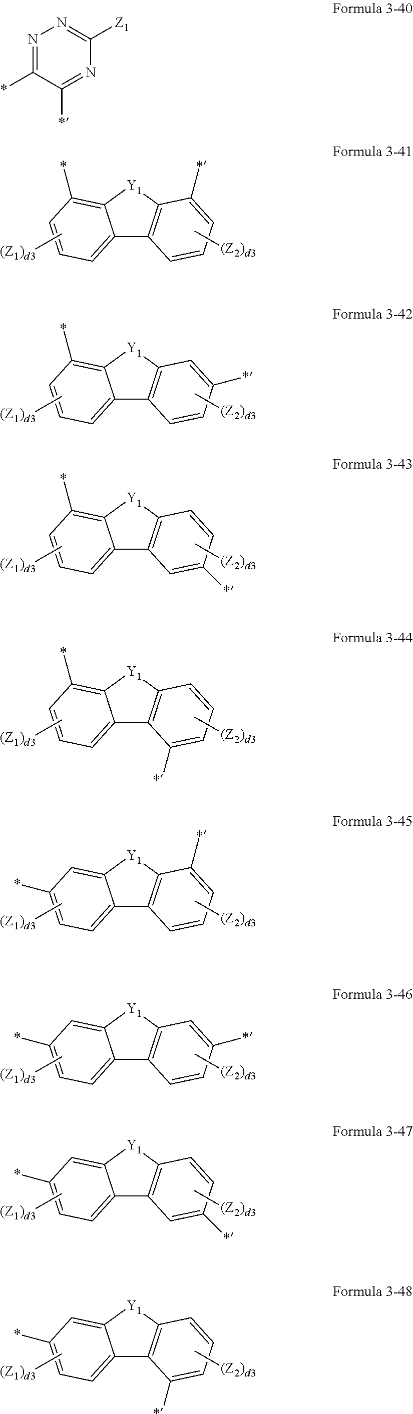

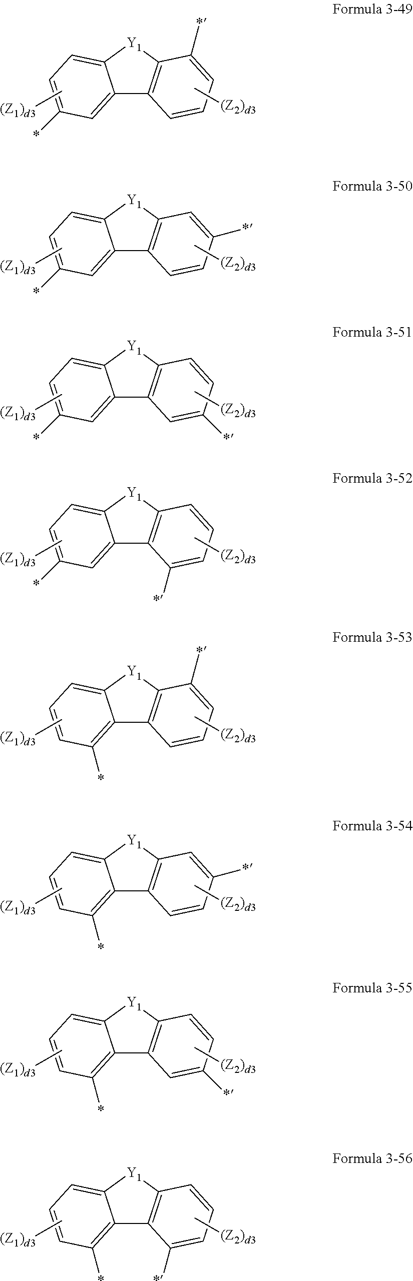

wherein, in Formulae 3-1 to 3-56,
Y₁ may be selected from O, S, C(Z₃)(Z₄), and N(Z₅),
Z₁ to Z₅ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, —CFH₂, a phenyl group, a phenyl group substituted with a cyano group, a naphthyl group, a pyridinyl group, a pyrimidinyl group, a pyrazinyl group, a pyridazinyl group, a triazinyl group, a fluorenyl group, a carbazolyl group, a dibenzofuranyl group, a dibenzothiophenyl group, and —Si(Q₁₁)(Q₁₂)(Q₁₃),
wherein Q₁₁ to Q₁₃ may each independently be selected from hydrogen, a C₁-C₁₀ alkyl group, a C₁-C₁₀ alkoxy group, a phenyl group, a naphthyl group, a pyridinyl group, a pyrimidinyl group, a pyrazinyl group, a pyridazinyl group, a triazinyl group, a fluorenyl group, a carbazolyl group, a dibenzofuranyl group, and a dibenzothiophenyl group, and
d4 may be an integer selected from 0 to 4,
d3 may be an integer selected from 0 to 3,
d2 may be an integer selected from 0 to 2, and
* and *′ each indicate a binding site to an adjacent atom.

In one or more embodiments, in Formulae A-1 and A-2, groups represented by *-(L₁₁)ₐ₁₁-*′, *-(L₁₂)ₐ₁₂-*′, and *-(L₁₃)ₐ₁₃-*′ may be selected from groups represented by Formulae 4-1 to 4-39:

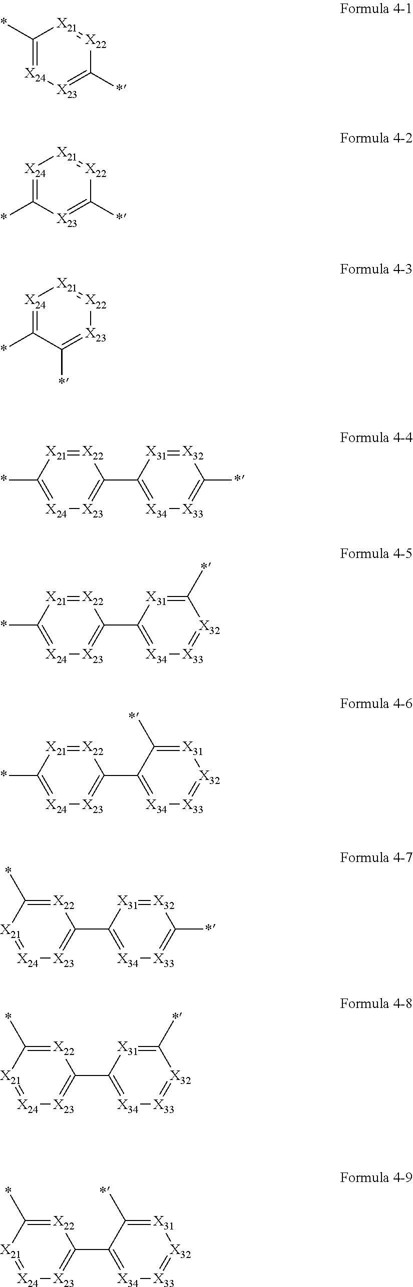

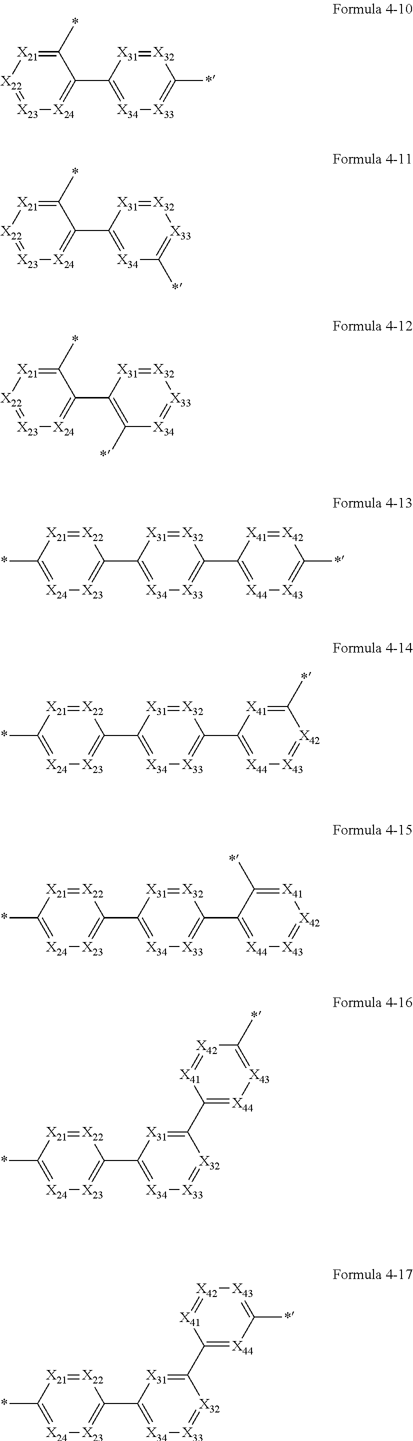

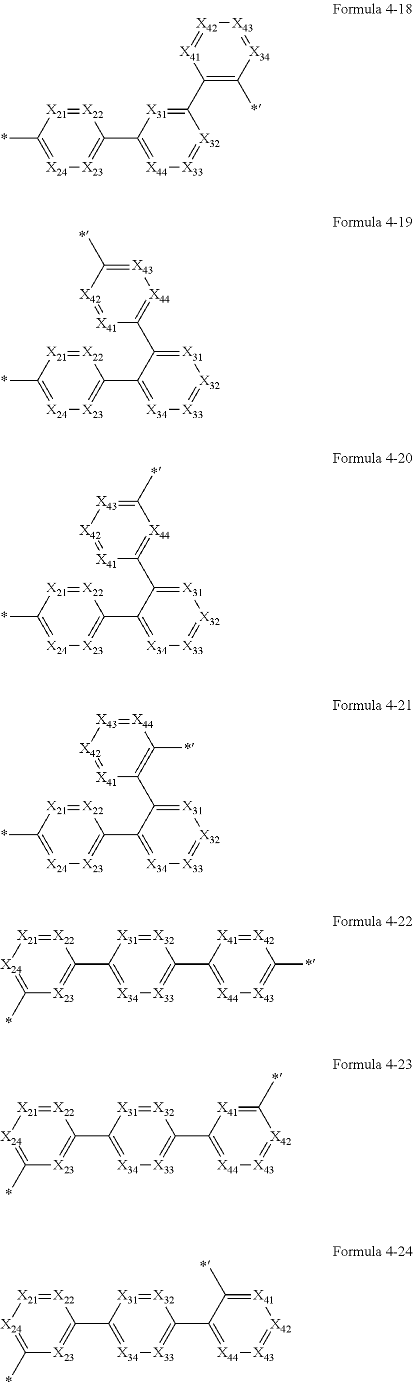

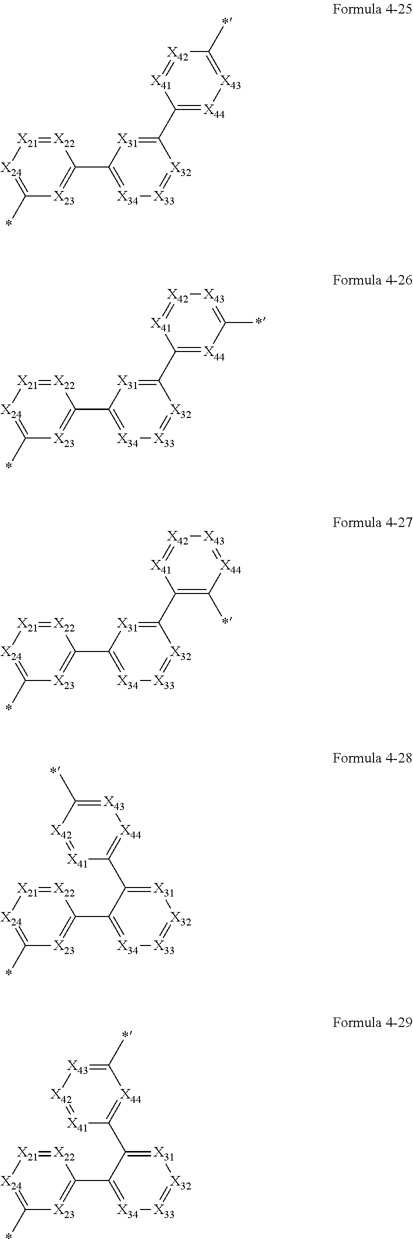

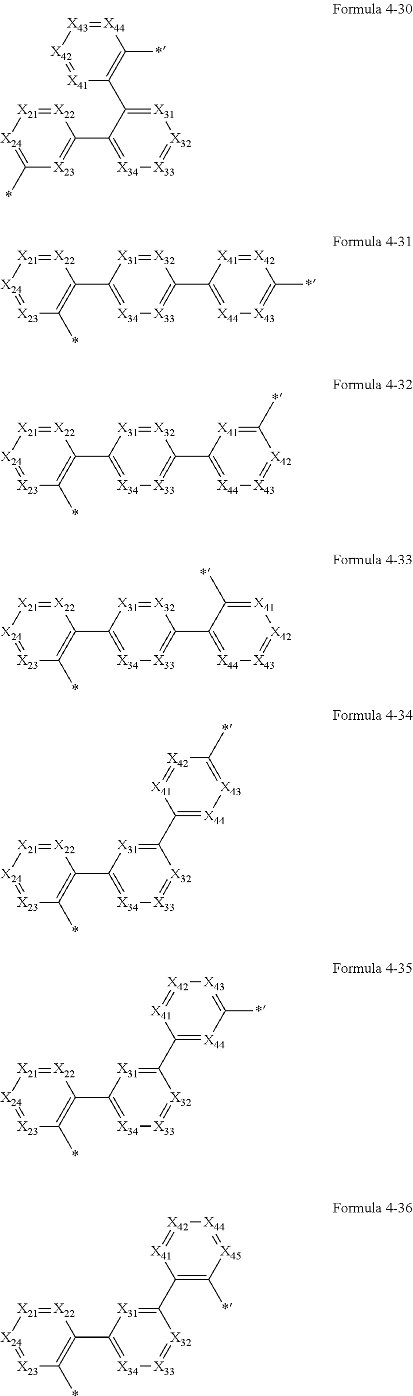

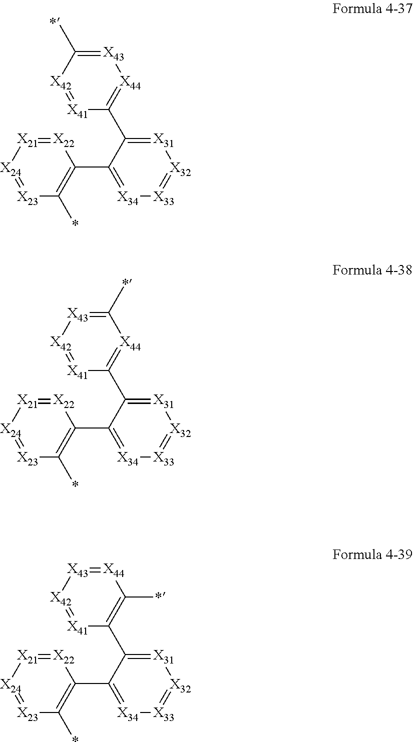

wherein, in Formulae 4-1 to 4-39,
X₂₁ may be N or C(Z₂₁), X₂₂ may be N or C(Z₂₂), X₂₃ may be N or C(Z₂₃), X₂₄ may be N or C(Z₂₄), X₃₁ may be N or C(Z₃₁), X₃₂ may be N or C(Z₃₂), X₃₃ may be N or C(Z₃₃), X₃₄ may be N or C(Z₃₄), X₄₁ may be N or C(Z₄₁), X₄₂ may be N or C(Z₄₂), X₄₃ may be N or C(Z₄₃), and X₄₄ may be N or C(Z₄₄), provided that at least one of X₂₁ to X₂₄ is not N, at least one of X₃₁ to X₃₄ is not N, and at least one of X₄₁ to X₄₄ is not N,
Z₂₁ to Z₂₄, Z₃₁ to Z₃₄, and Z₄₁ to Z₄₄ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, —CFH₂, a phenyl group, a phenyl group substituted with a cyano group, a naphthyl group, a pyridinyl group, a pyrimidinyl group, a pyrazinyl group, a pyridazinyl group, a triazinyl group, a fluorenyl group, a carbazolyl group, a dibenzofuranyl group, a dibenzothiophenyl group, and —Si(Q₁₁)(Q₁₂)(Q₁₃),
wherein Q₁₁ to Q₁₃ may each independently be selected from hydrogen, a C₁-C₁₀ alkyl group, a C₁-C₆₀ alkoxy group, a phenyl group, a naphthyl group, a pyridinyl group, a pyrimidinyl group, a pyrazinyl group, a pyridazinyl group, a triazinyl group, a fluorenyl group, a carbazolyl group, a dibenzofuranyl group, and a dibenzothiophenyl group, and
* and *′ each indicate a binding site to an adjacent atom.

In Formula A-2, T₁₁ to T₁₆ may each independently be selected from:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, and —CFH₂;
a C₁-C₁₀ alkyl group and a C₁-C₁₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —CF₃, —CF₂H, and —CFH₂;
a phenyl group, a naphthyl group, a pyridinyl group, a pyrimidinyl group, a pyrazinyl group, a pyridazinyl group, a triazinyl group, a fluorenyl group, a carbazolyl group, a dibenzofuranyl group, and a dibenzothiophenyl group;
a phenyl group, a naphthyl group, a pyridinyl group, a pyrimidinyl group, a pyrazinyl group, a pyridazinyl group, a triazinyl group, a fluorenyl group, a carbazolyl group, a dibenzofuranyl group, and a dibenzothiophenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, —CFH₂, a phenyl group, a naphthyl group, a pyridinyl group, a pyrimidinyl group, a pyrazinyl group, a pyridazinyl group, a triazinyl group, a fluorenyl group, a carbazolyl group, a dibenzofuranyl group, and a dibenzothiophenyl group; and
—Si(Q₁)(Q₂)(Q₃),
wherein Q₁ to Q₃ may each independently be selected from hydrogen, a C₁-C₁₀ alkyl group, a C₁-C₁₀ alkoxy group, a phenyl group, a naphthyl group, a pyridinyl group, a pyrimidinyl group, a pyrazinyl group, a pyridazinyl group, a triazinyl group, a fluorenyl group, a carbazolyl group, a dibenzofuranyl group, and a dibenzothiophenyl group.

In some embodiments, in Formula A-2, T₁₁ to T₁₆ may each independently be selected from:
hydrogen, deuterium, —F, a cyano group, a C₁-C₁₀ alkyl group, a C₁-C₁₀ alkoxy group, —CF₃, —CF₂H, and —CFH₂;
a C₁-C₁₀ alkyl group and a C₁-C₁₀ alkoxy group, each substituted with at least one selected from deuterium, —F, a cyano group, —CF₃, —CF₂H, and —CFH₂;
a phenyl group, a pyridinyl group, a pyrimidinyl group, a triazinyl group, a carbazolyl group, a dibenzofuranyl group, and a dibenzothiophenyl group;
a phenyl group, a pyridinyl group, a pyrimidinyl group, a triazinyl group, a carbazolyl group, a dibenzofuranyl group, and a dibenzothiophenyl group, each substituted with at least one selected from deuterium, —F, a cyano group, a C₁-C₁₀ alkyl group, a C₁-C₁₀ alkoxy group, —CF₃, —CF₂H, —CFH₂, a phenyl group, a pyridinyl group, a pyrimidinyl group, a triazinyl group, a carbazolyl group, a dibenzofuranyl group, and a dibenzothiophenyl group; and
—Si(Q₁)(Q₂)(Q₃),
wherein Q₁ to Q₃ may each independently be selected from hydrogen, a C₁-C₁₀ alkyl group, a C₁-C₁₀ alkoxy group, a phenyl group, a pyridinyl group, a pyrimidinyl group, a triazinyl group, a carbazolyl group, a dibenzofuranyl group, and a dibenzothiophenyl group.

In one or more embodiments,
i) the acceptor compound may be represented by Formula A-, in which Ar₁₁ and Ar₁₂ are each independently selected from groups represented by Formulae 17-1 to 17-3, and at least one of Ar₁₁ and Ar₁₂ is selected from groups represented by Formulae 17-2 and 17-3;
ii) the acceptor compound may be represented by Formula A-1 in which L₁₁ is selected from groups represented by Formulae 3-15 and 3-28, and at least one L₁₁ in the number of a11 is selected from groups represented by Formulae 6-1 to 6-4; or
iii) the acceptor compound may be represented by Formula A-2 in which X₁ to X₃ are each N, but embodiments are not limited thereto.

In some embodiments, the donor compound may be selected from Compounds D1 to D17, and the acceptor compound may be selected from Compounds A1 to A11 but embodiments are not limited thereto:

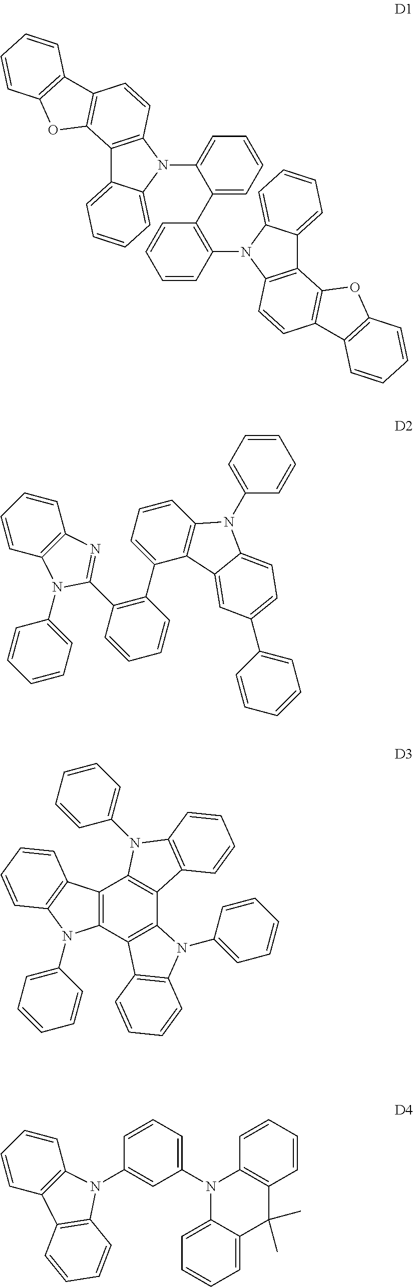 [SMILES: c1ccc(-n2c3ccccc3c3c4oc5ccccc5c4ccc32)c(-c2ccccc2-n2c3ccccc3c3c4oc5ccccc5c4ccc32)c1 ; c1ccc(-c2ccc3c(c2)c2c(-c4ccccc4-c4nc5ccccc5n4-c4ccccc4)cccc2n3-c2ccccc2)cc1 ; c1ccc(-n2c3ccccc3c3c2c2c4ccccc4n(-c4ccccc4)c2c2c4ccccc4n(-c4ccccc4)c32)cc1 ; CC1(C)c2ccccc2N(c2cccc(-n3c4ccccc4c4ccccc43)c2)c2ccccc21]

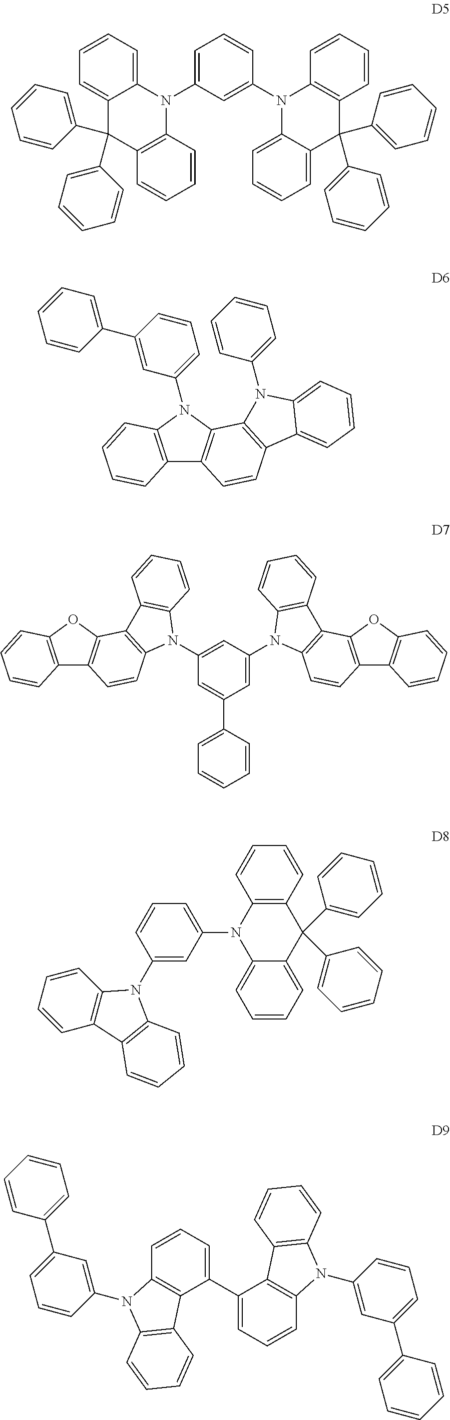 [SMILES: c1ccc(C2(c3ccccc3)c3ccccc3N(c3cccc(N4c5ccccc5C(c5ccccc5)(c5ccccc5)c5ccccc54)c3)c3ccccc32)cc1 ; c1ccc(-c2cccc(-n3c4ccccc4c4ccc5c6ccccc6n(-c6ccccc6)c5c43)c2)cc1 ; c1ccc(-c2cc(-n3c4ccccc4c4c5oc6ccccc6c5ccc43)cc(-n3c4ccccc4c4c5oc6ccccc6c5ccc43)c2)cc1 ; c1ccc(C2(c3ccccc3)c3ccccc3N(c3cccc(-n4c5ccccc5c5ccccc54)c3)c3ccccc32)cc1 ; c1ccc(-c2cccc(-n3c4ccccc4c4c(-c5cccc6c5c5ccccc5n6-c5cccc(-c6ccccc6)c5)cccc43)c2)cc1]

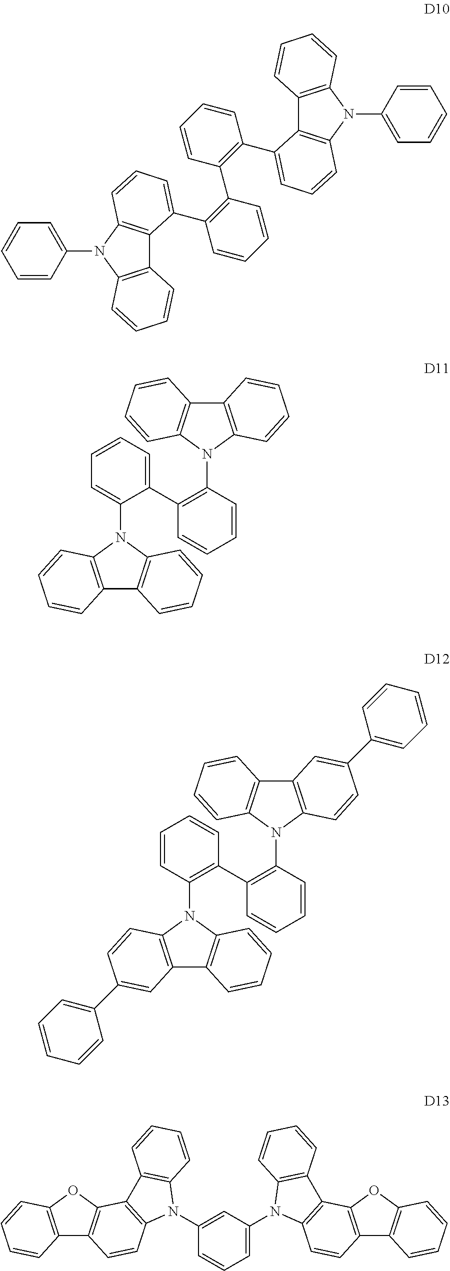 [SMILES: c1ccc(-n2c3ccccc3c3c(-c4ccccc4-c4ccccc4-c4cccc5c4c4ccccc4n5-c4ccccc4)cccc32)cc1 ; c1ccc(-n2c3ccccc3c3ccccc32)c(-c2ccccc2-n2c3ccccc3c3ccccc32)c1 ; c1ccc(-c2ccc3c(c2)c2ccccc2n3-c2ccccc2-c2ccccc2-n2c3ccccc3c3cc(-c4ccccc4)ccc32)cc1 ; c1cc(-n2c3ccccc3c3c4oc5ccccc5c4ccc32)cc(-n2c3ccccc3c3c4oc5ccccc5c4ccc32)c1]

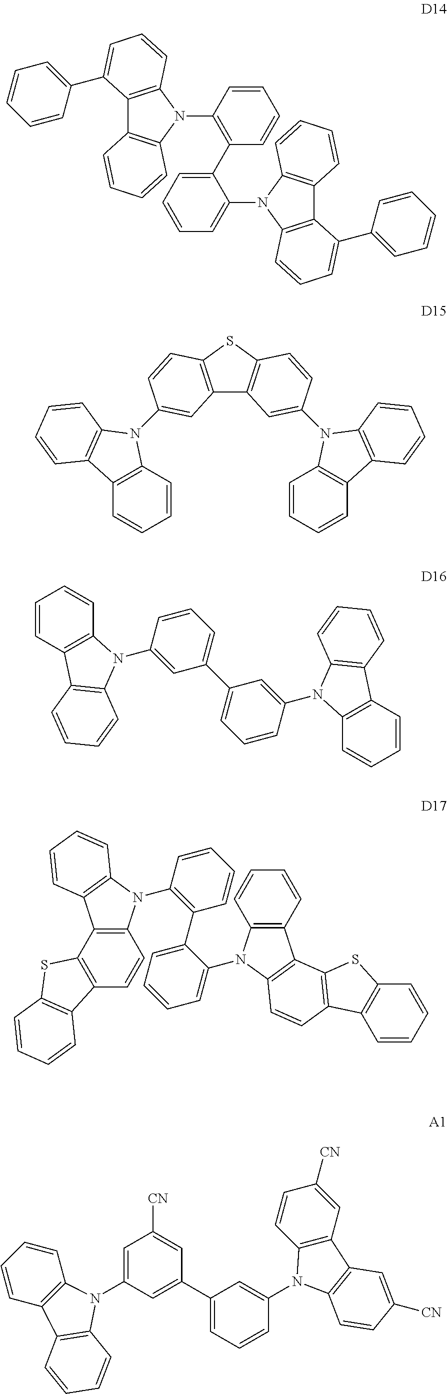 [SMILES: c1ccc(-c2cccc3c2c2ccccc2n3-c2ccccc2-c2ccccc2-n2c3ccccc3c3c(-c4ccccc4)cccc32)cc1 ; c1ccc2c(c1)c1ccccc1n2-c1ccc2sc3ccc(-n4c5ccccc5c5ccccc54)cc3c2c1 ; c1cc(-c2cccc(-n3c4ccccc4c4ccccc43)c2)cc(-n2c3ccccc3c3ccccc32)c1 ; c1ccc(-n2c3ccccc3c3c4sc5ccccc5c4ccc32)c(-c2ccccc2-n2c3ccccc3c3c4sc5ccccc5c4ccc32)c1 ; N#Cc1cc(-c2cccc(-n3c4ccc(C#N)cc4c4cc(C#N)ccc43)c2)cc(-n2c3ccccc3c3ccccc32)c1]

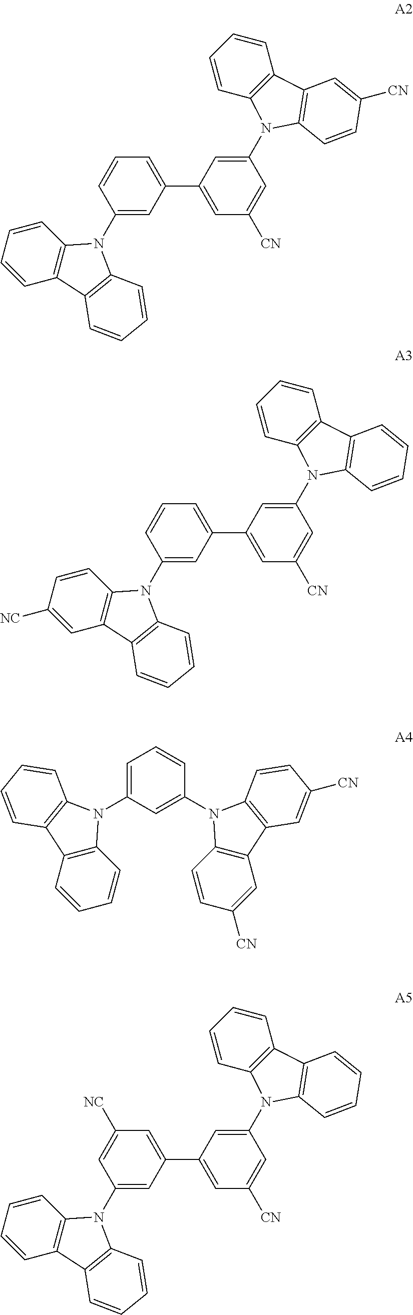 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1ccc2c(c1)c1cc(C#N)ccc1n2-c1cccc(-n2c3ccccc3c3ccccc32)c1 ; N#Cc1cc(-c2cc(C#N)cc(-n3c4ccccc4c4ccccc43)c2)cc(-n2c3ccccc3c3ccccc32)c1]

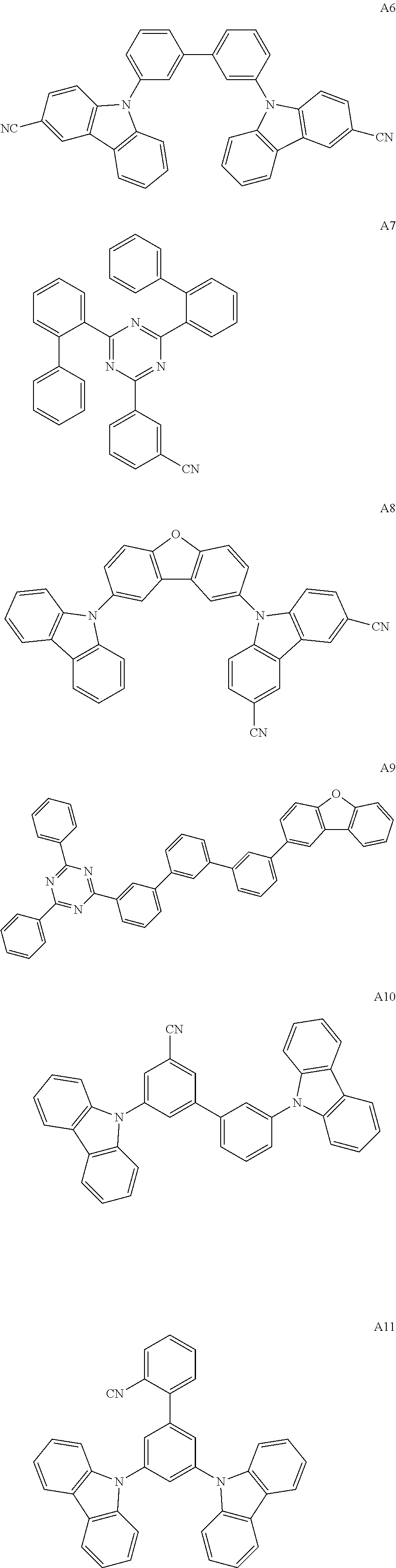

The dopant in the emission layer may include a phosphorescent dopant.

The phosphorescent dopant may be any suitable dopant capable of emitting light in accordance with a phosphorescent emission mechanism.

The phosphorescent dopant may be selected from a red phosphorescent dopant, a green phosphorescent dopant, and a blue phosphorescent dopant.

In an embodiment, the phosphorescent dopant may be a green phosphorescent dopant or a blue phosphorescent dopant, but embodiments are not limited thereto.

In some embodiments, the phosphorescent dopant may include an organometallic compound represented by Formula 81:

M(L₈₁)ₙ₈₁(L₈₂)ₙ₈₂ Formula 81

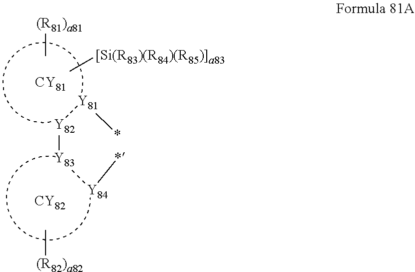

wherein, in Formulae 81 and 81A,
M may be selected from iridium (Ir), platinum (Pt), osmium (Os), titanium (Ti), zirconium (Zr), hafnium (Hf), europium (Eu), terbium (Tb), thulium (Tm), and rhodium (Rh),
L₈₁ may be a ligand represented by Formula 81A, n81 may be an integer from 1 to 3; when n81 is 2 or greater, at least two L₈₁ groups may be identical to or different from each other,
L₈₂ may be an organic ligand, n82 may be an integer from 0 to 4; when n82 is 2 or greater, at least two L₈₂ groups may be identical to or different from each other,
Y₈₁ to Y₈₄ may each independently be C or N,
Y₈₁ and Y₈₂ may be bound via a single bond or a double bond, Y₈₃ and Y₈₄ may be bound via a single bond or a double bond,
CY₈₁ and CY₈₂ may each independently be selected from a C₅-C₃₀ carbocyclic group and a C₁-C₃₀ heterocyclic group,
CY₈₁ and CY₈₂ may optionally and additionally be bound via an organic linking group,
R₈₁ to R₈₅ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —Si(Q₈₁)(Q₈₂)(Q₈₃), —N(Q₈₄)(Q₈₅), —B(Q₈₆)(Q₈₇), and —P(═O)(Q₈₈)(Q₈₉),
a81 to a83 may each independently be an integer selected from 0 to 5,
when a81 is 2 or greater, at least two R₈₁ groups may be identical to or different from each other,
when a82 is 2 or greater, at least two R₈₂ groups may be identical to or different from each other,
when a81 is 2 or greater, R₈₁ groups that are adjacent to each other may optionally be bound to form a saturated or unsaturated ring,
when a82 is 2 or greater, R₈₂ groups that are adjacent to each other may optionally be bound to form a saturated or unsaturated ring,
in Formula 81A, * and *′ each indicate a binding site to M in Formula 81, and
at least one substituent of the substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₇-C₆₀ arylalkyl group, substituted C₁-C₆₀ heteroaryl group, substituted C₁-C₆₀ heteroaryloxy group, substituted C₁-C₆₀ heteroarylthio group, substituted C₂-C₆₀ heteroarylalkyl group, substituted monovalent non-aromatic condensed polycyclic group, and substituted monovalent non-aromatic condensed heteropolycyclic group may be selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, and —Si(Q₁)(Q₉₂)(Q₉₃),
wherein Q₈₁ to Q₈₉ and Q₉₁ to Q₉₃ may each independently be selected from hydrogen, deuterium, a C₁-C₆₀ alkyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆ heteroaryl group, a monovalent non-aromatic condensed polycyclic group, and a monovalent non-aromatic condensed heteropolycyclic group.

In an embodiment, in Formula 81A,
a83 may be 1 or 2, and
R₈₃ to R₈₅ may each independently be selected from:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, and —CD₂CDH₂,
an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group; and
an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group, each substituted with at least one selected from deuterium, a C₁-C₁₀ alkyl group, and a phenyl group, but embodiments are not limited thereto.

In one or more embodiments, in Formula 81A,
Y₈₁ may be N, Y₈₂ and Y₈₃ may each be C, Y₈₄ may be N or C, and
CY₈₁ and CY₈₂ may each independently be selected from a cyclopentadiene group, a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicene group, a coronene group, an ovalene group, a pyrrole group, an isoindole group, an indole group, an indazole group, a pyrazole group, an imidazole group, a triazole group, an oxazole group, an isoxazole group, an oxadiazole group, a thiazole group, an isothiazole group, a thiadiazole group, a purine group, a furan group, a thiophene group, a pyridine group, a pyrimidine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, a benzofuran group, a benzothiophene group, an iso-benzothiazole group, a benzoxazole group, an isobenzoxazole group, a benzocarbazole group, a dibenzocarbazole group, an imidazopyridine group, an imidazopyrimidine group, a dibenzofuran group, a dibenzothiophene group, a dibenzothiophene sulfone group, a carbazole group, a dibenzosilole group, a 2,3-dihydro-1H-imidazole group, and a 2,3-dihydro-1H-imidazopyrazine group.

In one or more embodiments, in Formula 81A, Y₈₁ may be N, Y₈₂ to Y₈₄ may each be C, CY₈₁ may be selected from 5-membered rings including two N atoms as ring-forming atoms, and CY₈₂ may be selected from a benzene group, a naphthalene group, a fluorene group, a dibenzofuran group, and a dibenzothiophene group, but embodiments are not limited thereto.

In one or more embodiments, in Formula 81A, Y₈₁ may be N, Y₈₂ to Y₈₄ may each be C, CY₈₁ may be an imidazole group or a 2,3-dihydro-1H-imidazole group, and CY₈₂ may be selected from a benzene group, a naphthalene group a fluorene group, a dibenzofuran group, and a dibenzothiophene group, but embodiments are not limited thereto.

In one or more embodiments, in Formula 81A,
Y₈₁ may be N, Y₈₂ to Y₈₄ may each be C,
CY₈₁ may be selected from a pyrrole group, a pyrazole group, an imidazole group, a triazole group, an oxazole group, an isoxazole group, an oxadiazole group, a thiazole group, an isothiazole group, a thiadiazole group, a pyridine group, a pyrimidine group, a quinoline group, an isoquinoline group, a benzoquinoline group, a phthalazine group, a naphthyridine group, a quinoxaline group, a quinazoline group, a cinnoline group, a benzimidazole group, an iso-benzothiazole group, a benzoxazole group, and an isobenzoxazole group, and
CY₈₂ may be selected from a cyclopentadiene group, a benzene group, a naphthalene group, a fluorene group, a benzofluorene group, a dibenzofluorene group, a phenanthrene group, an anthracene group, a triphenylene group, a pyrene group, a chrysene group, a perylene group, a benzofuran group, a benzothiophene group, a benzocarbazole group, a dibenzocarbazole group, a dibenzofuran group, a dibenzothiophene group, a dibenzothiophene sulfone group, a carbazole group, and a dibenzosilole group.

In one or more embodiments, in Formula 81A, Y₈₁, Y₈₃, and Y₈₄ may each be C, Y₈₂ may be N, CY₈, may be selected from a) a condensed ring in which i) a 5-membered ring including at least one N as a ring-forming atom may be condensed with ii) a 6-membered ring selected from a benzene group, a pyridine group, a pyrazine group, a pyrimidine group, and a pyridazine group; and b) a 5-membered ring including at least one N as a ring-forming atom, and CY₈₂ may be selected from a benzene group, a naphthalene group, a fluorene group, a dibenzofuran group, a dibenzothiophene group, a pyridine group, a pyrimidine group, a quinoline group, and an isoquinoline group, but embodiments are not limited thereto.

In one or more embodiments, in Formula 81A,
R₈₁ and R₈₂ may each independently be selected from:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, and a C₁-C₂₀ alkoxy group;
a C₁-C₂₀ alkyl group and a C₁-C₂₀ alkoxy group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group; and
—B(Q₈₆)(Q₈₇) and —P(═O)(Q₈₈)(Q₈₉),
wherein Q₈₆ to Q₈₉ may each independently be selected from:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, and —CD₂CDH₂;
an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group; and
an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group, each substituted with at least one selected from deuterium, a C₁-C₁₀ alkyl group, and a phenyl group.

In one or more embodiments, in Formula 81A, R₈₁ and R₈₂ may each independently be selected from
hydrogen, deuterium, —F, a cyano group, a nitro group, —SF₅, a methyl group, an ethyl group, an n-propyl group, an iso-propyl group, an n-butyl group, an iso-butyl group, a sec-butyl group, a tert-butyl group, an n-pentyl group, an isopentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, a pyrimidinyl group, a dibenzothiophenyl group, and a dibenzofuranyl group;
a methyl group, an ethyl group, an n-propyl group, an iso-propyl group, an n-butyl group, an iso-butyl group, a sec-butyl group, a tert-butyl group, an n-pentyl group, an isopentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, a pyrimidinyl group, a dibenzothiophenyl group, and a dibenzofuranyl group, each substituted with at least one selected from deuterium, —F, —CD₃, —CD₂H, —CDH₂, —CF₃, —CF₂H, —CFH₂, a cyano group, a nitro group, a C₁-C₁₀ alkyl group, a C₁-C₁₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, a pyrimidinyl group, a dibenzothiophenyl group, and a dibenzofuranyl group; and
—B(Q₈₆)(Q₈₇) and —P(═O)(Q₈₈)(Q₈₉),
wherein Q₈₆ to Q₈₉ may each independently be selected from:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, and —CD₂CDH₂;
an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group; and
an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group, each substituted with at least one selected from deuterium, a C₁-C₁₀ alkyl group, and a phenyl group.

In one or more embodiments, in Formula 81A, at least one R₈₁ in the number of a81, at least one R₈₂ in the number of a82, or any combination thereof may be a cyano group.

In one or more embodiments, in Formula 81A, Y₈₁ may be N; Y₈₂ to Y₈₄ may each be C; CY₈₁ may be an imidazole group or a 2,3-dihydro-1H-imidazole group; CY₈₂ may be selected from a benzene group, a naphthalene group, a fluorene group, a dibenzofuran group, and a dibenzothiophene group; and at least one R₈₁ in the number of a81, at least one R₈₂ in the number of a82, or any combination thereof may be a cyano group.

In one or more embodiments, in Formula 81A, at least one R₈₂ in the number of a 82 may be a cyano group.

In one or more embodiments, in Formula 81A, at least one R₈₁ in the number of a81, at least one R₈₂ in the number of a82, or any combination thereof may be deuterium.

In one or more embodiments, in Formula 81A, CY₈₁ and CY₈₂ may additionally be bound via an organic linking group. Examples of the organic linking group may include a C₂-C₅ alkylene group, a C₂-C₅ alkenylene group,

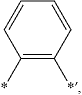

a C₂-C₅ alkylene group substituted with at least one R₈₁ₐ, a C₂-C₅ alkenylene group substituted with at least one R₈₁ₐ, and

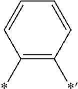

substituted with at least one R₈₁ₐ, but embodiments are not limited thereto. R₈₁ₐ may be the same as described herein with reference to R₈₁.

In some embodiments, in Formula 81, L₈₁ may be selected from ligands represented by Formulae 81A-1 to 81A-8, but embodiments are not limited thereto:

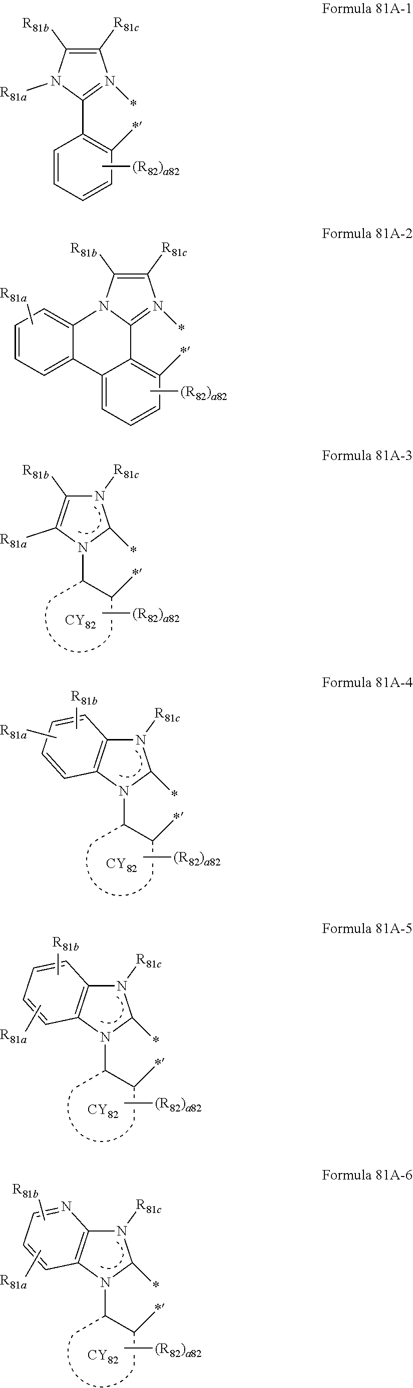

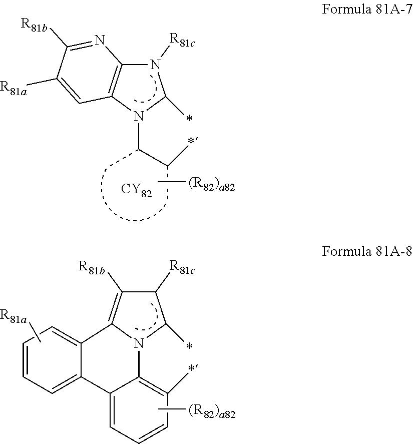

wherein in Formulae 81A-1 to 81A-8,
CY₈₂, R₈₂, a82, *, and *′ may be the same as those described herein, and
R₈₁ₐ, R_{81b}, and R_{81c} may each be the same as described herein with reference to R₈₁.

In some embodiments, in Formulae 81A-1 to 81A-8, at least one of R₈₁ₐ, R_{81b}, R_{81c}, and R₈₂ in the number of a82 may each be a cyano group, but embodiments are not limited thereto.

In one or more embodiments, in Formula 81, L₈₂ may be selected from ligands represented by Formulae 3-1(1) to 3-1(60), 3-1(61) to 3-1(69), 3-1(71) to 3-1(79), 3-1(81) to 3-1(88), 3-1(91) to 3-1(98), and 3-1(101) to 3-1(114):

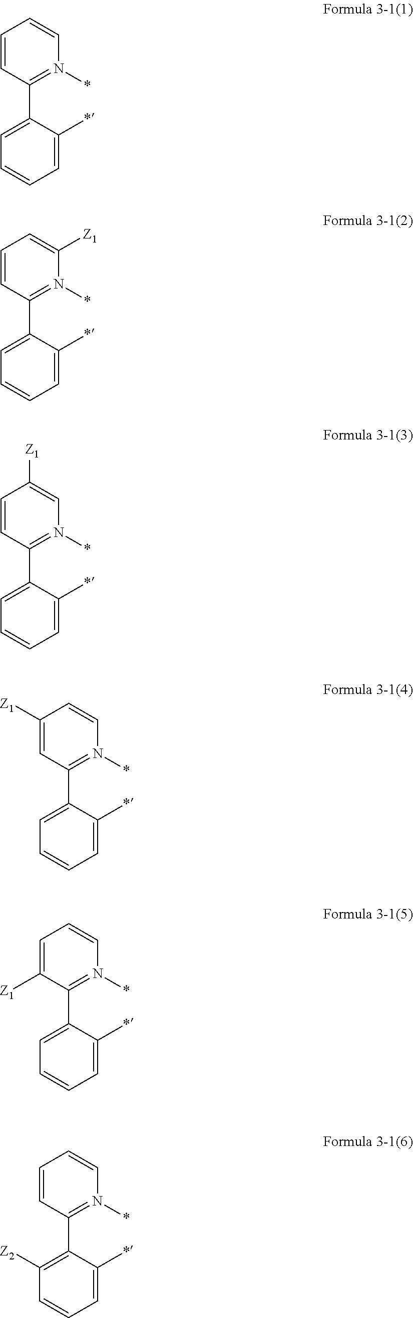

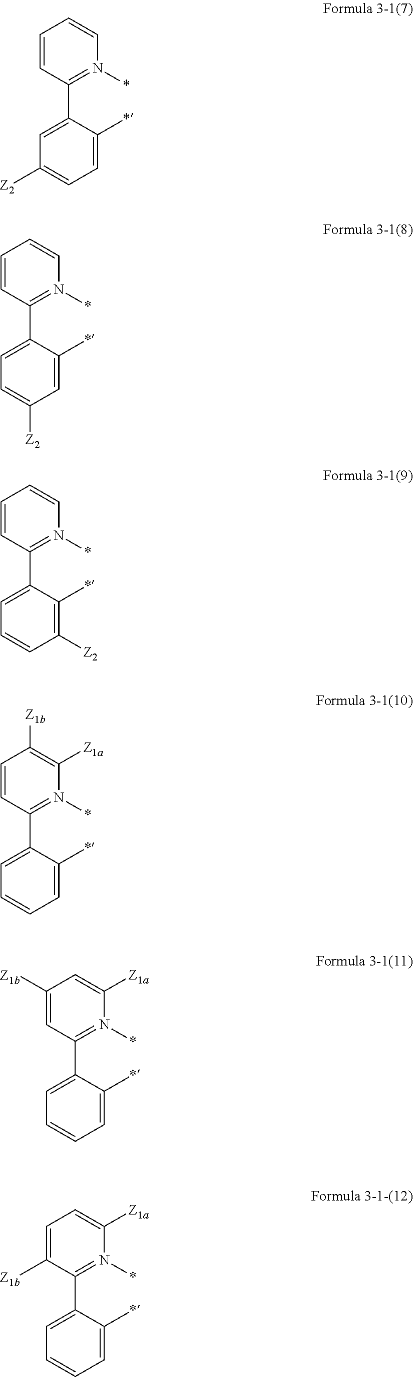

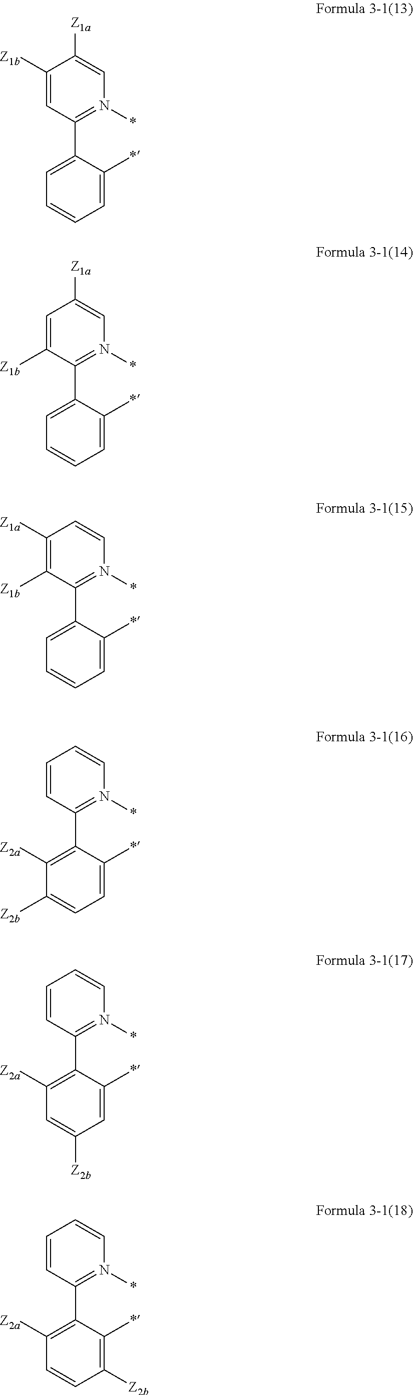

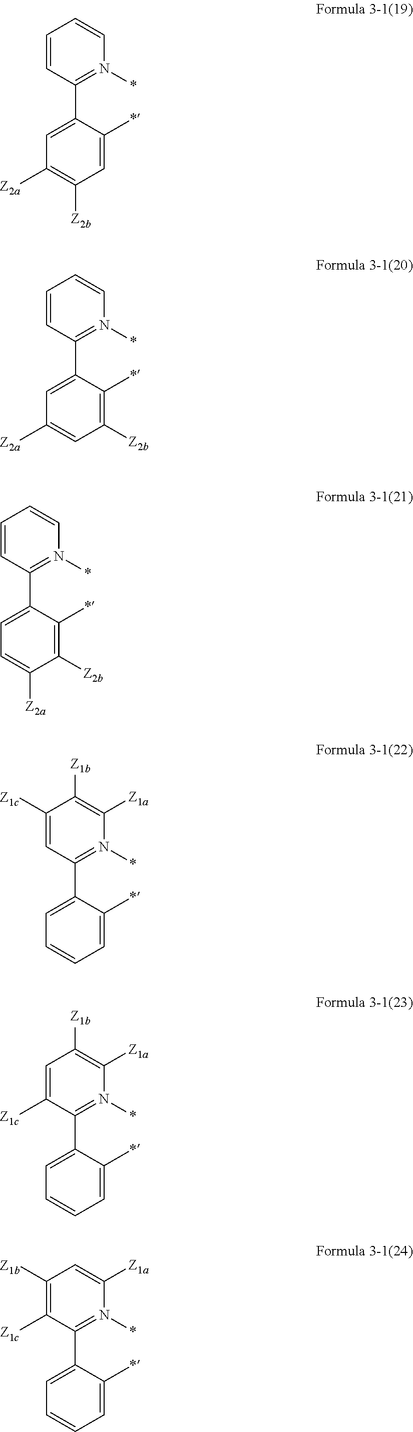

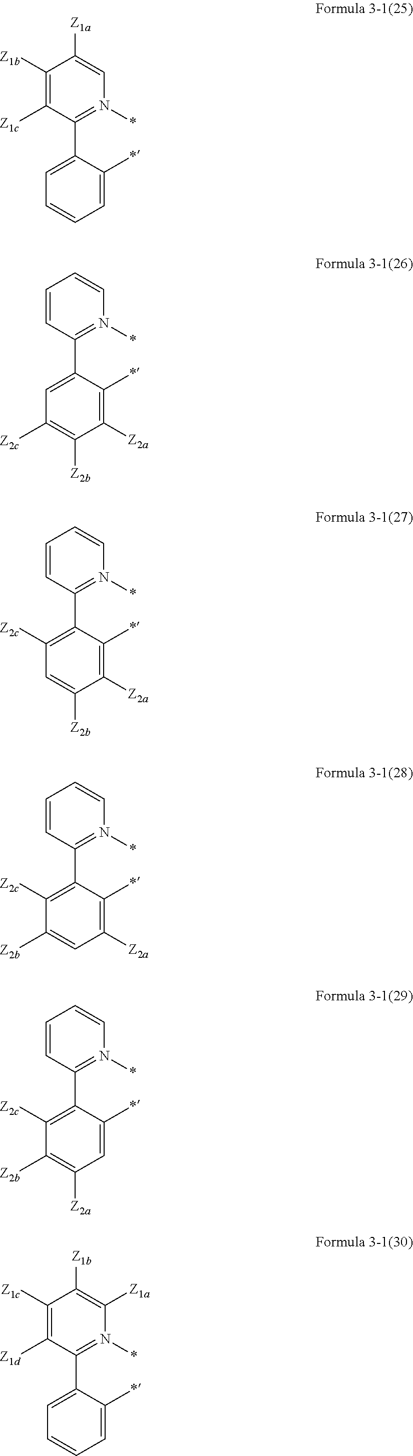

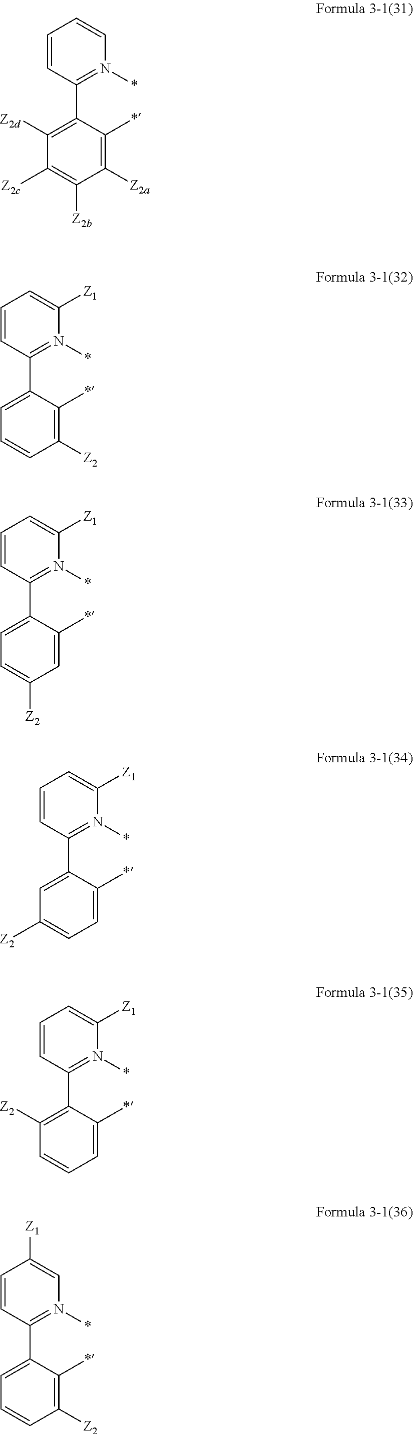

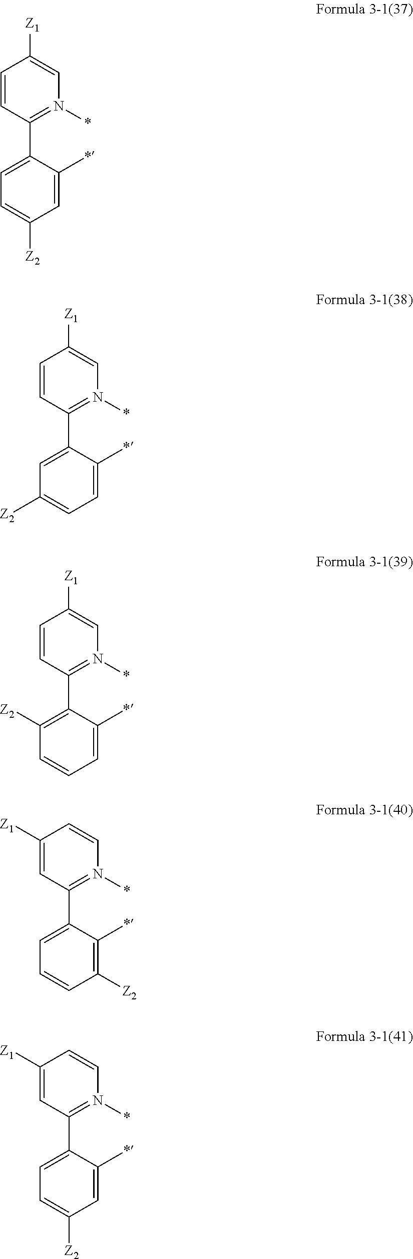

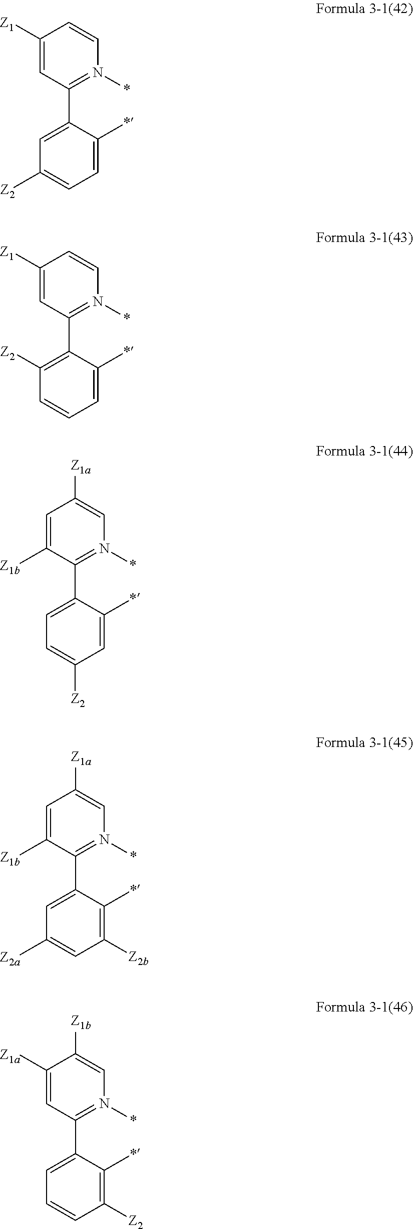

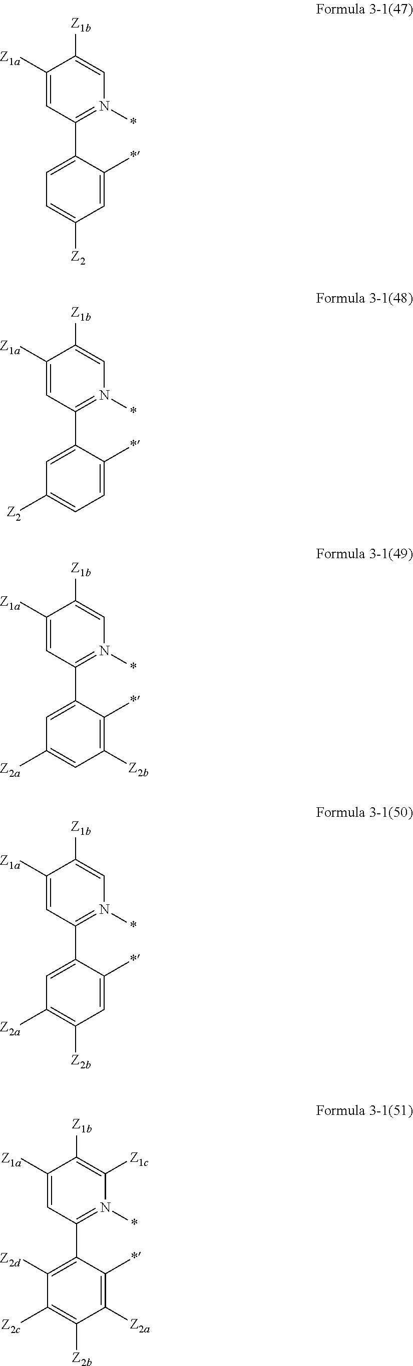

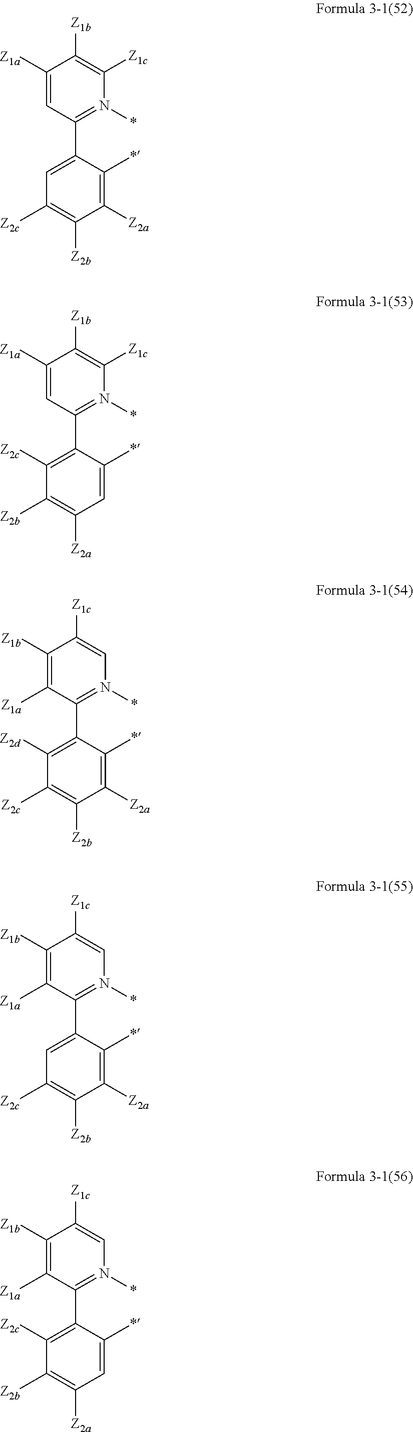

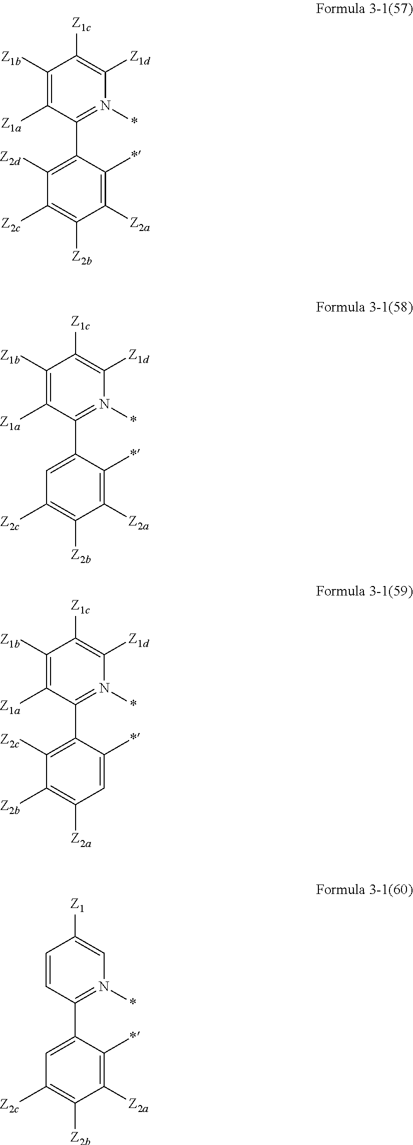

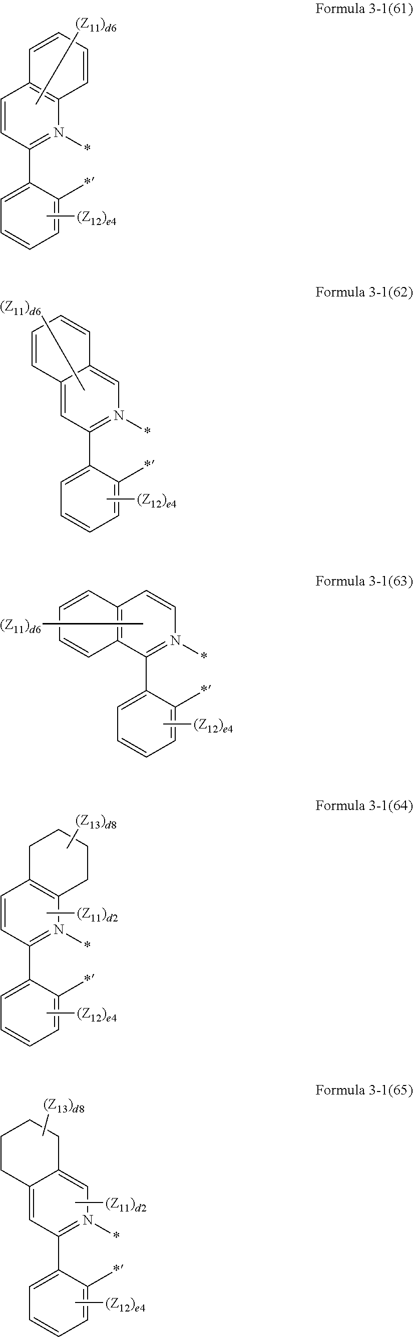

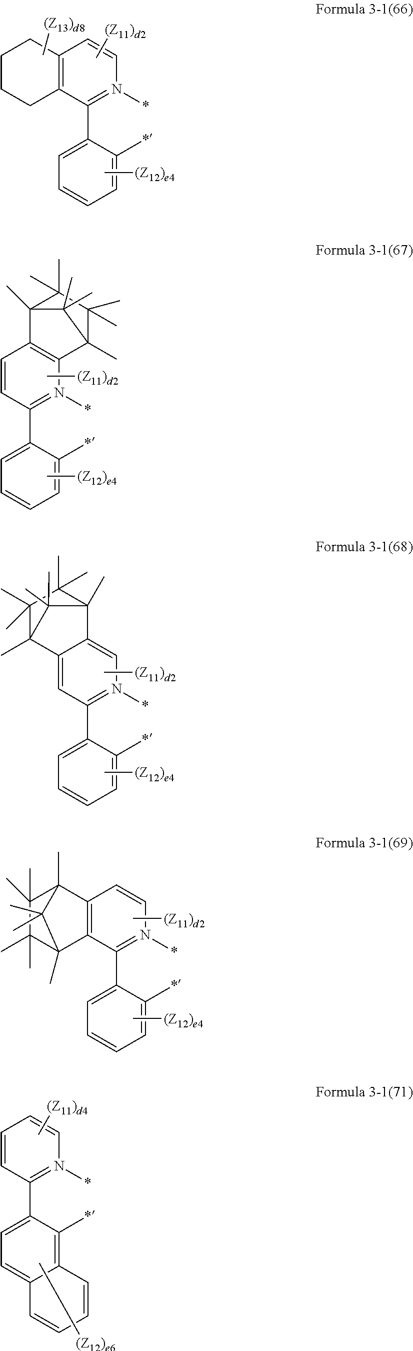

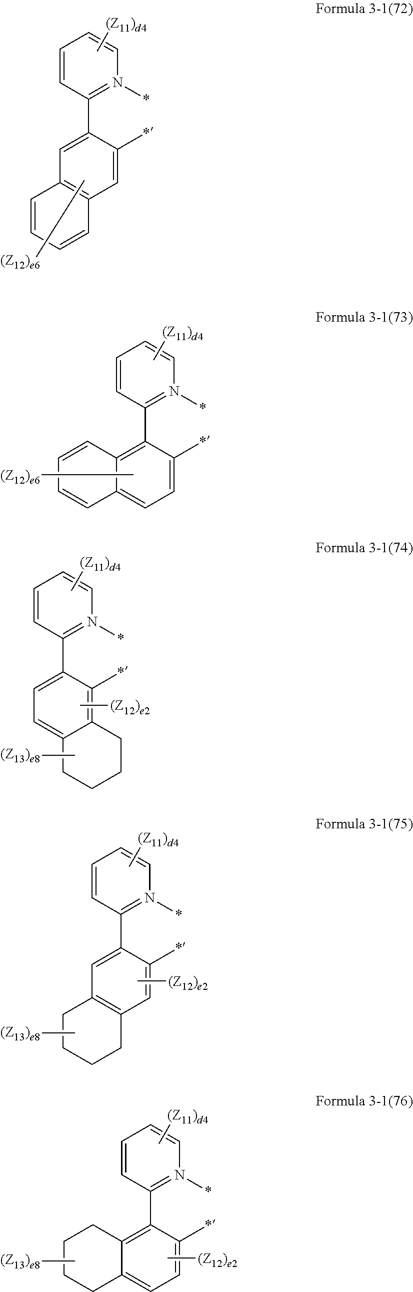

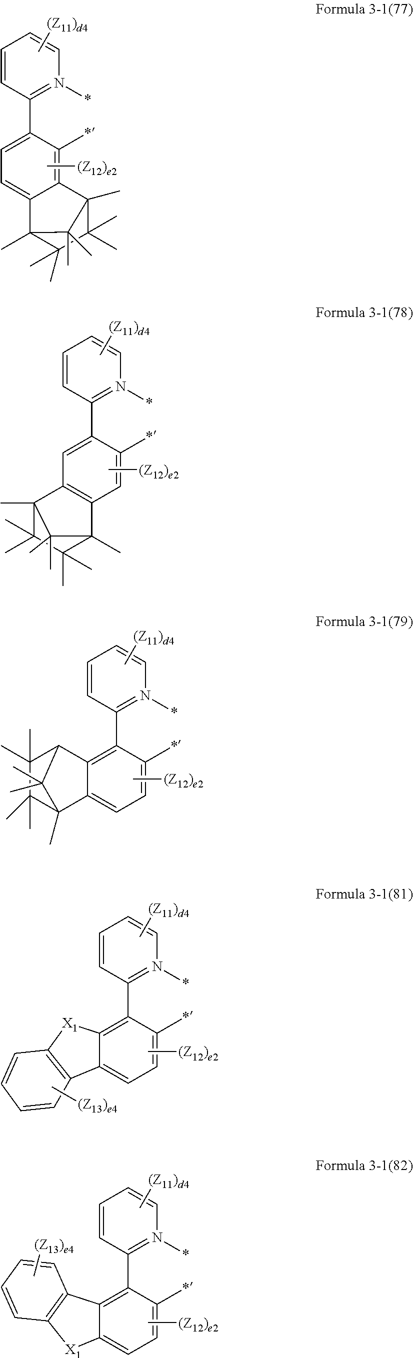

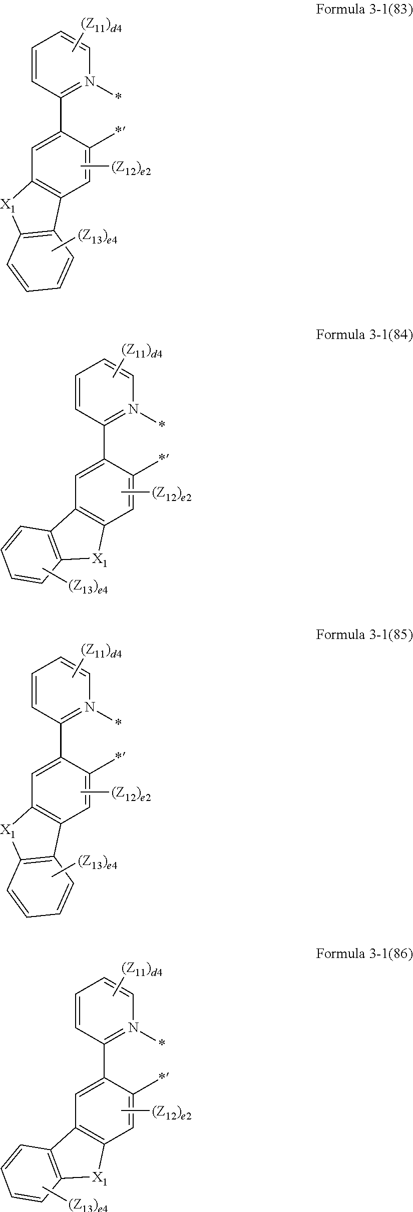

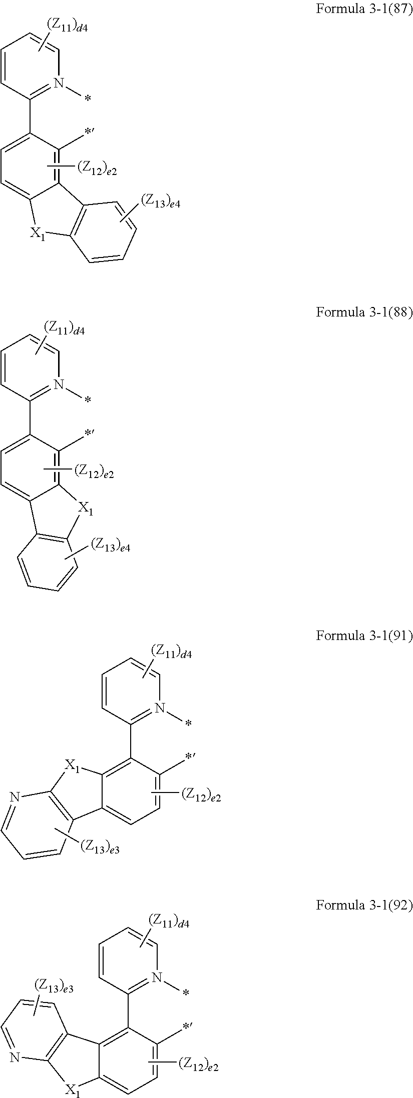

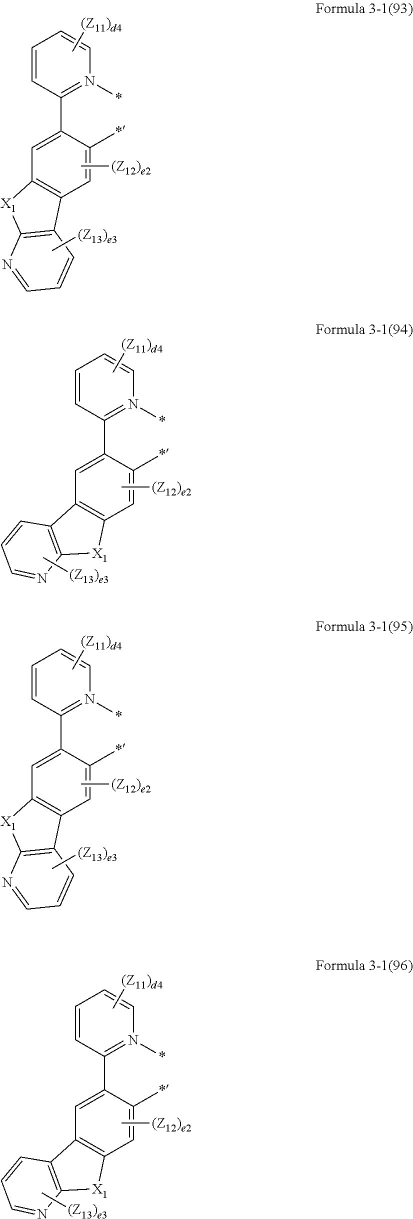

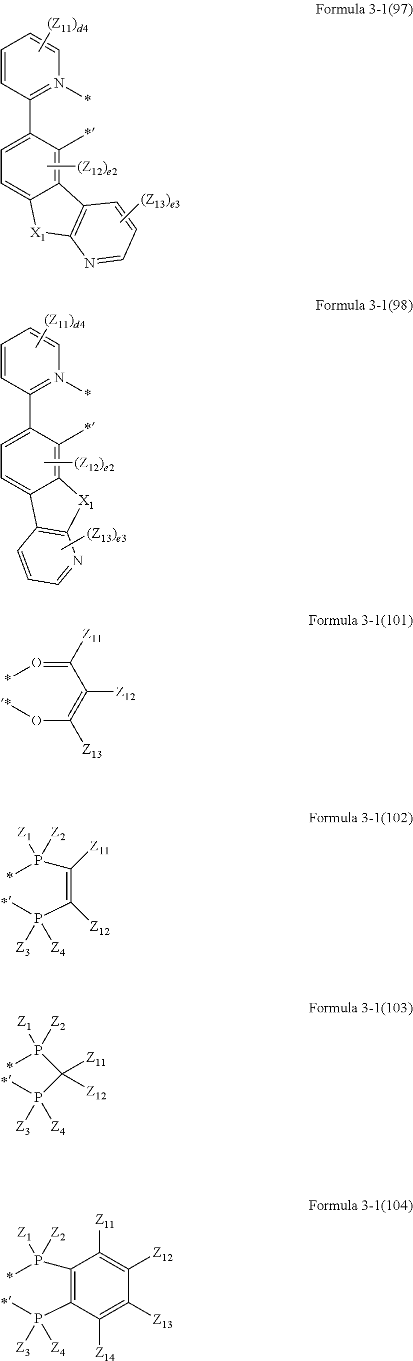

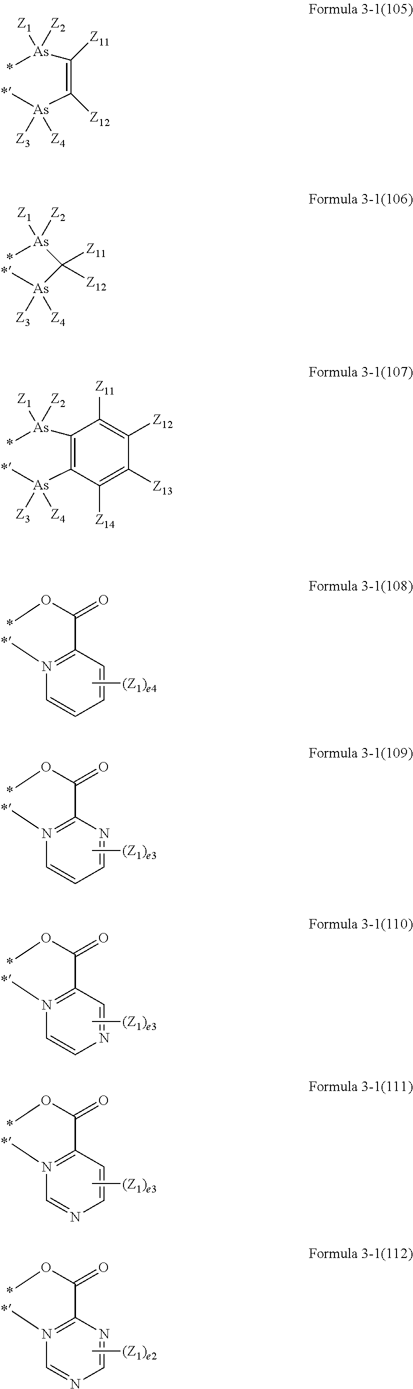

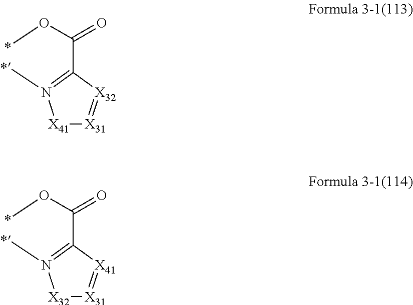

wherein, in Formulae 3-1(1) to 3-1(60), 3-1(61) to 3-1(69), 3-1(71) to 3-1(79), 3-1(81) to 3-1(88), 3-1(91) to 3-1(98), and 3-1(101) to 3-1(114),
X₁ may be O, S, C(Z₂₁)(Z₂₂), or N(Z₂₃),
X₃₁ may be N or C(Z₁ₐ), X₃₂ may be N or C(Z_{1b}),
X₄₁ may be O, S, N(Z₁ₐ), or C(Z₁ₐ)(Z_{1b}),
Z₁ to Z₄, Z₁ₐ, Z_{1b}, Z_{1c}, Z_{1d}, Z₂ₐ, Z_{2b}, Z_{2c}, Z_{2d}, Z₁₁ to Z₁₄, and Z₂₁ to Z₂₃ may each independently be selected from
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, and a C₁-C₂₀ alkoxy group,
a C₁-C₂₀ alkyl group and a C₁-C₂₀ alkoxy group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group; and
—B(Q₈₆)(Q₈₇) and —P(═O)(Q₈₈)(Q₈₉),
wherein Q₈₆ to Q₈₉ may each independently be selected from
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, and —CD₂CDH₂;
an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group; and
an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group, each substituted with at least one selected from deuterium, a C₁-C₁₀ alkyl group, and a phenyl group,
d2 and e2 may each independently be an integer selected from 0 to 4,
e3 may be an integer selected from 0 to 3,
d4 and e4 may each independently be an integer selected from 0 to 4,
d6 and e6 may each independently be an integer selected from 0 to 6,
d8 and e8 may each independently be an integer selected from 0 to 8, and
* and *′ each indicate a binding site to M in Formula 1.

In one or more embodiments, in Formula 81, M may be Ir, and a sum of n81 and n82 may be 3. In one or more embodiments, in Formula 81, M may be Pt, and a sum of n81 and n82 may be 2.

In one or more embodiments, the organometallic compound represented by Formula 81 may be neutral, and may not include ion pairs of cations and anions.

In one or more embodiments, in Formula 81A,
Y₈₁ may be N,
Y₈₂ to Y₈₄ may each be N,
CY₈₁ may be an imidazole group, and
CY₈₂ may be a benzene group, but embodiments are not limited thereto.

In one or more embodiments, in Formulae 81 and 81A,
M may be Ir,
n81 may be 2 or 3,
a81 and a82 may each independently be an integer from 0 to 3,
a83 may be 0,
R⁸¹ may be selected from
a C₁-C₁₀ alkyl group and a phenyl group; and
a C₁-C₁₀ alkyl group and a phenyl group, each substituted with at least one selected from deuterium and a C₁-C₁₀ alkyl group, and
at least one R₈₂ in the number of a82 may be a cyano group, but embodiments are not limited thereto.

In one or more embodiments, the dopant in the emission layer may include at least one selected from Compounds PD1 to PD83 and PD85 to PD116, but embodiments are not limited thereto:

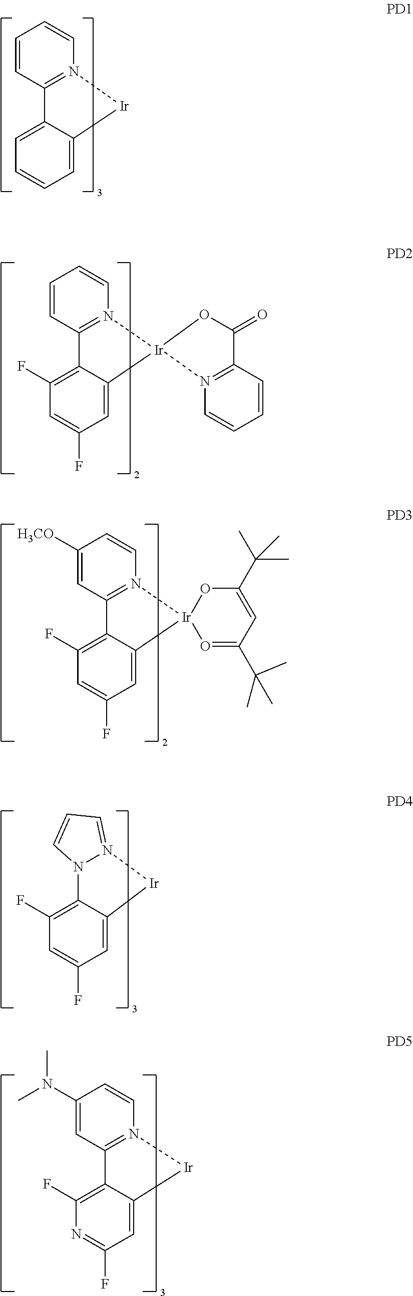

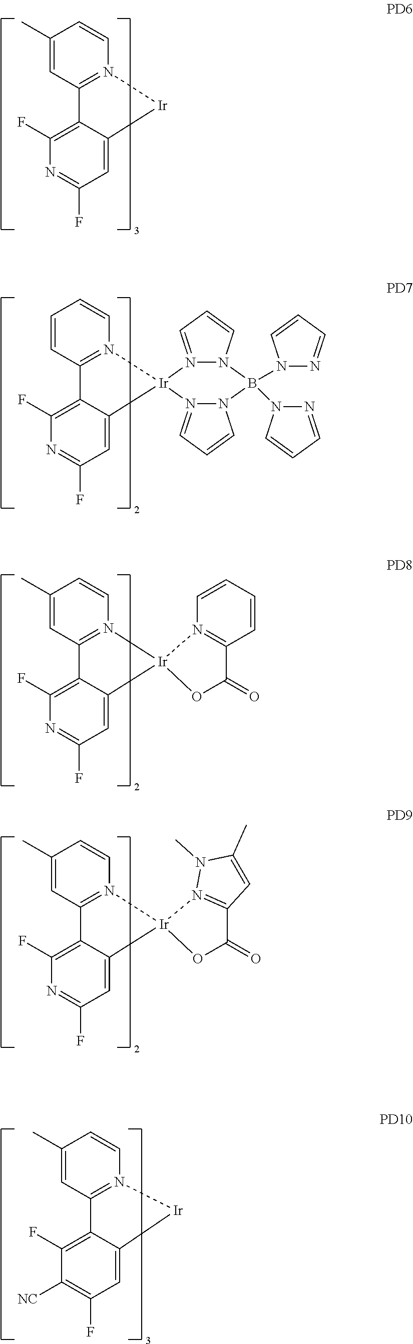

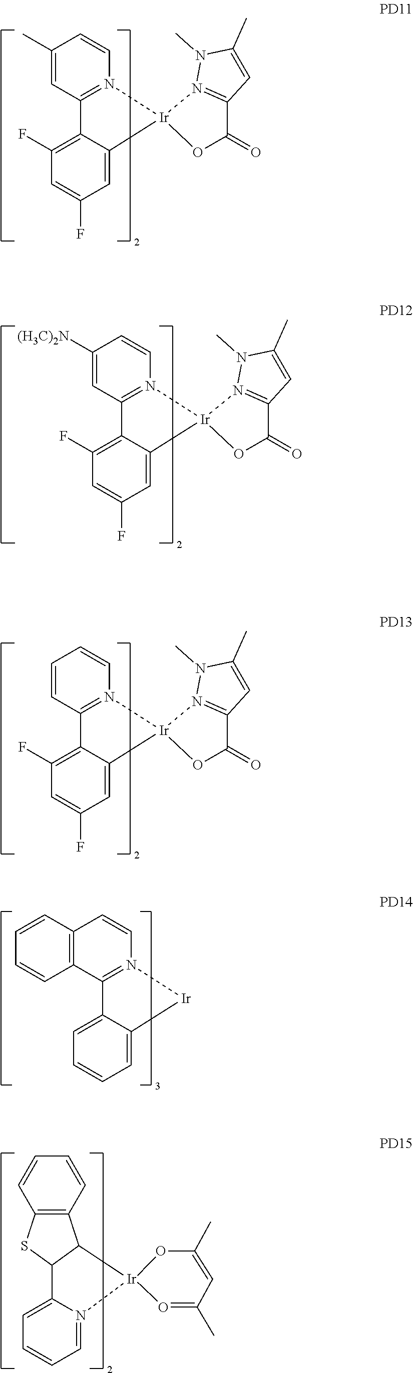

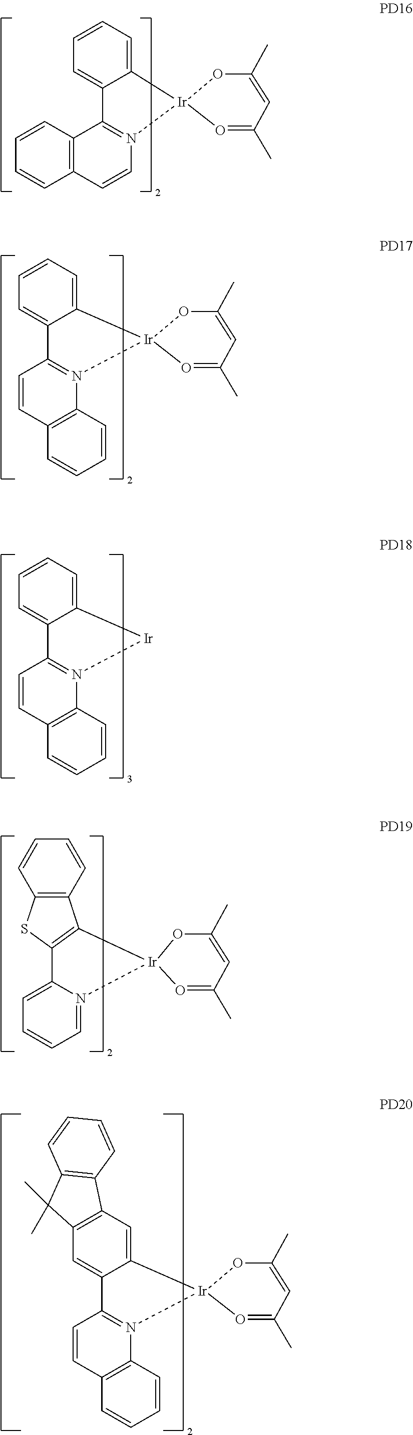

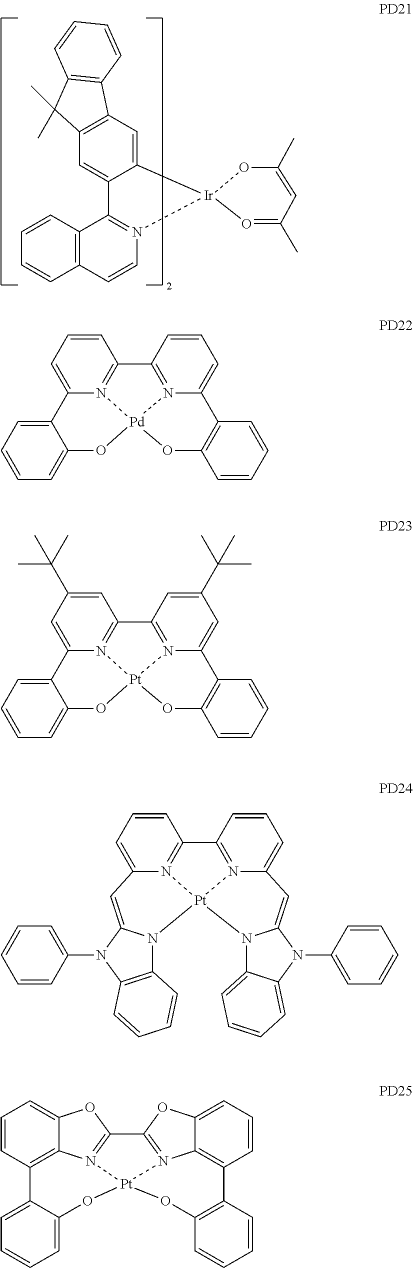

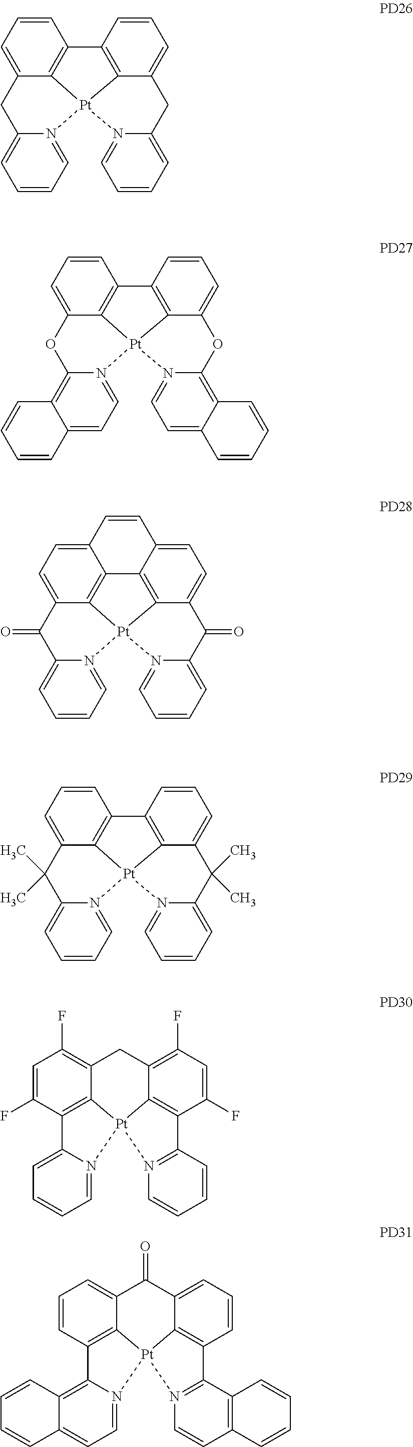

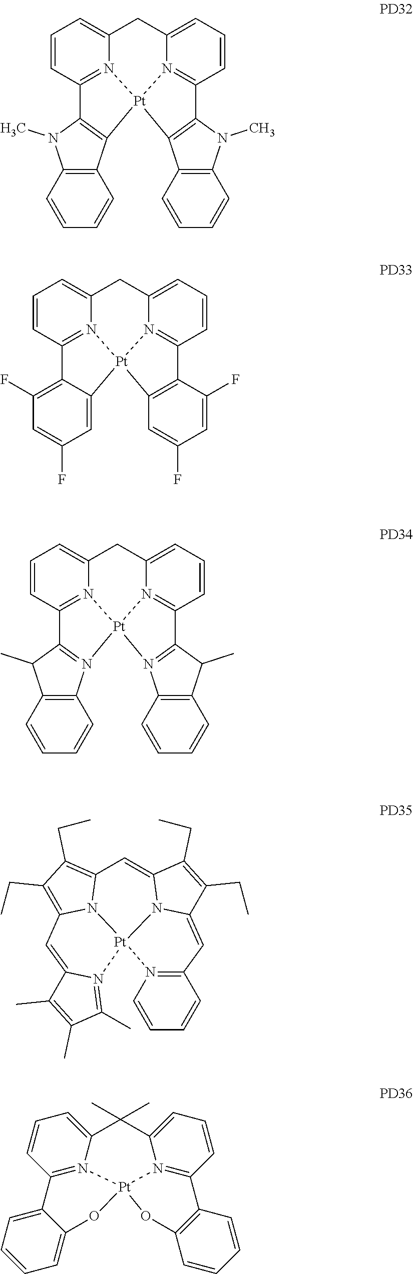

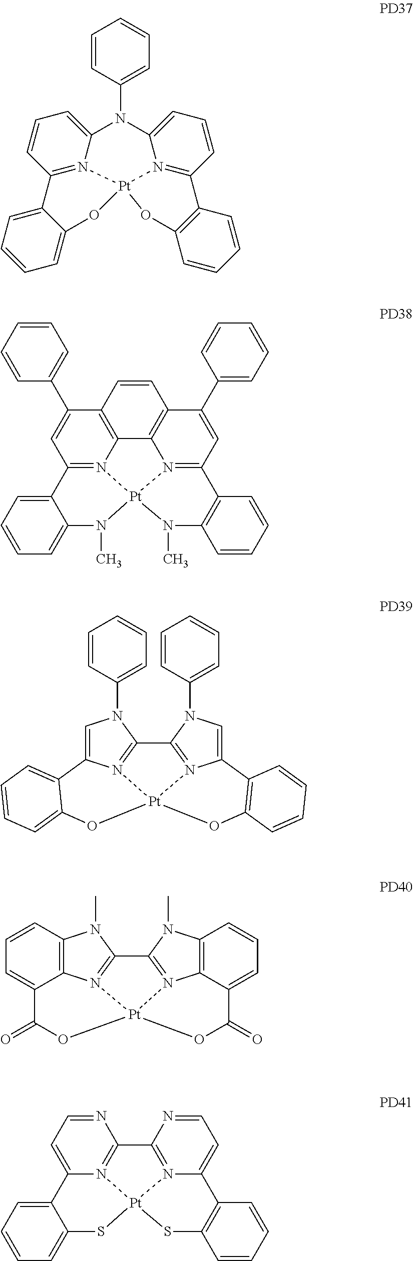

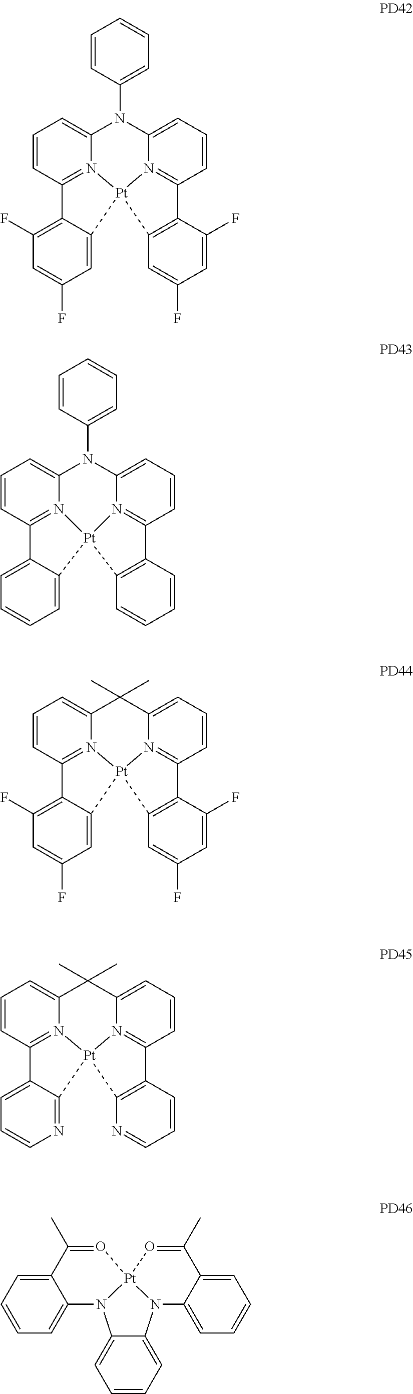

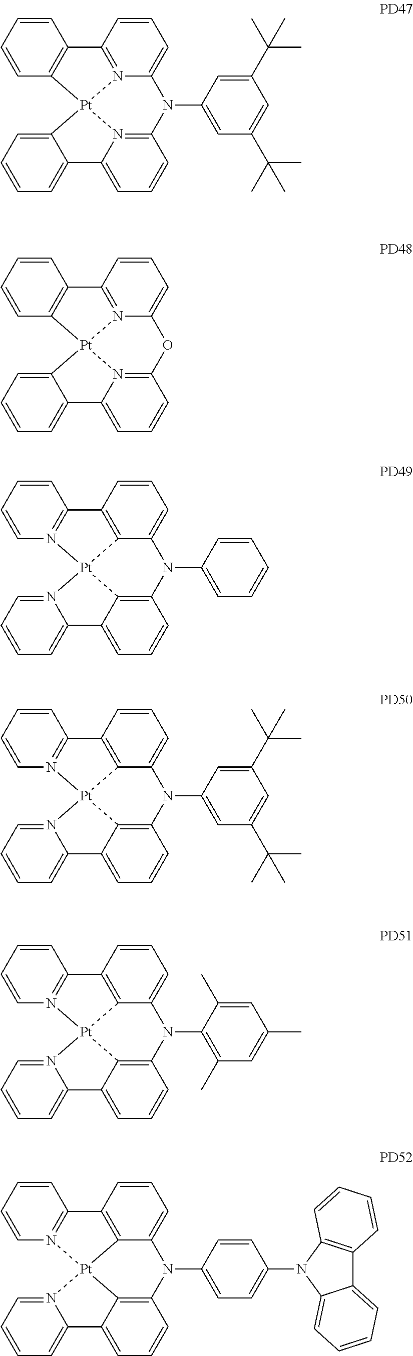

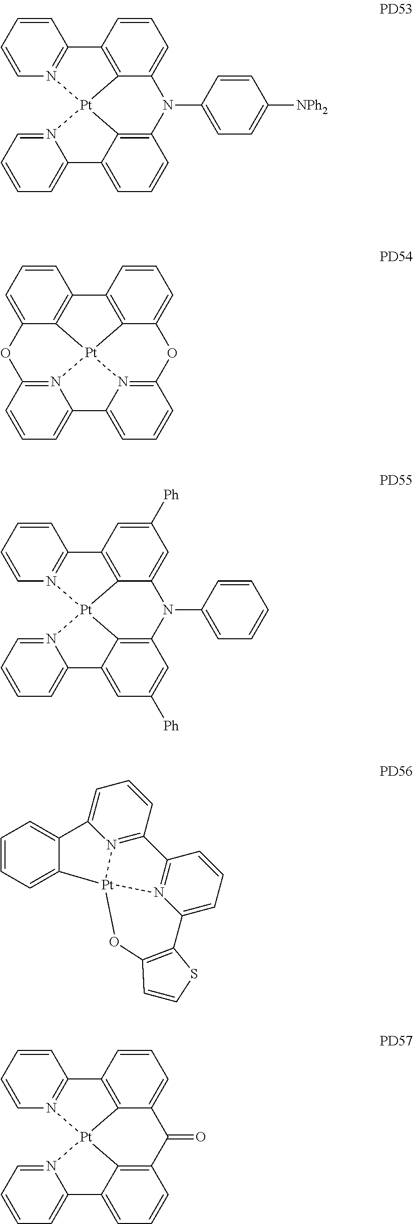

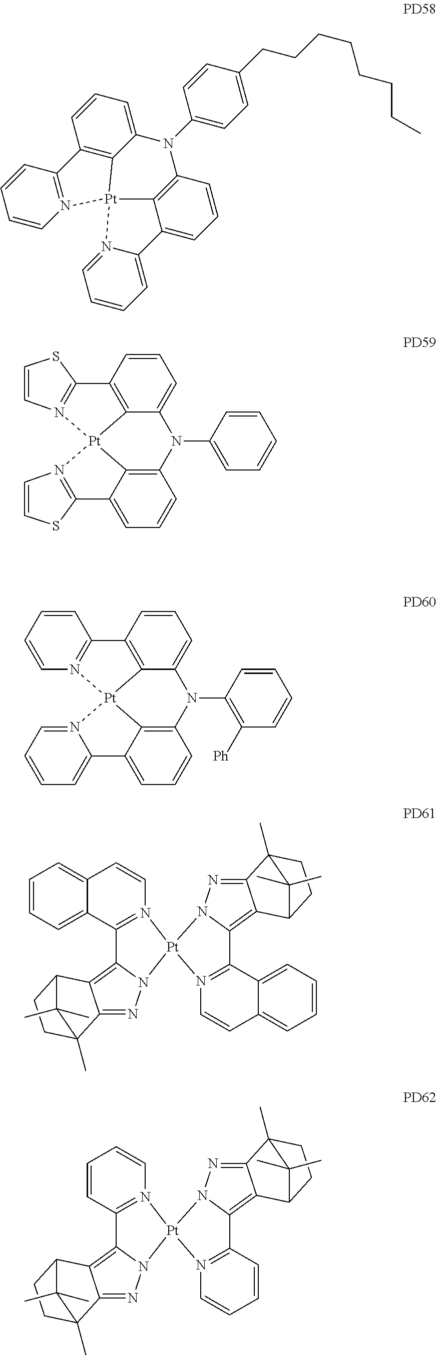

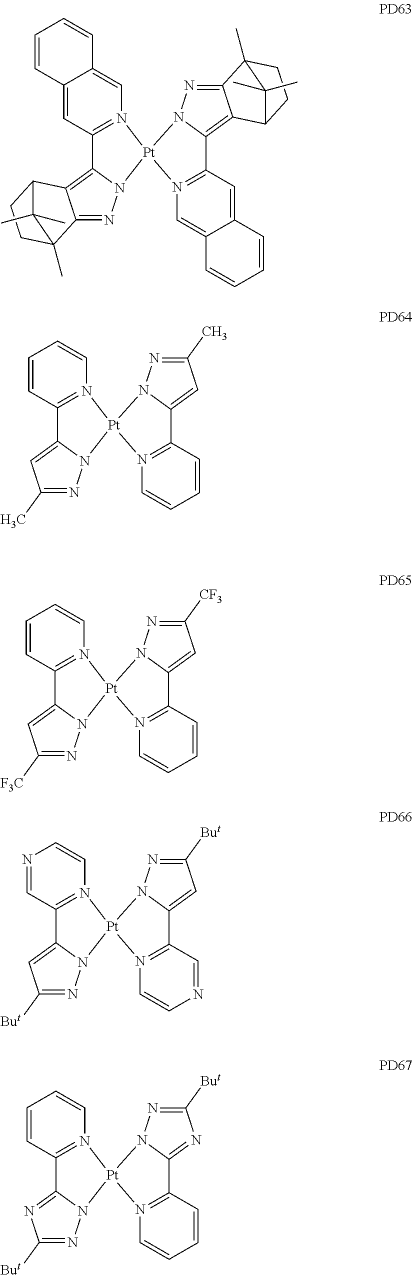

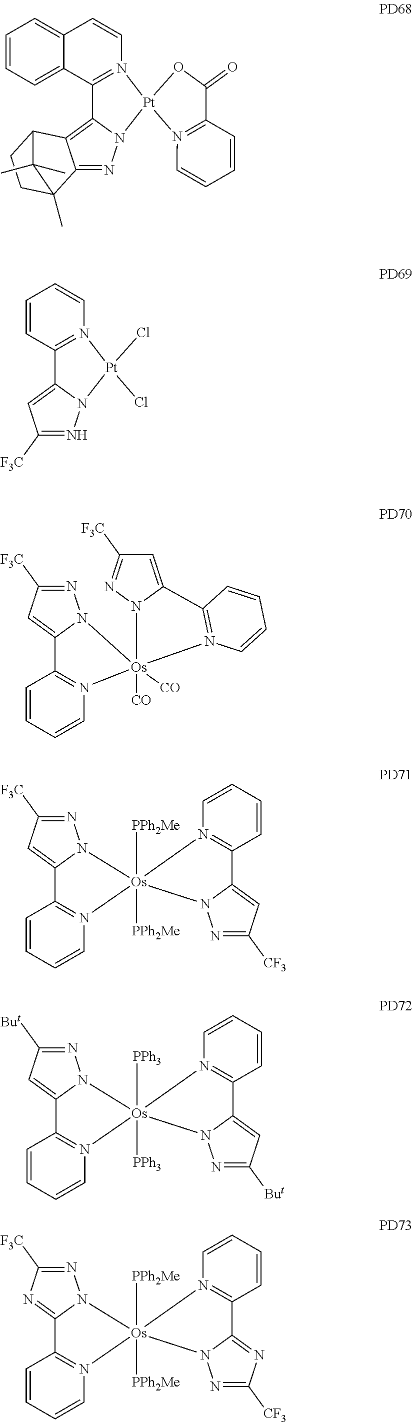

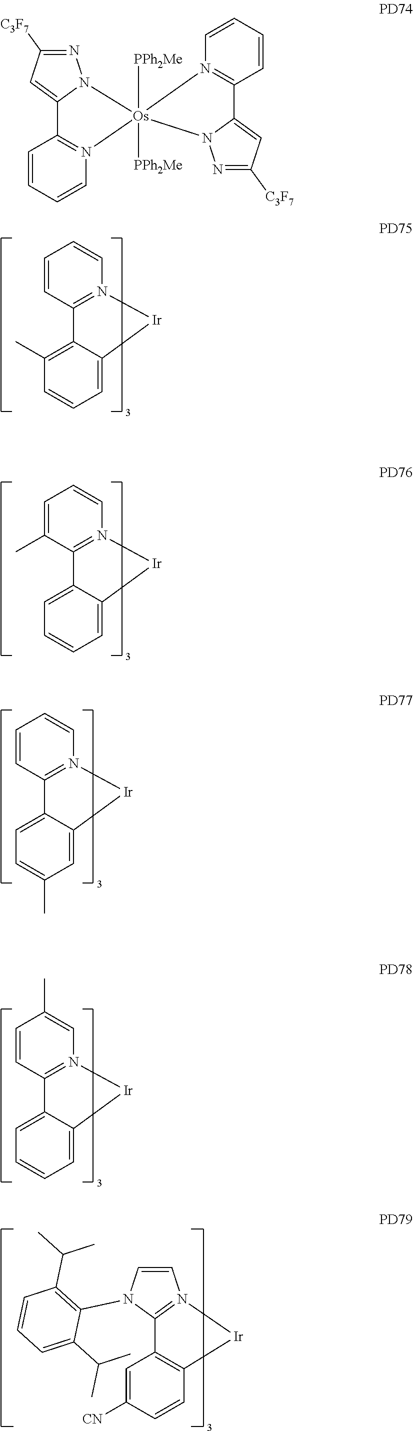

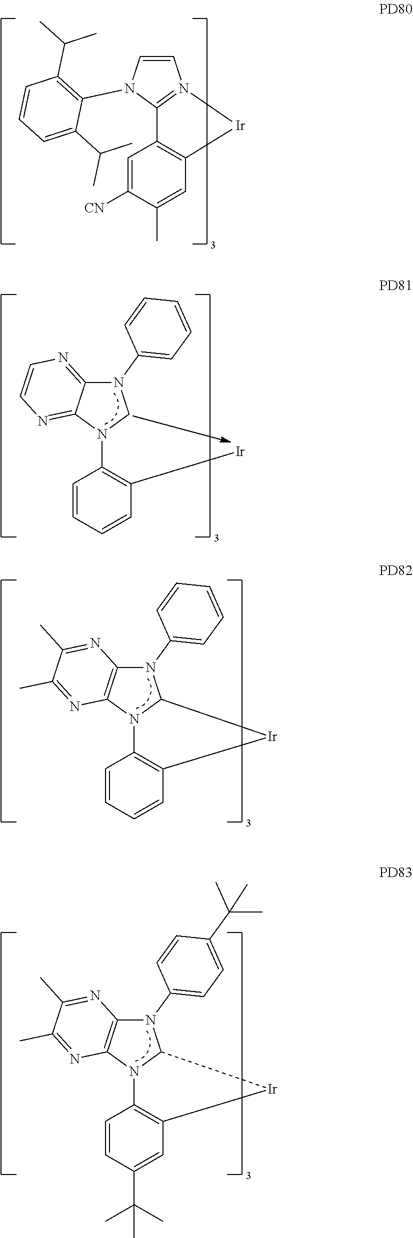

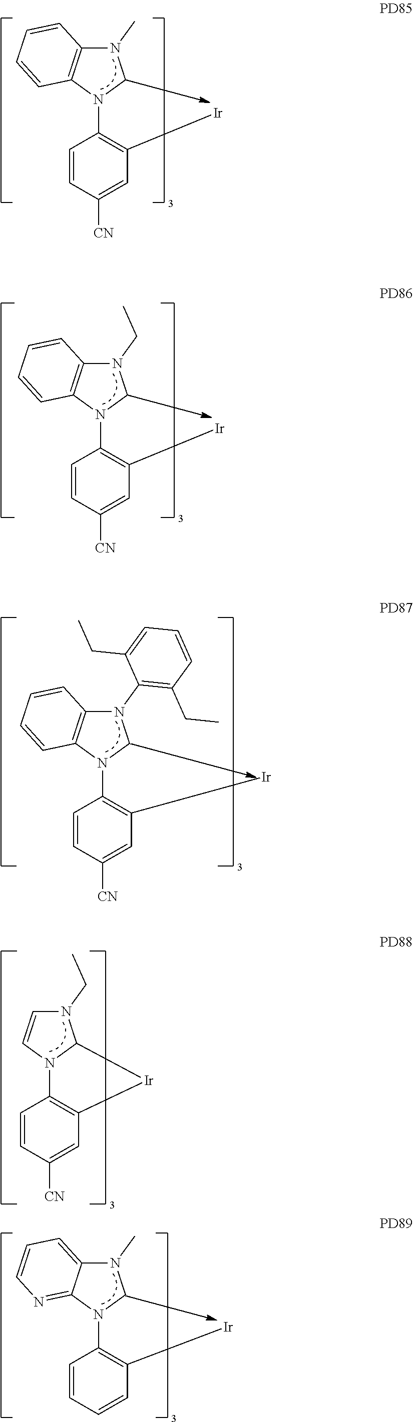

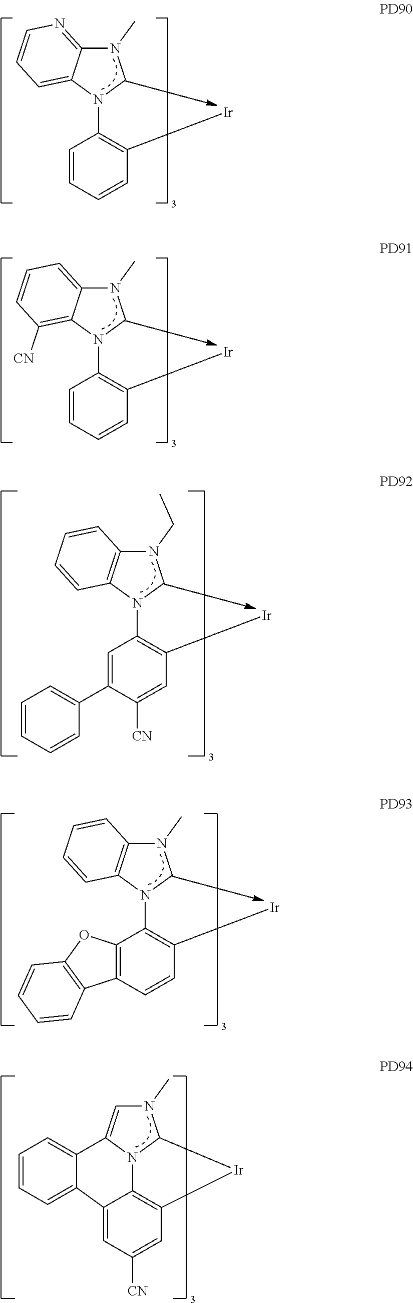

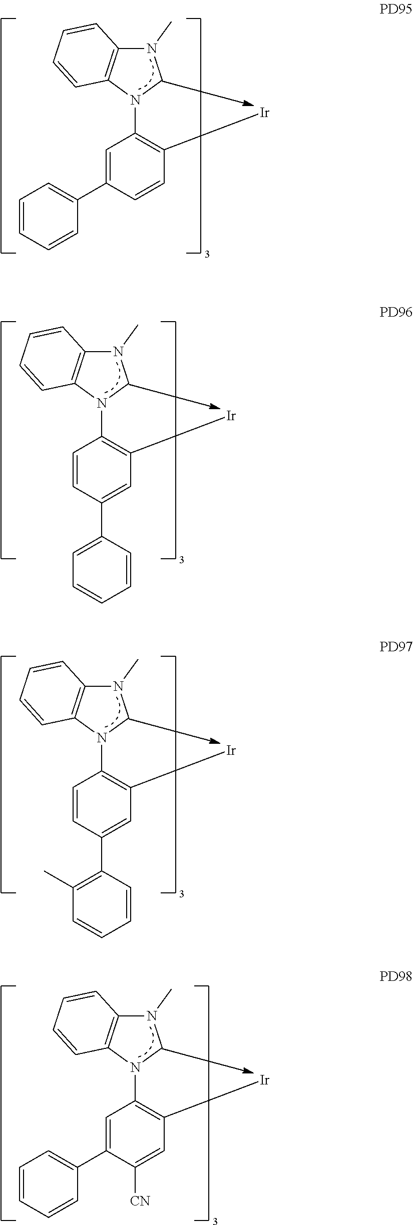

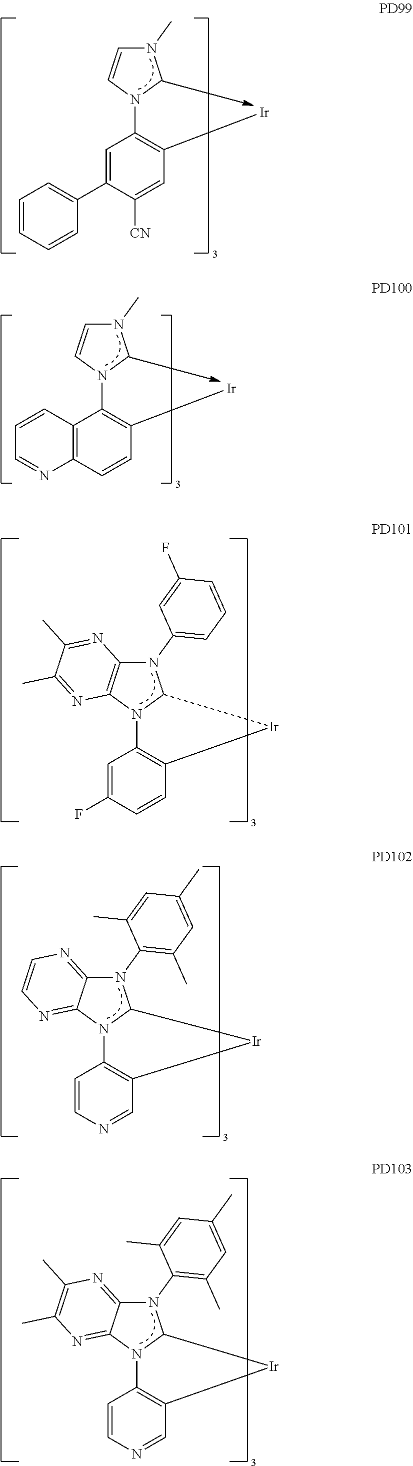

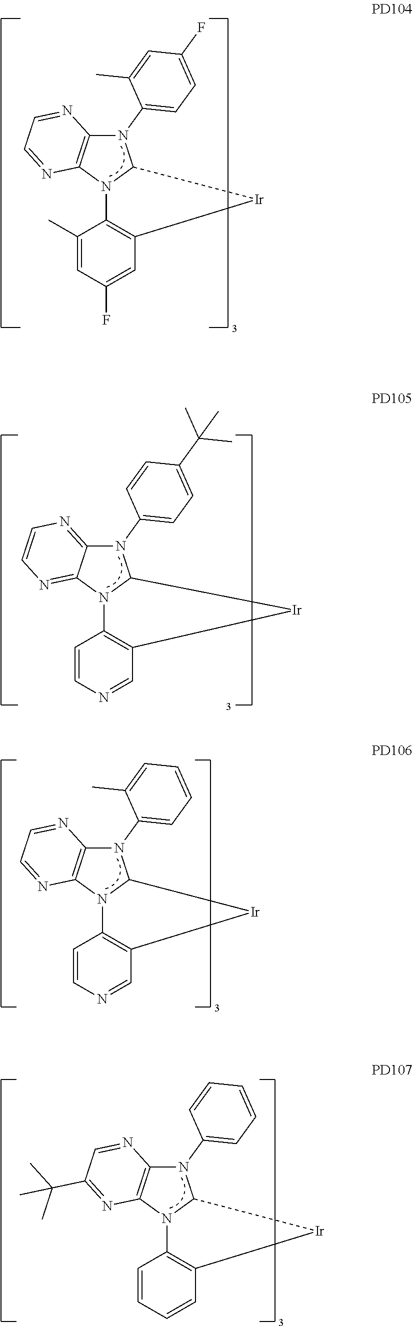

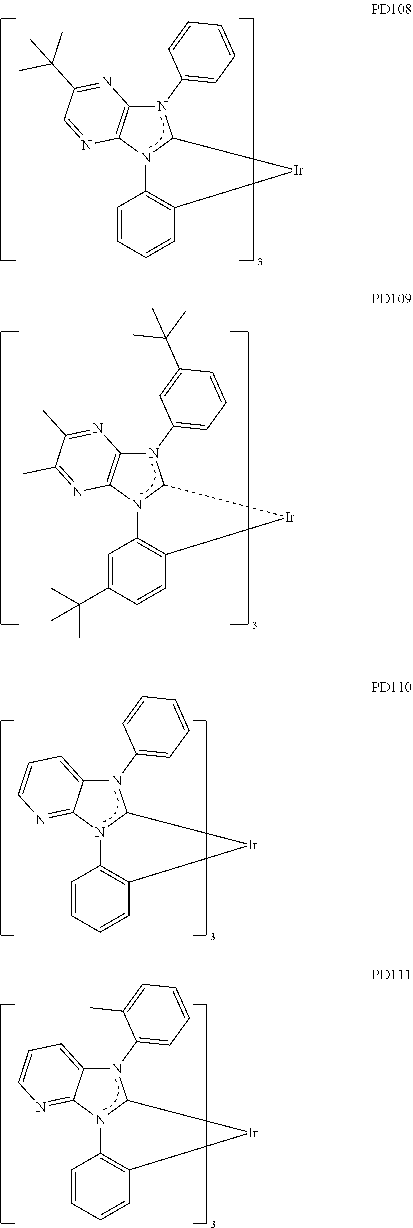

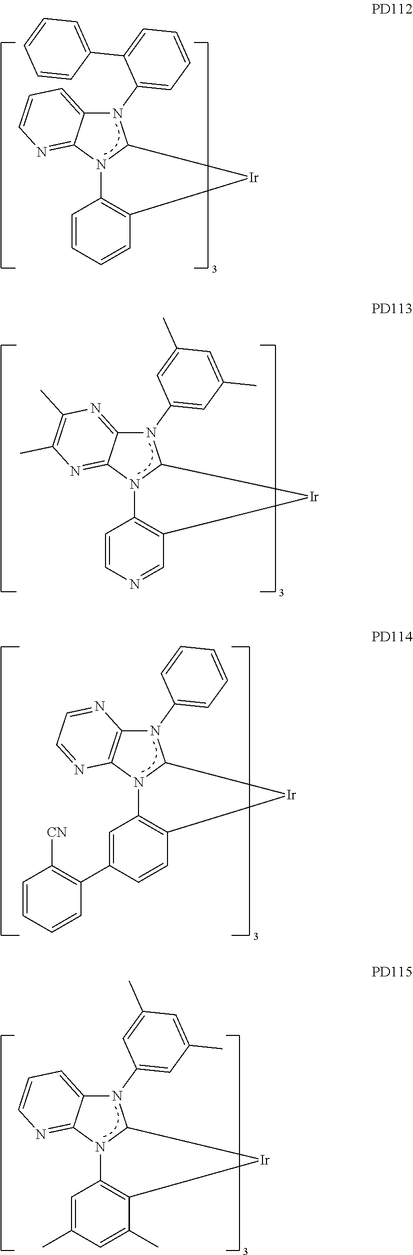

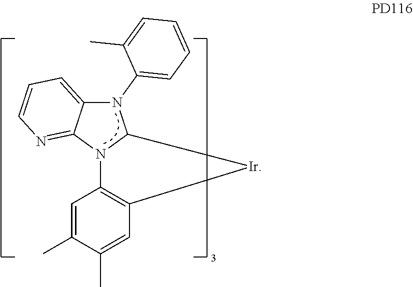

The amount of the dopant in the emission layer may be, in general, in a range of about 0.01 parts to about 20 parts by weight based on 100 parts by weight of the emission layer, but embodiments are not limited thereto. While not wishing to be bound by theory, it is understood that when the amount of the dopant is within this range, light emission without quenching may be realized.

The FIGURE illustrates a schematic view of an organic light-emitting device 10 according to an embodiment. Hereinafter, a structure of an organic light-emitting device according to one or more embodiments and a method of manufacturing the organic light-emitting device will be described with reference to the FIGURE. The organic light-emitting device 10 may include a first electrode 11, an organic layer 15, and a second electrode 19, which may be sequentially layered in this stated order.

A substrate may be additionally disposed under the first electrode 11 or on the second electrode 19. The substrate may be a conventional substrate used in organic light-emitting devices, e.g., a glass substrate or a transparent plastic substrate, each having excellent mechanical strength, thermal stability, transparency, surface smoothness, ease of handling, and water repellency.

The first electrode 11 may be formed by vacuum-depositing or sputtering, onto the substrate, a material for forming the first electrode 11. The first electrode 11 may be an anode. The material for forming the first electrode 11 may be selected from materials with a high work function for easy hole injection. The first electrode 11 may be a reflective electrode, a semi-transmissive electrode, or a transmissive electrode. The material for forming the first electrode 11 may be selected from indium tin oxide (ITO), indium zinc oxide (IZO), tin oxide (SnO₂), and zinc oxide (ZnO). In some embodiments, the material for forming the first electrode 11 may be a metal, such as magnesium (Mg), aluminum (Al), aluminum-lithium (Al—Li), calcium (Ca), magnesium-indium (Mg—In), or magnesium-silver (Mg—Ag).

The first electrode 11 may have a single-layered structure or a multi-layered structure including a plurality of layers. In some embodiments, the first electrode 11 may have a triple-layered structure of ITO/Ag/ITO, but embodiments are not limited thereto.

The organic layer 15 may be on the first electrode 11.

The organic layer 15 may include a hole transport region, an emission layer, and an electron transport region.

The hole transport region may be disposed between the first electrode 11 and the emission layer.

The hole transport region may include at least one selected from a hole injection layer, a hole transport layer, an electron blocking layer, and a buffer layer.

The hole transport region may include a hole injection layer only or a hole transport layer only. In some embodiments, the hole transport region may include a hole injection layer and a hole transport layer which are sequentially stacked on the first electrode 11. In some embodiments, the hole transport region may include a hole injection layer, a hole transport layer, and an electron blocking layer, which are sequentially stacked on the first electrode 11.

When the hole transport region includes a hole injection layer, the hole injection layer may be formed on the first electrode 11 by using one or more suitable methods, such as vacuum deposition, spin coating, casting, and Langmuir-Blodgett (LB) deposition.

When a hole injection layer is formed by vacuum deposition, for example, the vacuum deposition may be performed at a deposition temperature in a range of about 100° C. to about 500° C., at a vacuum pressure in a range of about 10⁻⁸ torr to about 10⁻³ torr, and at a deposition rate in a range of about 0.01 Angstroms per second (A/sec) to about 100 Å/sec, though the conditions may vary depending on a compound that is used as a hole injection material and a structure and thermal properties of a desired hole injection layer, but conditions for the vacuum deposition are not limited thereto.

When a hole injection layer is formed by spin coating, the spin coating may be performed at a coating rate in a range of about 2,000 revolutions per minute (rpm) to about 5,000 rpm, and at a temperature in a range of about 80° C. to 200° C., to facilitate removal of a solvent after the spin coating, though the conditions may vary depending on a compound that is used as a hole injection material and a structure and thermal properties of a desired hole injection layer, but conditions for the spin coating are not limited thereto.

The conditions for forming a hole transport layer and an electron blocking layer may be inferred from the conditions for forming the hole injection layer.

The hole transport region may include at least one selected from m-MTDATA, TDATA, 2-TNATA, NPB, β-NPB, TPD, spiro-TPD, spiro-NPB, methylated-NPB, TAPC, HMTPD, 4,4′,4″-tris(N-carbazolyl)triphenylamine (TCTA), polyaniline/dodecylbenzene sulfonic acid (PANI/DBSA), poly(3,4-ethylenedioxythiophene)/poly(4-styrene sulfonate) (PEDOT/PSS), polyaniline/camphor sulfonic acid (PANI/CSA), (polyaniline)/poly(4-styrene sulfonate) (PANI/PSS), a compound represented by Formula 201, and a compound represented by Formula 202:

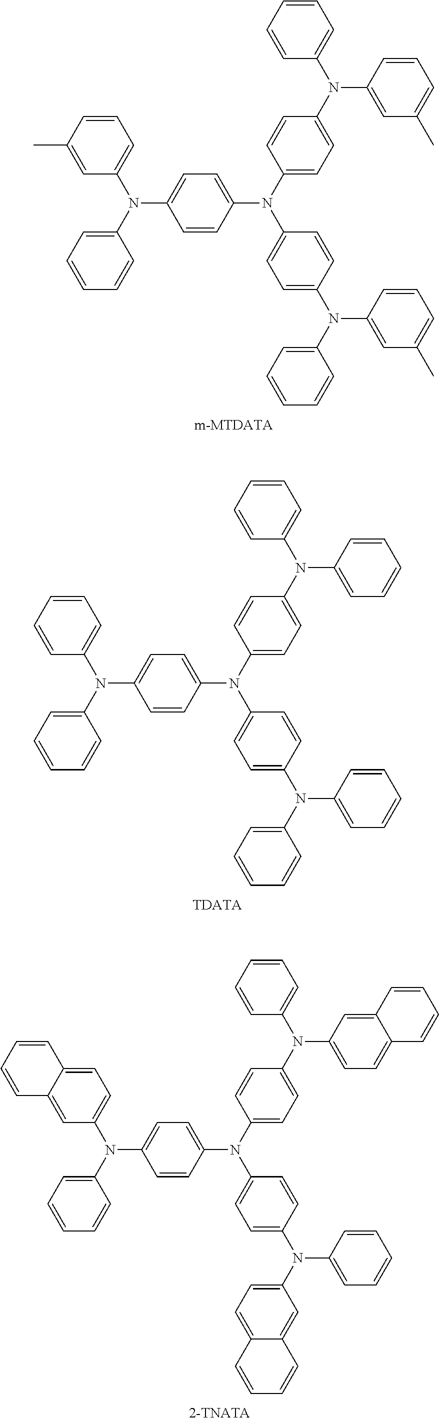

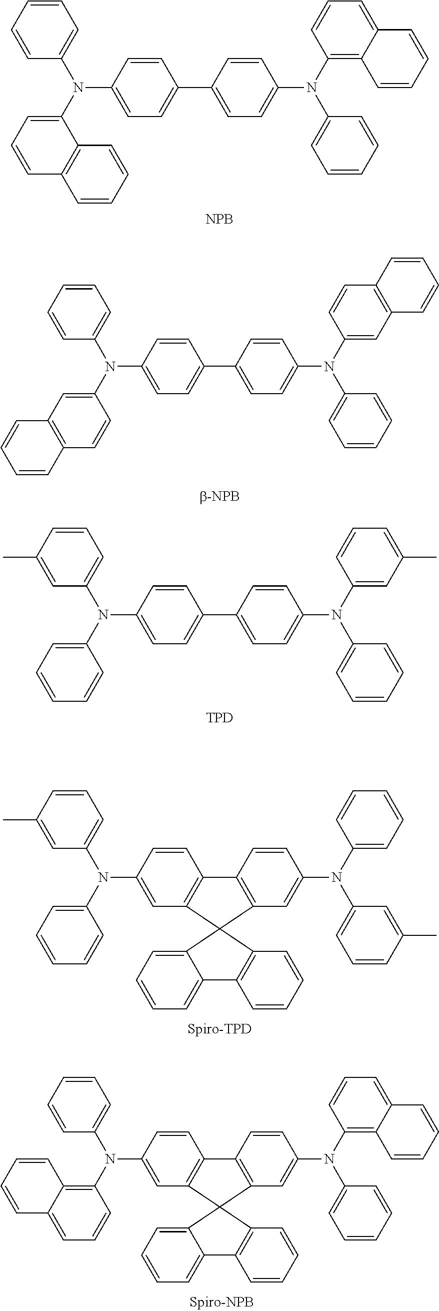

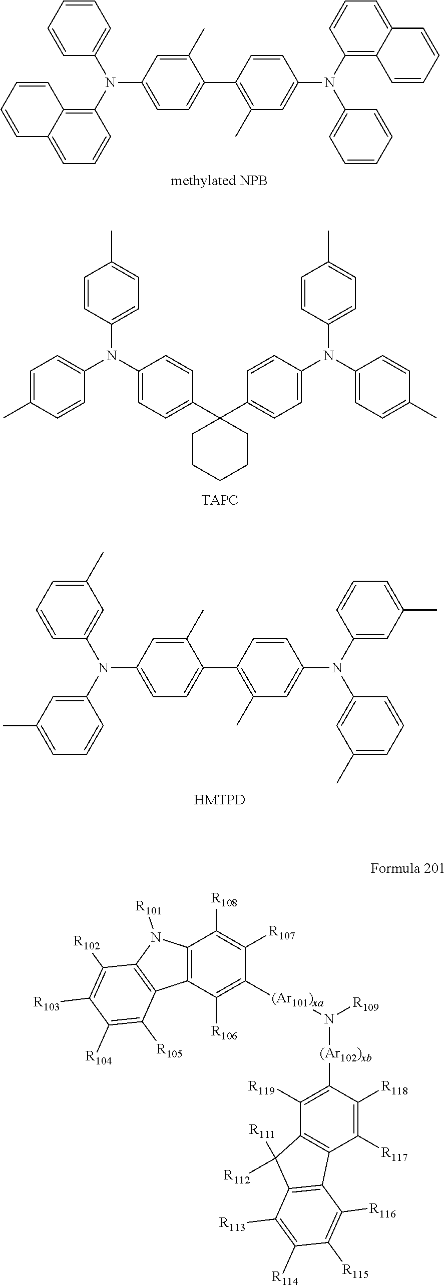

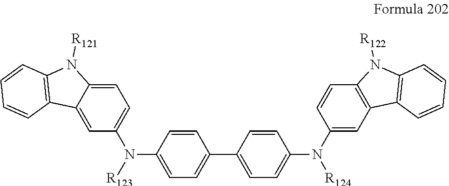

wherein, in Formula 201, Ar₁₀₁ and Ar₁₀₂ may each independently be selected from
a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group; and
a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group.

In Formula 201, xa and xb may each independently be an integer from 0 to 5. In some embodiments, xa and xb may each independently be an integer of 0, 1, or 2. In some embodiments, xa may be 1, and xb may be 0, but embodiments are not limited thereto.

In Formulae 201 and 202, R₁₀₁ to R₁₀₈, R₁₁₁ to R₁₁₉, and R₁₂₁ to R₁₂₄ may each independently be selected from
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (e.g., a methyl group, an ethyl group, a propyl group, a butyl group, pentyl group, or a hexyl group), and a C₁-C₁₀ alkoxy group (e.g., a methoxy group, an ethoxy group, a propoxy group, a butoxy group, or a pentoxy group);
a C₁-C₁₀ alkyl group and a C₁-C₁₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof;
a phenyl group, a naphthyl group, an anthracenyl group, a fluorenyl group, and a pyrenyl group; and
a phenyl group, a naphthyl group, an anthracenyl group, a fluorenyl group, and a pyrenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, and a C₁-C₁₀ alkoxy group, but embodiments are not limited thereto.

In Formula 201, R₁₀₉ may be selected from
a phenyl group, a naphthyl group, an anthracenyl group, and a pyridinyl group; and
a phenyl group, a naphthyl group, an anthracenyl group, and a pyridinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, and a pyridinyl group.

In some embodiments, the compound represented by Formula 201 may be represented by Formula 201A, but embodiments are not limited thereto:

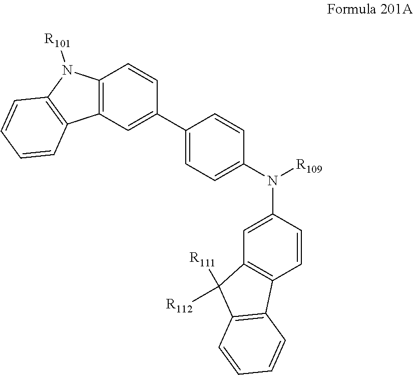

wherein, R₁₀₁, R₁₁₁, R₁₁₂, and R₁₀₉ in Formula 201A may be the same as those described above.

In some embodiments, the compounds represented by Formulae 201 and 202 may include Compounds HT1 to HT20, but embodiments are not limited thereto:

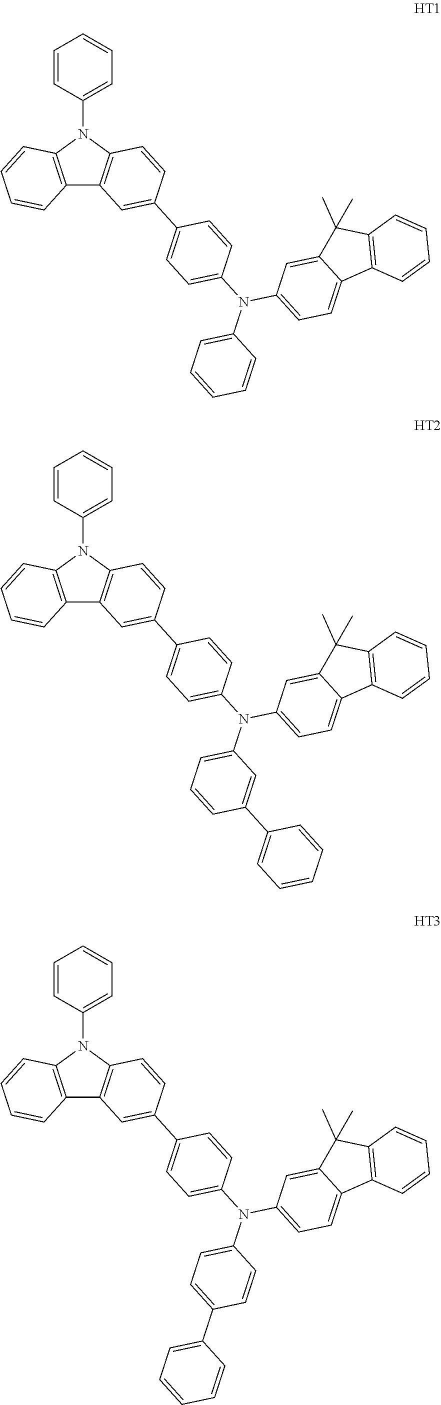 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

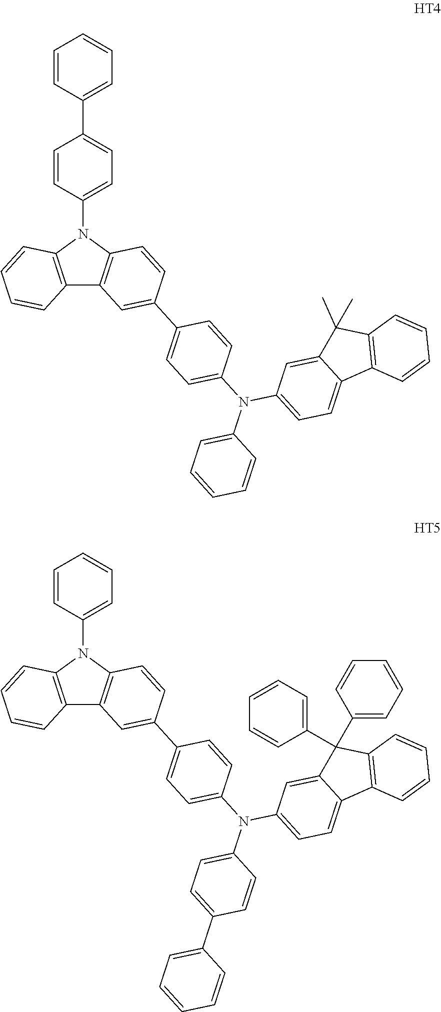 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

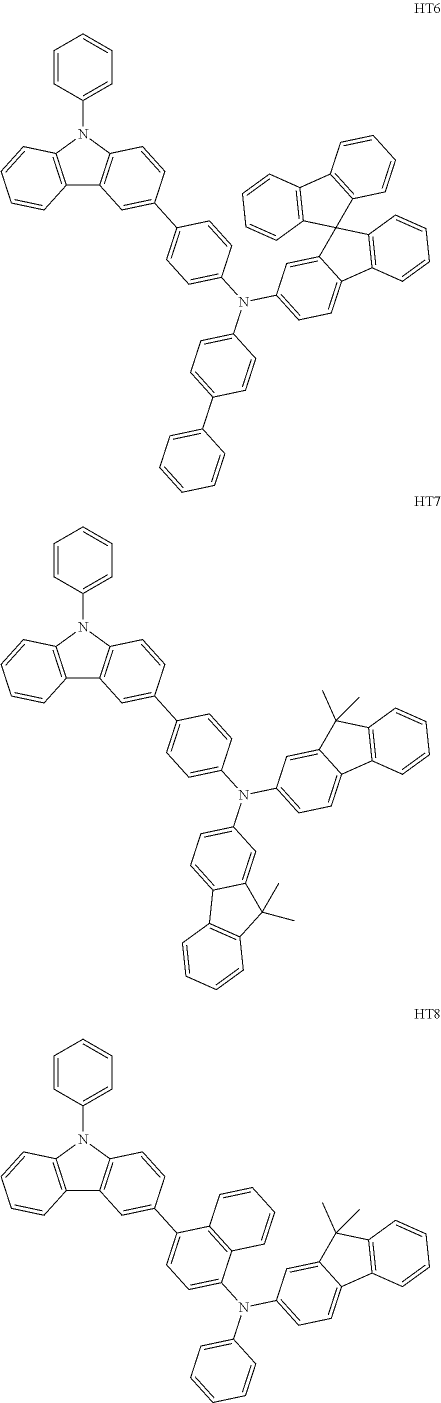 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

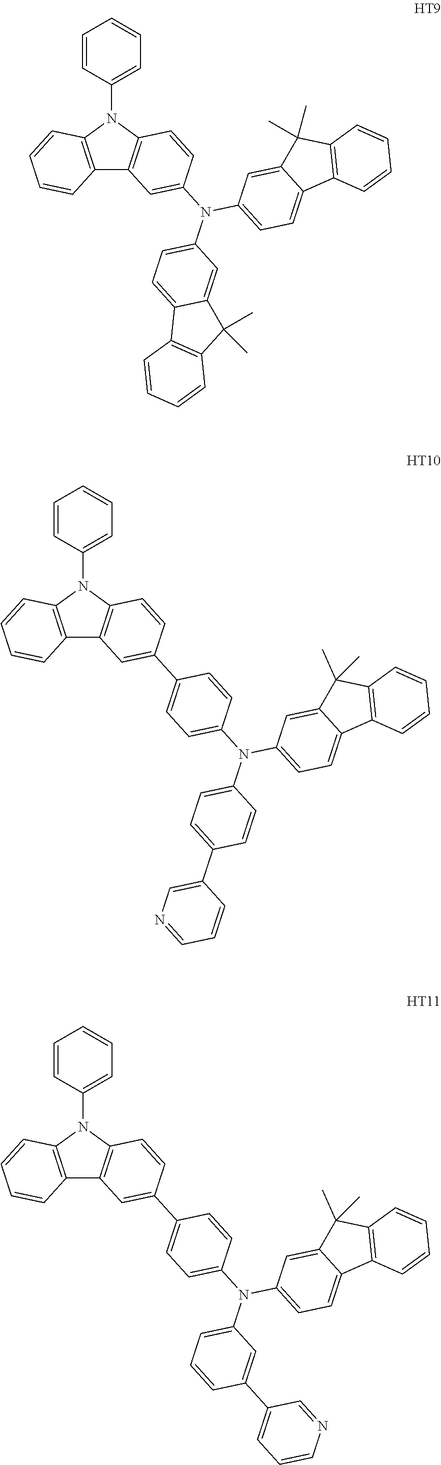 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

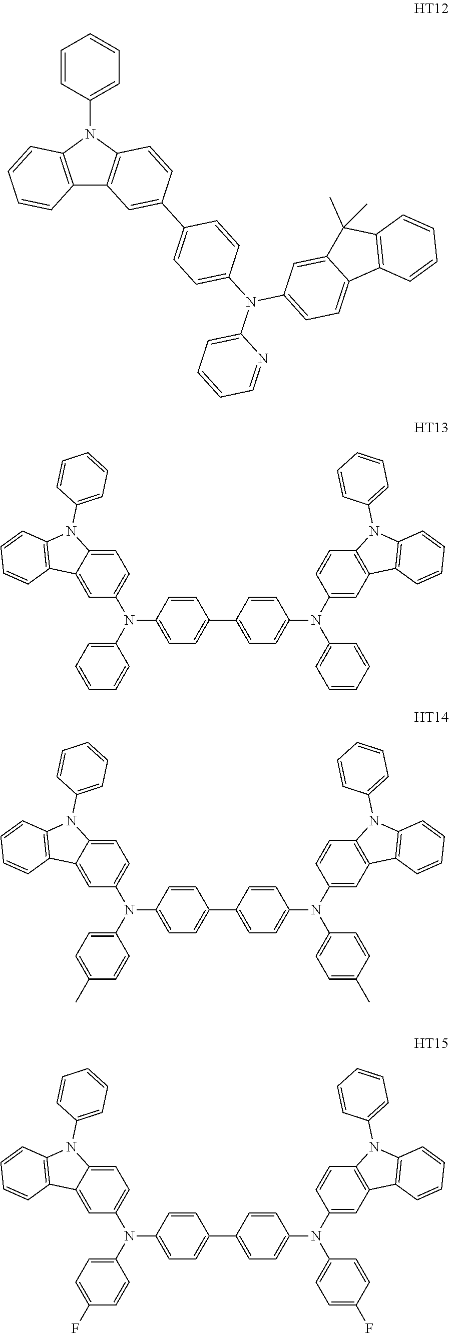 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

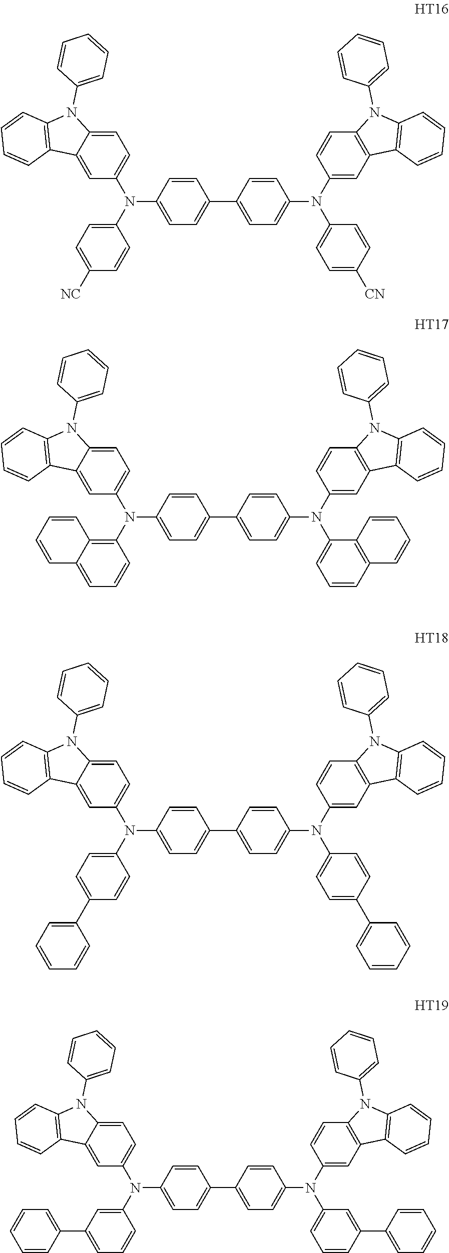 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

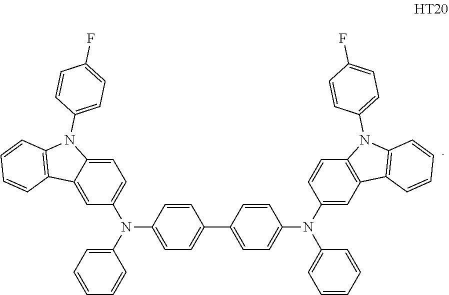 [SMILES: Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; "."]

The thickness of the hole transport region may be in a range of about 100 Angstroms (Å) to about 10,000 Å, and in some embodiments, about 100 Å to about 1,000 Å. When the hole transport region includes at least one selected from a hole injection layer and a hole transport layer, the thickness of the hole injection layer may be in a range of about 100 Å to about 10,000 Å, and in some embodiments, about 100 Å to about 1,000 Å, and the thickness of the hole transport layer may be in a range of about 50 Å to about 2,000 Å, and in some embodiments, about 100 Å to about 1,500 Å. While not wishing to be bound by theory, it is understood that when the thicknesses of the hole transport region, the hole injection layer, and the hole transport layer are within any of these ranges, excellent hole transport characteristics may be obtained without a substantial increase in driving voltage.

The hole transport region may include a charge generating material as well as the aforementioned materials, to improve conductive properties of the hole transport region. The charge generating material may be substantially homogeneously or non-homogeneously dispersed in the hole transport region.

The charge generating material may include, for example, a p-dopant. The p-dopant may include one of a quinone derivative, a metal oxide, and a compound containing a cyano group, but embodiments are not limited thereto. For example, non-limiting examples of the p-dopant include a quinone derivative, such as tetracyanoquinodimethane (TCNQ) or 2,3,5,6-tetrafluoro-tetracyano-1,4-benzoquinonedimethane (F4-TCNQ); a metal oxide, such as a tungsten oxide or a molybdenum oxide; and a compound containing a cyano group, such as Compound HT-D1 or Compound HP-1, but embodiments are not limited thereto:

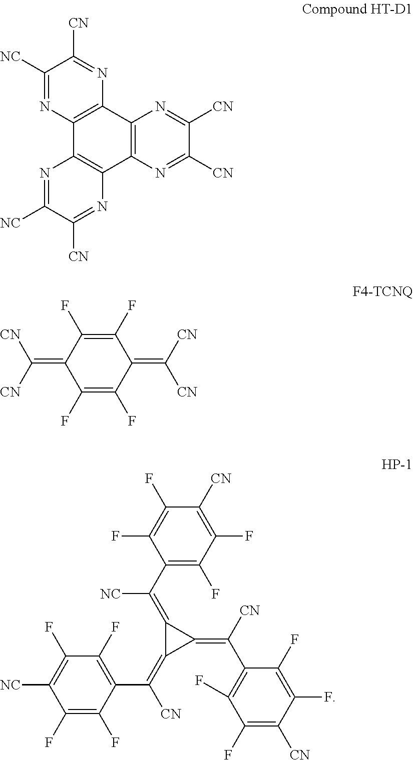

The hole transport region may further include a buffer layer.

The buffer layer may compensate for an optical resonance distance depending on a wavelength of light emitted from the emission layer, to improve the efficiency of an organic light-emitting device.

The hole transport region may further include an electron blocking layer. The electron blocking layer may include any suitable known material, e.g., mCP, but embodiments are not limited thereto:

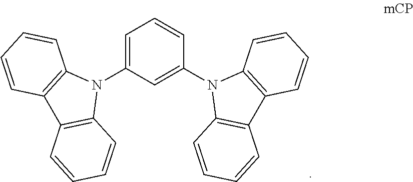 [SMILES: c1cc(-n2c3ccccc3c3ccccc32)cc(-n2c3ccccc3c3ccccc32)c1]

In some embodiments, a donor compound included in the emission layer may be used as a material for forming the electron blocking layer.

An emission layer may be formed on the hole transport region by using one or more suitable methods, such as vacuum deposition, spin coating, casting, or LB deposition. When the emission layer is formed by vacuum deposition or spin coating, vacuum deposition and coating conditions for forming the emission layer may be generally similar to the those conditions for forming a hole injection layer, though the conditions may vary depending on a compound that is used.

When the organic light-emitting device 10 is a full-color organic light-emitting device, the emission layer may be patterned into a red emission layer, a green emission layer, and a blue emission layer. In some embodiments, the emission layer may have a structure in which the red emission layer, the green emission layer, and/or the blue emission layer are layered to emit white light. In some embodiments, the structure of the emission layer may vary.

The emission layer may include a host and a dopant which may satisfy the above-described conditions.

In one or more embodiments, the emission layer may consist of a host and a dopant which may satisfy the above-described conditions.

The thickness of the emission layer may be in a range of about 100 Å to about 1,000 Å, and in some embodiments, about 200 Å to about 600 Å. While not wishing to be bound by theory, it is understood that when the thickness of the emission layer is within any of these ranges, improved luminous characteristics may be obtained without a substantial increase in driving voltage.

Next, an electron transport region may be formed on the emission layer.

The electron transport region may include at least one selected from a hole blocking layer, an electron transport layer, and an electron injection layer.

In some embodiments, the electron transport region may have a hole blocking layer/an electron transport layer/an electron injection layer structure or an electron transport layer/an electron injection layer structure, but embodiments are not limited thereto. The electron transport layer may have a single-layered structure or a multi-layered structure including two or more different materials.

The conditions for forming a hole blocking layer, an electron transport layer, and an electron injection layer may be inferred based on the conditions for forming the hole injection layer.

When the electron transport region includes a hole blocking layer, the hole blocking layer, for example, may include at least one of BCP and Bphen, but embodiments are not limited thereto:

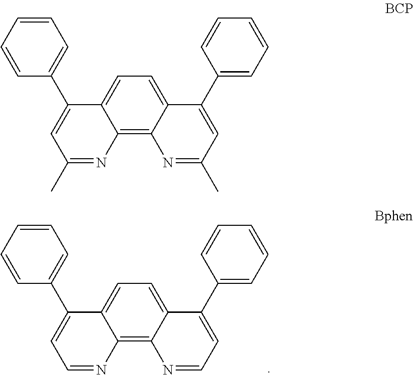

In some embodiments, the acceptor compound used in the emission layer may be used as a material for forming the hole blocking layer.

The thickness of the hole blocking layer may be in a range of about 20 Å to about 1,000 Å, and in some embodiments, about 30 Å to about 300 Å. While not wishing to be bound by theory, it is understood that when the thickness of the hole blocking layer is within these ranges, excellent hole blocking characteristics may be obtained without a substantial increase in driving voltage.

The electron transport layer may further include at least one selected from BCP, BPhen, Alq₃, BAlq, TAZ, and NTAZ:

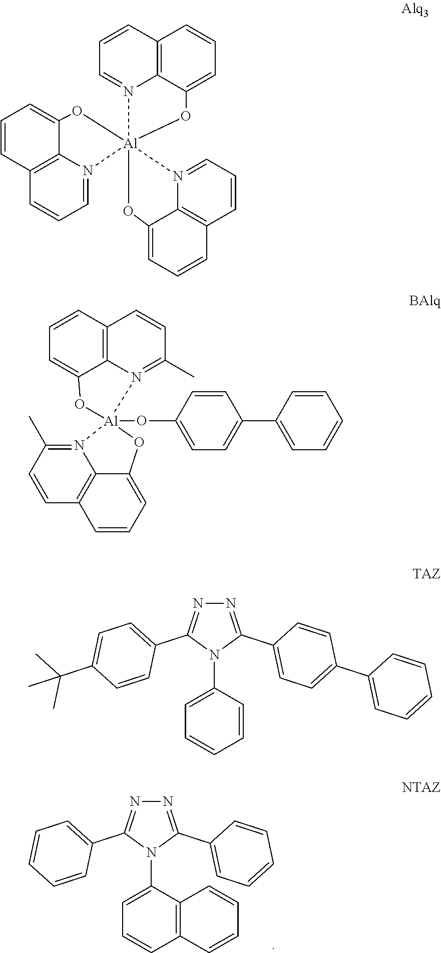

In some embodiments, an electron transport material in the electron transport layer may include a compound represented by Formula 40 or a compound represented by Formula 41:

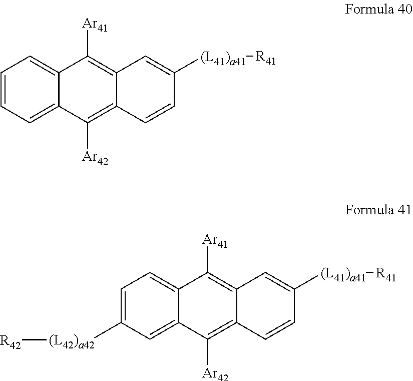

wherein, in Formulae 40 and 41,
L₄₁ and L₄₂ may each independently be selected from
a C₆-C₆₀ arylene group, a C₁-C₆₀ heteroarylene group, a divalent non-aromatic condensed polycyclic group, and a divalent non-aromatic condensed heteropolycyclic group; and
a C₆-C₆₀ arylene group, a C₁-C₆₀ heteroarylene group, a divalent non-aromatic condensed polycyclic group, and a divalent non-aromatic condensed heteropolycyclic group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a pyrenyl group, a chrysenyl group, a phenanthrenyl group, a pyridinyl group, a pyrimidinyl group, and a triazinyl group,
a41 and a42 may each independently be an integer from 0 to 5,
Ar₄₁ and Ar₄₂ may each independently be selected from
a C₆-C₆₀ aryl group, a C₁-C₆₀ heteroaryl group, a monovalent non-aromatic condensed polycyclic group, and a monovalent non-aromatic condensed heteropolycyclic group; and
a C₆-C₆₀ aryl group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a pyrenyl group, a chrysenyl group, a phenanthrenyl group, a pyridinyl group, a pyrimidinyl group, and a triazinyl group, and
R₄₁ and R₄₂ may each independently be selected from
a benzimidazolyl group, a benzoxazolyl group, a benzothiazolyl group, a benzopyrimidinyl group, an imidazopyridinyl group, a quinolinyl group, an isoquinolinyl group, a quinazolinyl group, a pyridinyl group, a pyrimidinyl group, a pyrazinyl group, a phenyl group, a naphthyl group, a pyrenyl group, a chrysenyl group, a fluorenyl group, and a phenanthrenyl group; and
a benzimidazolyl group, a benzoxazolyl group, a benzothiazolyl group, a benzopyrimidinyl group, an imidazopyridinyl group, a quinolinyl group, an isoquinolinyl group, a quinazolinyl group, a pyridinyl group, a pyrimidinyl group, a pyrazinyl group, a phenyl group, a naphthyl group, a pyrenyl group, a chrysenyl group, a fluorenyl group, and a phenanthrenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a benzimidazolyl group, a benzoxazolyl group, a benzothiazolyl group, a benzopyrimidinyl group, an imidazopyridinyl group, a quinolinyl group, an isoquinolinyl group, a quinazolinyl group, a pyridinyl group, a pyrimidinyl group, a pyrazinyl group, a phenyl group, a naphthyl group, a pyrenyl group, a chrysenyl group, a fluorenyl group, and a phenanthrenyl group.

In Formulae 40 and 41, L₄₁ and L₄₂ may be the same as described herein with reference to L₁₁.

In some embodiments, an electron transport material in the electron transport layer may include a compound represented by Formula 42:

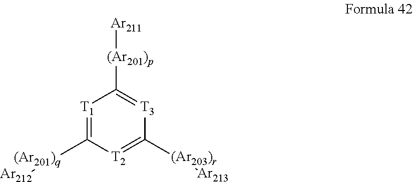

wherein, in Formula 42,
T₁ may be N or C(R₂₀₁), T₂ may be N or C(R₂₀₂), T₃ may be N or C(R₂₀₃), provided that at least one of T₁ to T₃ is N,
R₂₀₁ to R₂₀₃ may each independently be selected from
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₆-C₆₀ aryl group, a C₁-C₆₀ heteroaryl group, a monovalent non-aromatic condensed polycyclic group, and a monovalent non-aromatic condensed heteropolycyclic group; and
a C₆-C₆₀ aryl group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a pyrenyl group, a chrysenyl group, a phenanthrenyl group, a pyridinyl group, a pyrimidinyl group, and a triazinyl group, and
Ar₂₀₁ to Ar₂₀₃ may each independently be selected from
a C₆-C₆₀ arylene group, a C₁-C₆₀ heteroarylene group, a divalent non-aromatic condensed polycyclic group, and a divalent non-aromatic condensed heteropolycyclic group; and
a C₆-C₆₀ arylene group, a C₁-C₆₀ heteroarylene group, a divalent non-aromatic condensed polycyclic group, and a divalent non-aromatic condensed heteropolycyclic group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a pyrenyl group, a chrysenyl group, a phenanthrenyl group, a pyridinyl group, a pyrimidinyl group, and a triazinyl group,
p, q, and r may each independently be 0, 1, or 2, and
Ar₂₁₁ and Ar₂₁₃ may each independently be selected from
a C₆-C₆₀ aryl group, a C₁-C₆₀ heteroaryl group, a monovalent non-aromatic condensed polycyclic group, and a monovalent non-aromatic condensed heteropolycyclic group; and
a C₆-C₆₀ aryl group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a pyrenyl group, a chrysenyl group, a phenanthrenyl group, a pyridinyl group, a pyrimidinyl group, and a triazinyl group.

In an embodiment, in Formula 42, at least two of T₁ to T₃ may be N.

In one or more embodiments, in Formula 42, T₁ to T₃ may each be N.

In Formula 42, Ar₂₀₁ to Ar₂₀₃ may each independently be selected from
a phenylene group, a naphthylene group, an anthrylene group, a pyrenylene group, a fluorenylene group, a triphenylenylene group, a pyridinylene group, and a pyrimidinylene group; and
a phenylene group, a naphthylene group, an anthrylene group, a pyrenylene group, a fluorenylene group, a triphenylenylene group, a pyridinylene group, and a pyrimidinylene group, each substituted with at least one selected from a phenyl group, a naphthyl group, an anthryl group, a pyrenyl group, a fluorenyl group, a triphenylenyl group, a pyridinyl group, and a pyrimidinyl group, but embodiments are not limited thereto.

In Formula 42, p, q, and r may each independently be 0, 1, or 2. In some embodiments, in Formula 42, p, q, and r may each independently be 0 or 1, but embodiments are not limited thereto.

In Formula 42, Ar₂₁₁ to Ar₂₁₃ may each independently be selected from a phenyl group, a naphthyl group, a pyrenyl group, a chrysenyl group, a fluorenyl group, a phenanthrenyl group, a benzimidazolyl group, a benzoxazolyl group, a benzothiazolyl group, a benzopyrimidinyl group, an imidazopyrimidinyl group, a quinolinyl group, an isoquinolinyl group, a quinazolinyl group, a pyridinyl group, a pyrimidinyl group, a pyrazinyl group, and a triazinyl group; and
a phenyl group, a naphthyl group, a pyrenyl group, a chrysenyl group, a fluorenyl group, a phenanthrenyl group, a benzimidazolyl group, a benzoxazolyl group, a benzothiazolyl group, a benzopyrimidinyl group, an imidazopyrimidinyl group, a quinolinyl group, an isoquinolinyl group, a quinazolinyl group, a pyridinyl group, a pyrimidinyl group, a pyrazinyl group, and a triazinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a pyrenyl group, a chrysenyl group, a phenanthrenyl group, a pyridinyl group, a pyrimidinyl group, and a triazinyl group, but embodiments are not limited thereto.

In an embodiment, in Formula 42, at least one selected from Ar₂₁₁ to Ar₂₁₃ may each independently be selected from
a benzimidazolyl group, a benzoxazolyl group, a benzothiazolyl group, a benzopyrimidinyl group, an imidazopyrimidinyl group, a quinolinyl group, an isoquinolinyl group, a quinazolinyl group, a pyridinyl group, a pyrimidinyl group, a pyrazinyl group, and a triazinyl group; and
a benzimidazolyl group, a benzoxazolyl group, a benzothiazolyl group, a benzopyrimidinyl group, an imidazopyrimidinyl group, a quinolinyl group, an isoquinolinyl group, a quinazolinyl group, a pyridinyl group, a pyrimidinyl group, a pyrazinyl group, and a triazinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a pyrenyl group, a chrysenyl group, a phenanthrenyl group, a pyridinyl group, a pyrimidinyl group, and a triazinyl group, but embodiments are not limited thereto.

In one or more embodiments, in Formula 20A, at least one selected from Ar₂₁₁ to Ar₂₁₃ may be a substituted or unsubstituted phenanthrenyl group.

In some embodiments, the electron transport layer may include at least one selected from Compounds ET1 to ET17, but embodiments are not limited thereto:

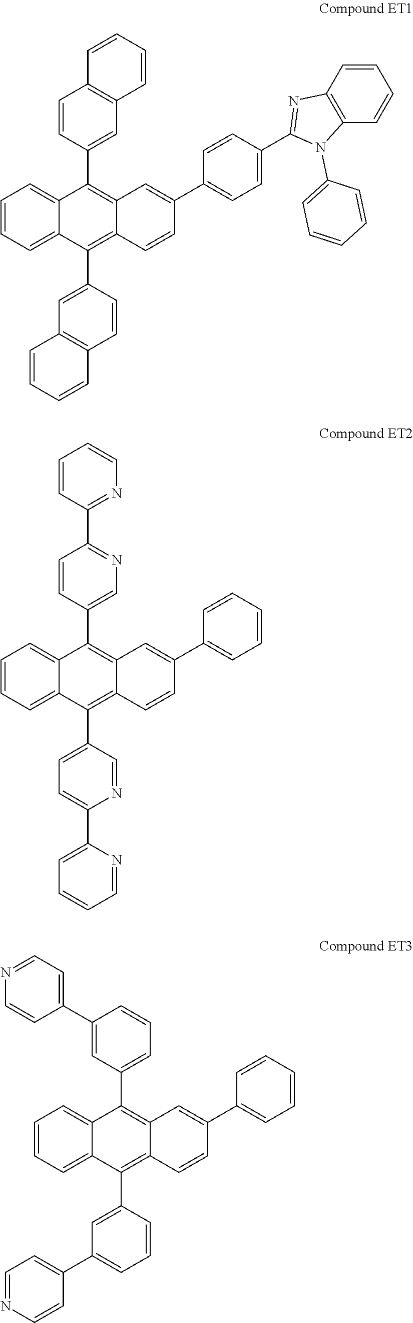 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

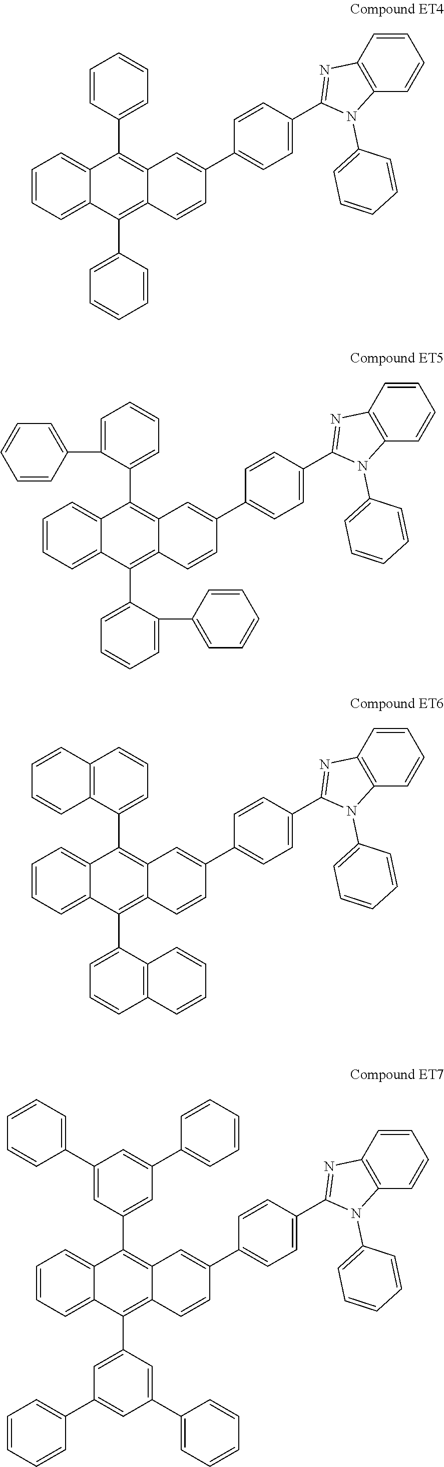 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

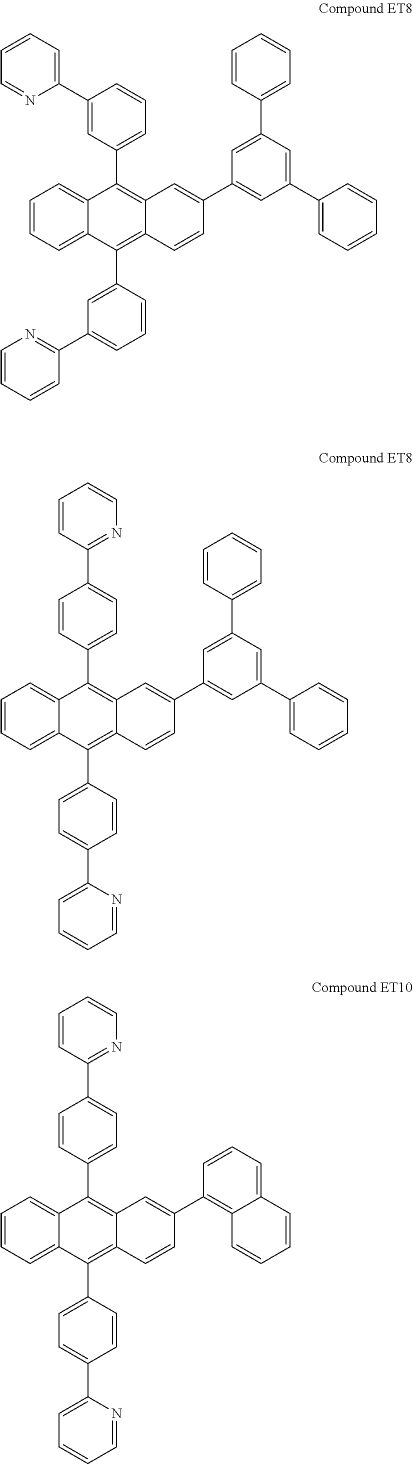 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

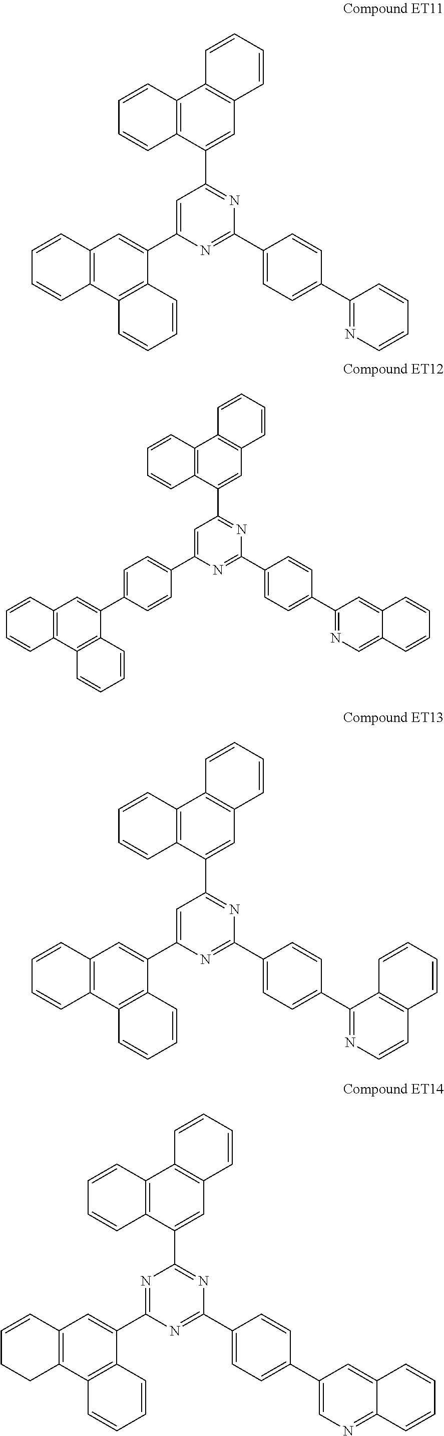 [SMILES: c1ccc(-c2ccc(-c3nc(-c4cc5ccccc5c5ccccc45)cc(-c4cc5ccccc5c5ccccc45)n3)cc2)nc1 ; c1ccc2cc(-c3ccc(-c4nc(-c5ccc(-c6cc7ccccc7c7ccccc67)cc5)cc(-c5cc6ccccc6c6ccccc56)n4)cc3)ncc2c1 ; c1ccc2c(-c3ccc(-c4nc(-c5cc6ccccc6c6ccccc56)cc(-c5cc6ccccc6c6ccccc56)n4)cc3)nccc2c1 ; C1=Cc2cc(-c3nc(-c4ccc(-c5cnc6ccccc6c5)cc4)nc(-c4cc5ccccc5c5ccccc45)n3)c3ccccc3c2CC1]

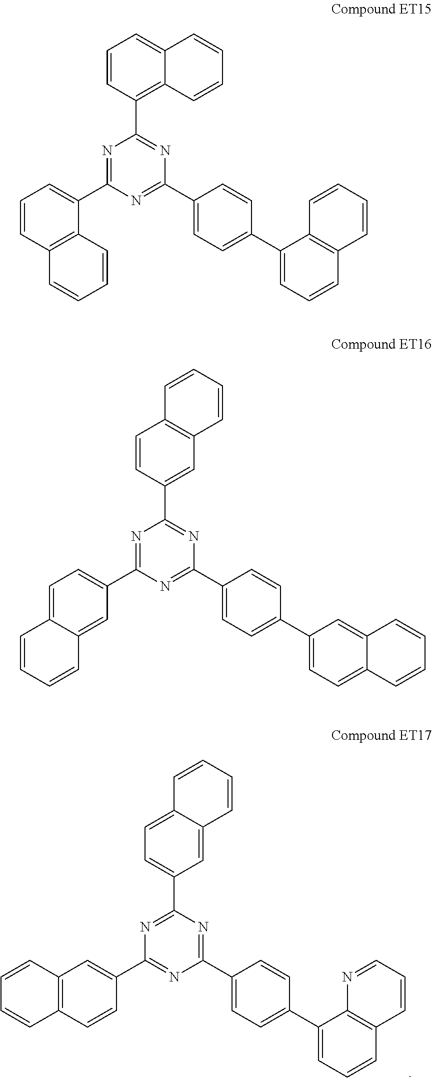 [SMILES: c1ccc2c(-c3ccc(-c4nc(-c5cccc6ccccc56)nc(-c5cccc6ccccc56)n4)cc3)cccc2c1 ; c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1]

The thickness of the electron transport layer may be in a range of about 100 Å to about 1,000 Å, and in some embodiments, about 150 Å to about 500 Å. While not wishing to be bound by theory, it is understood that when the thickness of the electron transport layer is within any of these ranges, excellent electron transport characteristics may be obtained without a substantial increase in driving voltage.

The electron transport layer may further include a material containing metal, in addition to the materials described above.

The material containing metal may include a lithium (Li) complex. The Li complex may include, e.g., Compound ET-D1 (lithium 8-hydroxyquinolate, LiQ) or Compound ET-D2:

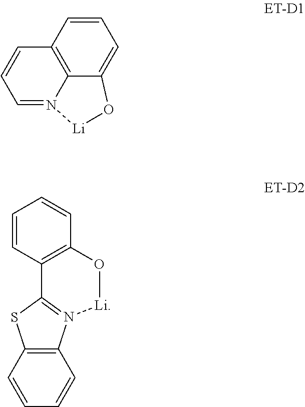

The electron transport region may include an electron injection layer that facilitates electron injection from the second electrode 19.

The electron injection layer may include at least one selected from LiF, NaCl, CsF, Li₂O, and BaO.

The thickness of the electron injection layer may be in a range of about 1 Å to about 100 Å, for example, about 3 Å to about 90 Å. While not wishing to be bound by theory, it is understood that when the thickness of the electron injection layer is within any of these ranges, excellent electron injection characteristics may be obtained without a substantial increase in driving voltage.

The second electrode 19 may be formed on the organic layer 15. The second electrode 19 may be a cathode. A material for forming the second electrode 19 may be a material with a relatively low work function, such as a metal, an alloy, an electrically conductive compound, and a mixture thereof. Examples of the material for forming the second electrode 19 may include lithium (Li), magnesium (Mg), aluminum (Al), aluminum-lithium (Al—Li), calcium (Ca), magnesium-indium (Mg—In), and magnesium-silver (Mg—Ag). In some embodiments, ITO or IZO may be used to form a transmissive second electrode 19 to manufacture a top emission light-emitting device. In some embodiments, the material for forming the second electrode 19 may vary.

Hereinbefore, the organic light-emitting device 10 has been described with reference to the FIGURE, but embodiments are not limited thereto.

The term “C₁-C₆₀ alkyl group” as used herein refers to a linear or branched aliphatic saturated hydrocarbon monovalent group having 1 to 60 carbon atoms. Examples thereof include a methyl group, an ethyl group, a propyl group, an iso-butyl group, a sec-butyl group, a tert-butyl group, a pentyl group, an iso-amyl group, and a hexyl group. The term “C₁-C₆₀ alkylene group” as used herein refers to a divalent group having substantially the same structure as the C₁-C₆₀ alkyl group.

The term “C₁-C₆₀ alkoxy group” as used herein refers to a monovalent group represented by —OA₁₀₁ (wherein A₁₀₁ is a C₁-C₆₀ alkyl group). Examples thereof include a methoxy group, an ethoxy group, and an iso-propyloxy group.

The term “C₂-C₆₀ alkenyl group” as used herein refers to a group formed by including at least one carbon-carbon double bond in the middle or at the terminus of the C₂-C₆₀ alkyl group. Examples thereof include an ethenyl group, a propenyl group, and a butenyl group. The term “C₂-C₆₀ alkenylene group” as used herein refers to a divalent group having substantially the same structure as the C₂-C₆₀ alkenyl group.

The term “C₂-C₆₀ alkynyl group” as used herein refers to a group formed by including at least one carbon-carbon triple bond in the middle or at the terminus of the C₂-C₆₀ alkyl group. Examples thereof include an ethynyl group and a propynyl group. The term “C₂-C₆₀ alkynylene group” as used herein refers to a divalent group having substantially the same structure as the C₂-C₆₀ alkynyl group.

The term “C₃-C₁₀ cycloalkyl group” as used herein refers to a monovalent monocyclic saturated hydrocarbon group including 3 to 10 carbon atoms. Examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having substantially the same structure as the C₃-C₁₀ cycloalkyl group.

The term “C₁-C₁₀ heterocycloalkyl group” as used herein refers to a saturated monovalent monocyclic group including at least one heteroatom selected from N, O, P, Si, and S as a ring-forming atom and 1 to 10 carbon atoms. Examples thereof include a tetrahydrofuranyl group and a tetrahydrothiophenyl group. The term “C₁-C₁₀ heterocycloalkylene group” as used herein refers to a divalent group having substantially the same structure as the C₁-C₁₀ heterocycloalkyl group.

The term “C₃-C₁₀ cycloalkenyl group” as used herein refers to a monovalent monocyclic hydrocarbon group including 3 to 10 carbon atoms and at least one carbon-carbon double bond in its ring, wherein the molecular structure as a whole is non-aromatic. Examples thereof include a cyclopentenyl group, a cyclohexenyl group, and a cycloheptenyl group. The term “C₃-C₁₀ cycloalkenylene group” as used herein refers to a divalent group having substantially the same structure as the C₃-C₁₀ cycloalkenyl group.

The term “C₁-C₁₀ heterocycloalkenyl group” as used herein refers to a monovalent monocyclic group including at least one heteroatom selected from N, O, P, Si and S as a ring-forming atom, 1 to 10 carbon atoms, and at least one double bond in its ring. Examples of the C₁-C₁₀ heterocycloalkenyl group include a 2,3-dihydrofuranyl group and a 2,3-dihydrothiophenyl group. The term “C₁-C₁₀ heterocycloalkylene group” as used herein refers to a divalent group having substantially the same structure as the C₁-C₁₀ heterocycloalkyl group.

The term “C₆-C₆₀ aryl group” as used herein refers to a monovalent group having a carbocyclic aromatic system having 6 to 60 carbon atoms. The term “C₆-C₆₀ arylene group” as used herein refers to a divalent group having a carbocyclic aromatic system having 6 to 60 carbon atoms. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and a C₆-C₆₀ arylene group each include at least two rings, the at least two rings may be fused.

The term “C₁-C₆₀ heteroaryl group” as used herein refers to a monovalent group having a heterocyclic aromatic system having at least one heteroatom selected from N, O, P, Si and S as a ring-forming atom and 1 to 60 carbon atoms. The term “C₁-C₆₀ heteroarylene group” as used herein refers to a divalent group having a heterocyclic aromatic system having at least one heteroatom selected from N, O, P, Si and S as a ring-forming atom and 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include at least two rings, the at least two rings may be fused.

The term “C₆-C₆₀ aryloxy group” as used herein refers to a group represented by —OA₁₀₂ (where A₁₀₂ is a C₆-C₆₀ aryl group), and the term “C₇-C₆₀ arylalkyl group” as used herein indicates -A₁₀₄A₁₀₅ (wherein A₁₀₅ is the C₆-C₅₉ aryl group and A₁₀₄ is the C₁-C₅₃ alkylene group). The term “C₆-C₆₀ arylthio group” as used herein refers to a group represented by —SA₁₀₃ (where A₁₀₃ is a C₆-C₆₀ aryl group).

The term “C₁-C₆₀ heteroaryloxy group” as used herein refers to —OA₁₀₆ (wherein A₁₀₆ is the C₂-C₆₀ heteroaryl group), and the term “C₁-C₆₀ heteroarylthio group” as used herein indicates —SA₁₀₇ (wherein A₁₀₇ is the C₁-C₆₀ heteroaryl group).

The term “C₂-C₆₀ heteroarylalkyl group” as used herein refers to -A₁₀₈A₁₀₉ (A₁₀₉ is a C₁-C₅₉ heteroaryl group, and A₁₀₈ is a C₁-C₅₉ alkylene group).

The term “monovalent non-aromatic condensed polycyclic group” as used herein refers to a monovalent group having two or more rings condensed and only carbon atoms (for example, the number of carbon atoms may be in a range of 8 to 60) as ring-forming atoms, wherein the molecular structure as a whole is non-aromatic. Examples of the non-aromatic condensed polycyclic group include a fluorenyl group. The term “divalent non-aromatic condensed polycyclic group” as used herein refers to a divalent group having substantially the same structure as the monovalent non-aromatic condensed polycyclic group.

The term “monovalent non-aromatic condensed heteropolycyclic group” as used herein refers to a monovalent group having at least two rings condensed and a heteroatom selected from N, O, P, Si and S as well as carbon atoms (for example, the number of carbon atoms may be in a range of 2 to 60) as ring-forming atoms, wherein the molecular structure as a whole is non-aromatic. Examples of the monovalent non-aromatic condensed heteropolycyclic group include a carbazolyl group. The term “divalent non-aromatic condensed heteropolycyclic group” as used herein refers to a divalent group having substantially the same structure as the monovalent non-aromatic condensed heteropolycyclic group.

At least one substituent of the substituted C₃-C₁₀ cycloalkylene group, substituted C₁-C₁₀ heterocycloalkylene group, substituted C₃-C₁₀ cycloalkenylene group, substituted C₁-C₁₀ heterocycloalkenylene group, substituted C₆-C₆₀ arylene group, substituted C₁-C₆₀ heteroarylene group, substituted divalent non-aromatic condensed polycyclic group, substituted divalent non-aromatic condensed heteropolycyclic group, substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₇-C₆₀ arylalkyl group, substituted C₁-C₆₀ heteroaryl group, substituted C₁-C₆₀ heteroaryloxy group, substituted C₁-C₆₀ heteroarylthio group, substituted C₂-C₆₀ heteroarylalkyl group, substituted monovalent non-aromatic condensed polycyclic group, and substituted monovalent non-aromatic condensed heteropolycyclic group may be:
deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or a C₁-C₆₀ alkoxy group;
a C₁-C₆₀ alkyl group, a C₂-C₆₀ alkenyl group, a C₂-C₆₀ alkynyl group, or C₁-C₆₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), and —B(Q₁₆)(Q₁₇);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, or a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, or a monovalent non-aromatic condensed heteropolycyclic group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), and —B(Q₂₆)(Q₂₇), or
—N(Q₃₁)(Q₃₂), —Si(Q₃₃)(Q₃₄)(Q₃₅), or —B(Q₃₆)(Q₃₇),
wherein Q₁ to Q₇, Q₁₁ to Q₁₇, Q₂₁ to Q₂₇, and Q₃₁ to Q₃₇ may each independently be hydrogen, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, or a monovalent non-aromatic condensed heteropolycyclic group.

The term “room temperature” as used herein refers to a temperature of about 25° C.

Hereinafter, a compound and an organic light-emitting device according to an embodiment will be described in detail with reference to Synthesis Examples and Examples, however, the present disclosure is not limited thereto. The wording “B was used instead of A” used in describing Synthesis Examples means that an amount of B used was identical to an amount of A used in terms of molar equivalents.

### EXAMPLES

### Evaluation Example 1

Referring to the methods shown in Table 1, T1, S1, Eₒₓ, E*ₒₓ, E_{red}, and E*_{red} of Compounds PD79 to PD84, Compounds PD300 to PD303, and Compound A2 were evaluated. The results thereof are shown in Table 2.

Referring to Table 2, a value of E*ₒₓ of each of Compounds PD79 to PD84 and PD300 to PD303 is equal to a value of Eₒₓ−T1 of the corresponding compound. A value of E*ₒₓ of Compound A2 is equal to a value of Eₒₓ−S1 of Compound A2. A value of E*_{red} of each of Compounds PD79 to PD84 and PD300 to PD303 is equal to a value of E_{red}+T1 of the corresponding compound. A value of E*_{red} of Compound A2 is equal to a value of E_{red}+S1 of Compound A2.

TABLE 1

| | |
|---|---|
| T1 energy | A mixture of 2-Methyltetrahydrofuran (2-MeTHF) and |
| level | each compound (in which each compound was dissolved |
| evaluation | in 3 milliliters (mL) of 2-MeTHF at a concentration |
| method | of 10 micromolar, μM) was loaded into a quartz cell. |
| | Subsequently, the resulting quartz cell was loaded into a |
| | cryostat (available from Oxford Instruments, DN) including |
| | liquid nitrogen at atemperature of 77 Kelvins (K). A |
| | fluorescence spectrum thereof was measured by using a |
| | spectrofluorometer (available from PTI, QuantaMaster |
| | 400). A T1 energy level was calculated from the start |
| | wavelength of the short-wavelength side. |
| S1 energy | A mixture of 2-MeTHF and each compound (in which each |
| level | compound was dissolved in 3 mL of 2-MeTHF at a |
| evaluation | concentration of 10 μM) was loaded into a quartz cell. A |
| method | fluorescence spectrum thereof was measured at room |
| | temperature by using a spectrofluorometer (available from |
| | PTI, QuantaMaster 400). An S1 energy level was calculated |
| | from the start wavelength of the short-wavelength side. |
| Eₒₓ | A potential (Volts, V) versus current (Amperes, A) graph of |
| evaluation | each compound was obtained by using cyclic voltammetry |
| method | (CHI630B available from CH Instruments, electrolyte: 0.1 |
| | molar (M) Bu₄NPF₆/solvent: CH₂Cl₂/electrode: 3-electrode |
| | system (working electrode: Pt disc (1 mm diameter), |
| | reference electrode: Pt wire, and auxiliary electrode: Pt |
| | wire)). Subsequently, Eₒₓ was calculated. |
| E_{red} | A potential (V) versus current (A) graph of each compound |
| evaluation | was obtained by using differential pulse voltammetry |
| method | (DPV, CHI630B available from CH Instruments, |
| | electrolyte: 0.1M Bu₄NPF₆/solvent: CH₂Cl₂/electrode: 3- |
| | electrode system (working electrode: Pt disc (1 mm |
| | diameter), reference electrode: Pt wire, and auxiliary |
| | electrode: Pt wire)). Subsequently, Eₒₓ was calculated. |

TABLE 2

| | T1 | S1 | Eₒₓ | E*ₒₓ | E_{red} | E*_{red} |
|---|---|---|---|---|---|---|
| Compound No. | (eV) | (eV) | (eV) | (eV) | (eV) | (eV) |
| PD79 | 2.68 | — | 0.94 | −1.74 | −1.67 | 1.01 |
| PD80 | 2.72 | — | 0.87 | −1.85 | −1.77 | 0.95 |
| A2 | — | 2.86 | 1.23 | −1.63 | −1.65 | 1.21 |
| PD81 | 2.59 | — | 1.18 | −1.41 | −1.83 | 0.76 |
| PD82 | 2.68 | — | 0.97 | −1.71 | — | — |
| PD83 | 2.59 | — | 0.88 | −1.71 | — | — |
| PD84 | 2.86 | — | 0.96 | −1.90 | −1.21 | 1.65 |
| PD300 | 2.97 | — | 1.86 | −1.11 | −1.13 | 1.84 |
| PD301 | 2.90 | — | 1.02 | −1.88 | −1.14 | 1.76 |
| PD302 | 2.81 | — | 0.80 | −2.01 | −1.12 | 1.69 |
| PD303 | 2.81 | — | 2.24 | −0.57 | −1.10 | 1.71 |

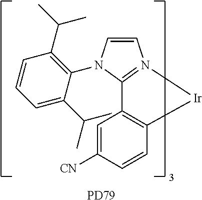

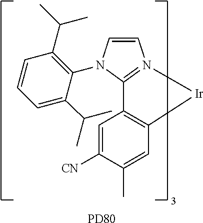

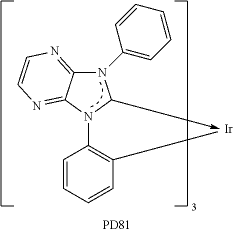

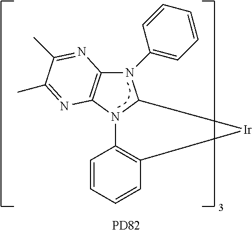

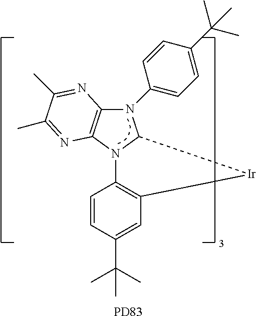

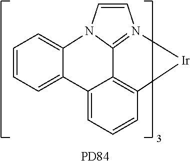

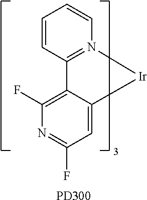

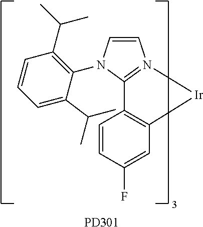

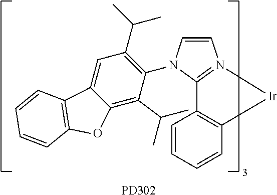

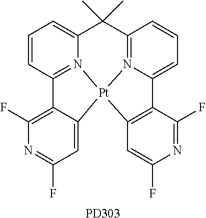

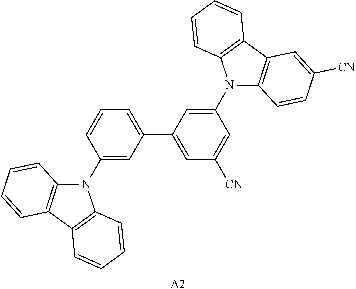 [SMILES: N#Cc1cc(-c2cccc(-n3c4ccccc4c4ccccc43)c2)cc(-n2c3ccccc3c3cc(C#N)ccc32)c1 ; "A2"]

Based on Table 2, it was identified whether Conditions 1, 2, 3, 4, 5-1, and 6-1 were satisfied in Combinations 1 to 10. The results thereof are shown in Tables 3 and 4.

TABLE 3

| Combination | | | Condi- | Condi- | Condi- | Condi- |
|---|---|---|---|---|---|---|
| No. | Host | Dopant | tion 1 | tion 2 | tion 3 | tion 4 |
| Combination 1 | A2 | PD79 | X | ◯ | X | ◯ |
| Combination 2 | A2 | PD80 | X | ◯ | X | ◯ |
| Combination 3 | A2 | PD81 | ◯ | ◯ | X | ◯ |
| Combination 4 | A2 | PD82 | X | N/A | X | N/A |
| Combination 5 | A2 | PD83 | X | N/A | X | N/A |
| Combination 6 | A2 | PD84 | X | X | X | X |
| Combination 7 | A2 | PD300 | ◯ | X | ◯ | X |
| Combination 8 | A2 | PD301 | X | X | X | X |
| Combination 9 | A2 | PD302 | X | X | X | X |
| Combination 10 | A2 | PD303 | ◯ | X | ◯ | X |

TABLE 4

| Combination | | | T1_{dopant} − | \| E_{red,host} − | \| E_{red,dopant} − | T1_{dopant} + | Condition | Condition |
|---|---|---|---|---|---|---|---|---|
| No. | Host | Dopant | 0.4 eV | E_{ox,dopant} \| | E_{ox,host} \| | 0.3 eV | 5-1 | 6-1 |
| Combination 1 | A2 | PD79 | 2.28 | 2.59 | 2.9 | 2.98 | ◯ | ◯ |
| Combination 2 | A2 | PD80 | 2.32 | 2.52 | 3 | 3.02 | ◯ | ◯ |
| Combination 3 | A2 | PD81 | 2.19 | 2.83 | 3.06 | 2.89 | ◯ | X |
| Combination 4 | A2 | PD82 | 2.28 | 2.62 | N/A | 2.98 | ◯ | N/A |
| Combination 5 | A2 | PD83 | 2.19 | 2.53 | N/A | 2.89 | ◯ | N/A |
| Combination 6 | A2 | PD84 | 2.46 | 2.61 | 2.44 | 3.16 | ◯ | X |
| Combination 7 | A2 | PD300 | 2.57 | 3.51 | 2.36 | 3.27 | X | X |
| Combination 8 | A2 | PD301 | 2.50 | 2.67 | 2.37 | 3.20 | ◯ | X |
| Combination 9 | A2 | PD302 | 2.41 | 2.45 | 2.35 | 3.11 | ◯ | X |
| Combination 10 | A2 | PD303 | 2.41 | 3.89 | 2.33 | 3.11 | X | X |

″O″ indicates that the combination satisfied the condition.
″X″ indicates that the combination did not satisfy the condition.
″N/A″ indicates that an evaluation could not be made because a measurement was not available.

### Example 1

As an anode, a glass substrate having an ITO electrode thereon was cut to a size of 50 millimeters (mm)×50 mm×0.5 mm. Then the glass substrate was sonicated in acetone iso-propyl alcohol and pure water for about 15 minutes in each solvent, and cleaned by exposure to ultraviolet rays and ozone for 30 minutes.

Compounds HT3 and HP-1 (in which a concentration of Compound HP-1 was 3 percent by weight (wt %)) were co-deposited on the anode to form a hole injection layer having a thickness of 100 Angstroms (Å). Compound HT3 was deposited on the hole injection layer to form a hole transport layer. mCP was deposited on the hole transport layer to form an electron blocking layer having a thickness of 100 Å, thereby forming a hole transport region having a thickness of 1,700 Å.

Compound A2 (as a host) and Compound PD79 (as a dopant) were co-deposited on the hole transport region at a weight ratio of 9:1, thereby forming an emission layer having a thickness of 400 Å.

Compound A4 was vacuum-deposited on the emission layer to form a hole blocking layer having a thickness of 100 Å. Compound ET17 and LiQ were co-deposited on the hole blocking layer at a weight ratio of 5:5 to form an electron transport layer having a thickness of 360 Å. LiQ was deposited on the electron transport layer to form an electron injection layer having a thickness of 5 Å. Aluminum (Al) was deposited on the electron injection layer to form a layer of aluminum having a thickness of 120 Å, thereby completing the manufacture of an organic light-emitting device.

### Examples 2 and 3 and Comparative Examples 1 to 3

Organic light-emitting devices were manufactured in substantially the same manner as in Example 1, except that the host and the dopant shown in Table 5 were used in the formation of an emission layer.

### Evaluation Example 2

Relative lifespan (T₉₅) characteristics of the organic light-emitting devices manufactured in Examples 1 to 3 and Comparative Examples 1 and 2 were measured by using a current voltmeter (Keithley 2400) and a luminance meter (Minolta Cs-1000A). The evaluation results are shown in Table 5. In Table 5, the relative lifespan (T₉₅) represents lifespan data evaluating a period taken for the luminance (at 500 nit) to reach 95% with respect to 100% of the initial luminance.

TABLE 5

| | | | Weight | Relative |
|---|---|---|---|---|
| | | | ratio of host | lifespan (T₉₅) |
| | Host | Dopant | to dopant | (percent, %) |
| Example 1 | A2 | PD79 | 9:1 | 231% |
| (Combination 1) | | | | |
| Example 2 | A2 | PD80 | 9:1 | 100% |
| (Combination 2) | | | | |
| Example 3 | A2 | PD81 | 9:1 | 77% |
| (Combination 3) | | | | |
| Comparative | A2 | PD84 | 9:1 | <1% |
| Example 1 | | | | |
| (Combination 6) | | | | |
| Comparative | A2 | PD301 | 9:1 | <1% |
| Example 2 | | | | |
| (Combination 8) | | | | |
| Comparative | A2 | PD302 | 9:1 | <1% |
| Example 3 | | | | |
| (Combination 9) | | | | |

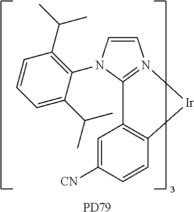

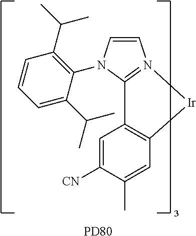

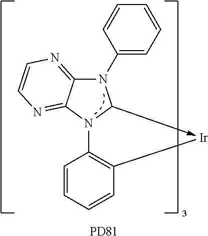

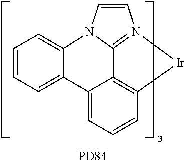

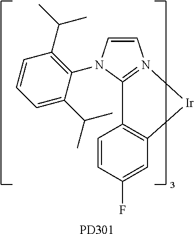

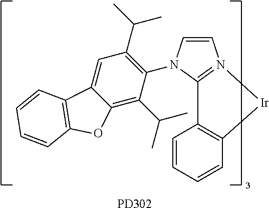

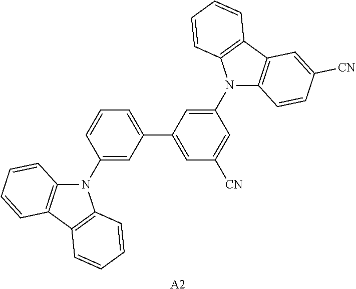 [SMILES: N#Cc1cc(-c2cccc(-n3c4ccccc4c4ccccc43)c2)cc(-n2c3ccccc3c3cc(C#N)ccc32)c1 ; "A2"]

Referring to the results of Table 5, it was found that the organic light-emitting device of Examples 1 to 3 have long lifespan characteristics, as compared with the organic light-emitting devices of Comparative Examples 1 to 3.

As apparent from the foregoing description, an organic light-emitting device, according to one or more embodiments, may include a host and a dopant satisfying the aforementioned conditions so as to have a long lifespan.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the present disclosure as defined by the following claims.

What is claimed is:

1. An organic light-emitting device comprising:
a first electrode;
a second electrode facing the first electrode; and
an organic layer disposed between the first electrode and the second electrode, wherein the organic layer includes an emission layer,
wherein the emission layer comprises a host and a dopant,
1) the dopant comprises a phosphorescent dopant, and
i) Conditions 1, 2, 3, and 4 are all satisfied;
ii) when Conditions 1 and 4 are satisfied and at least one of Conditions 2 and 3 is not satisfied, Condition 5-1 is satisfied;
iii) when at least one of Conditions 1 and 4 is not satisfied and Conditions 2 and 3 are satisfied, Condition 6-1 is satisfied; or
iv) when at least one of Conditions 1 and 4 is not satisfied and at least one of Conditions 2 and 3 is not satisfied, Conditions 5-1 and 6-1 are both satisfied, or
2) the dopant comprises a fluorescent dopant, and
i) Conditions 1, 2, 3, and 4 are all satisfied;
ii) when Conditions 1 and 4 are satisfied and at least one of Conditions 2 and 3 is not satisfied, Condition 5-2 is satisfied;
iii) when at least one of Conditions 1 and 4 is not satisfied and Conditions 2 and 3 are satisfied, Condition 6-2 is satisfied; or
iv) when at least one of Conditions 1 and 4 is not satisfied and at least one of Conditions 2 and 3 is not satisfied, Conditions 5-2 and 6-2 are both satisfied:
E*_{ox,dopant}≥E_{red,host} Condition 1
E*_{red,dopant}≤E_{ox,host} Condition 2
E_{ox,dopant}≥E*_{red,host} Condition 3
E_{red,dopant}≤E*_{ox,host} Condition 4
T1_{dopant}−0.4 eV<|E_{red,host}−E_{ox,dopant}|<T1_{dopant}+0.3 eV Condition 5-1
T1_{dopant}−0.4 eV<|E_{red,dopant}−E_{ox,host}|<T1_{dopant}+0.3 eV Condition 6-1
S1_{dopant}−0.4 eV<|E_{red,host}−E_{ox,dopant}|<S1_{dopant}+0.3 eV Condition 5-2
S1_{dopant}−0.4 eV<|E_{red,dopant}−E_{ox,host}|<S1_{dopant}+0.3 eV Condition 6-2
wherein, “E*_{ox,dopant}” represents an excited-state oxidation potential (eV) of the dopant,
“E*_{red,dopant}” represents an excited-state reduction potential (eV) of the dopant,
“E_{ox,dopant}” represents a ground-state oxidation potential (eV) of the dopant,
“E_{red,dopant}” represents a ground-state reduction potential (eV) of the dopant,
“E_{red,host}” represents an excited-state reduction potential (eV) of the host,
“E_{ox,host}” represents an excited-state oxidation potential (eV) of the host,
“E_{red,host}” represents a ground-state reduction potential (eV) of the host,
“E_{ox,host}” represents a ground-state oxidation potential (eV) of the host,
E*_{ox,dopant} is identical to E_{ox,dopant}−T1_{dopant},
E*_{red,dopant} is identical to E_{red,dopant}+T1_{dopant},
E*_{ox,host} is identical to E_{ox,host}−S1ₕₒₛₜ,
E*_{red,host} is identical to E_{red,host}+S1ₕₒₛₜ,
“T1_{dopant}” represents the lowest triplet energy level (eV) of the dopant,
“S1_{dopant}” represents the lowest singlet energy level (eV) of the dopant,
“S1ₕₒₛₜ” represents the lowest singlet energy level (eV) of the host,
E_{ox,dopant} and E_{ox,host} are measured by using cyclic voltammetry (CV),
E_{red,dopant} and E_{red,host} are measured by using differential pulse voltammetry,
T1_{dopant} and S1_{dopant} are calculated from a photoluminescence (PL) spectrum of the dopant in solution, and
S1ₕₒₛₜ is calculated from a PL spectrum of the host in solution,
wherein “eV” denotes “electron volts”.

2. The organic light-emitting device of claim 1, wherein
the dopant comprises the phosphorescent dopant,
Conditions 1 and 3 are not satisfied, and
Conditions 2, 4, 5-1, and 6-1 are satisfied.

3. The organic light-emitting device of claim 1, wherein
the dopant comprises the phosphorescent dopant,
Conditions 3 and 6-1 are not satisfied, and
Conditions 1, 2, 4, and 5-1 are satisfied.

4. The organic light-emitting device of claim 1, wherein
the host comprises i) at least one donor compound, ii) at least one acceptor compound, or iii) a combination of at least one donor compound and at least one acceptor compound,
wherein the acceptor compound comprises a compound including at least one electron withdrawing group,
wherein the electron withdrawing group is selected from:
—F, —CFH₂, —CF₂H, —CF₃, —CN, and —NO₂;
a C₁-C₆₀ alkyl group substituted with at least one selected from —F, —CFH₂, —CF₂H, —CF₃, —CN, and —NO₂;
a C₁-C₆₀ heteroaryl group and a monovalent non-aromatic condensed polycyclic heterocyclic group, each including *═N—*′ as a ring-forming moiety; and
a C₁-C₆₀ heteroaryl group and a monovalent non-aromatic condensed polycyclic heterocyclic group, each including *═N—*′ as a ring-forming moiety and each substituted with at least one selected from deuterium, —F, —CFH₂, —CF₂H, —CF₃, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, and a substituted or unsubstituted monovalent non-aromatic condensed heteropolycyclic group.

5. The organic light-emitting device of claim 4, wherein the acceptor compound comprises a compound represented by Formula A-1, a compound represented by Formula A-2, or any combination thereof:
Ar₁₁-(L₁₁)ₐ₁₁-Ar₁₂ Formula A-1 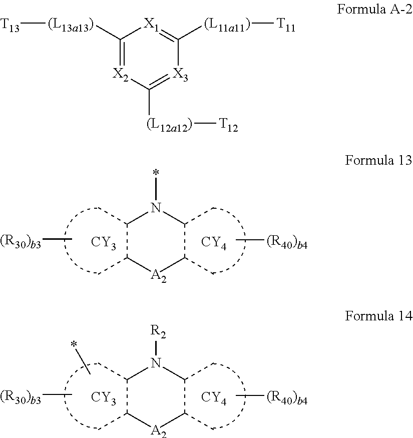
wherein, in Formulae A-1, A-2, 13, and 14,
Ar₁₁ and Ar₁₂ are each independently selected from groups represented by Formulae 13 and 14,
X₁ is N or C(T₁₄), X₂ is N or C(T₁₅), and X₃ is N or C(T₁₆), provided that at least one of X₁ to X₃ is N,
L₁₁ to L₁₃ are each independently selected from:
a single bond, a phenylene group, a pyridinylene group, a pyrimidinylene group, a pyrazinylene group, a pyridazinylene group, a triazinylene group, a naphthylene group, a fluorenylene group, a carbazolylene group, a dibenzofuranylene group, and a dibenzothiophenylene group; and
a phenylene group, a pyridinylene group, a pyrimidinylene group, a pyrazinylene group, a pyridazinylene group, a triazinylene group, a naphthylene group, a fluorenylene group, a carbazolylene group, a dibenzofuranylene group, and a dibenzothiophenylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, —CFH₂, a phenyl group, a phenyl group substituted with a cyano group, a naphthyl group, a pyridinyl group, a pyrimidinyl group, a pyrazinyl group, a pyridazinyl group, a triazinyl group, a fluorenyl group, a carbazolyl group, a dibenzofuranyl group, a dibenzothiophenyl group, and —Si(Q₁₁)(Q₁₂)(Q₁₃),
a11 to a13 are each independently an integer selected from 0 to 5; when a11 is 2 or greater, at least two L₁₁ groups are identical to or different from each other; when a12 is 2 or greater, at least two L₁₂ groups are identical to or different from each other; and when a13 is 2 or greater, at least two L₁₃ groups are identical to or different from each other,
CY₃ and CY₄ are each independently selected from a benzene group, a naphthalene group, a fluorene group, a carbazole group, a benzocarbazole group, an indolocarbazole group, a dibenzofuran group, and a dibenzothiophene group,
A₂ is selected from:
a single bond, a C₁-C₄ alkylene group, and a C₂-C₄ alkenylene group; and
a C₁-C₄ alkylene group and a C₂-C₄ alkenylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, a phenyl group, a naphthyl group, a pyridinyl group, a pyrimidinyl group, a pyrazinyl group, a pyridazinyl group, a triazinyl group, a fluorenyl group, a carbazolyl group, a dibenzofuranyl group, a dibenzothiophenyl group, and —Si(Q₂₁)(Q₂₂)(Q₂₃),
T₁₁ to T₁₆, R₂, R₃₀, and R₄₀ are each independently selected from hydrogen, deuterium, —F, —Cl, —Br, —I, a hydroxyl group, a cyano group (CN), a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, and —Si(Q₁)(Q₂)(Q₃),
b3 and b4 are each independently an integer selected from 0 to 10, and
at least one substituent of the substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₇-C₆₀ arylalkyl group, substituted C₁-C₆₀ heteroaryl group, substituted C₁-C₆₀ heteroaryloxy group, substituted C₁-C₆₀ heteroarylthio group, substituted C₂-C₆₀ heteroarylalkyl group, substituted monovalent non-aromatic condensed polycyclic group, and substituted monovalent non-aromatic condensed heteropolycyclic group is selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, and —Si(Q₃₁)(Q₃₂)(Q₃₃),
wherein Q₁ to Q₃, Q₁₁ to Q₁₃, Q₂₁ to Q₂₃, and Q₃₁ to Q₃₃ are each independently selected from hydrogen, deuterium, a C₁-C₆₀ alkyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

6. The organic light-emitting device of claim 5, wherein Ar₁₁ and Ar₁₂ are each independently selected from groups represented by Formulae 13-1 to 13-8 and 14-1 to 14-8: 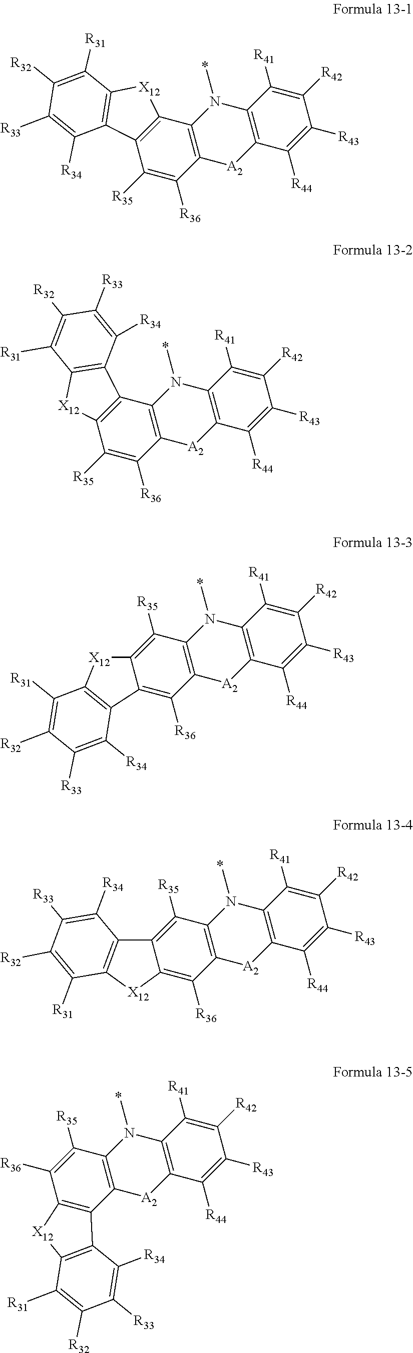 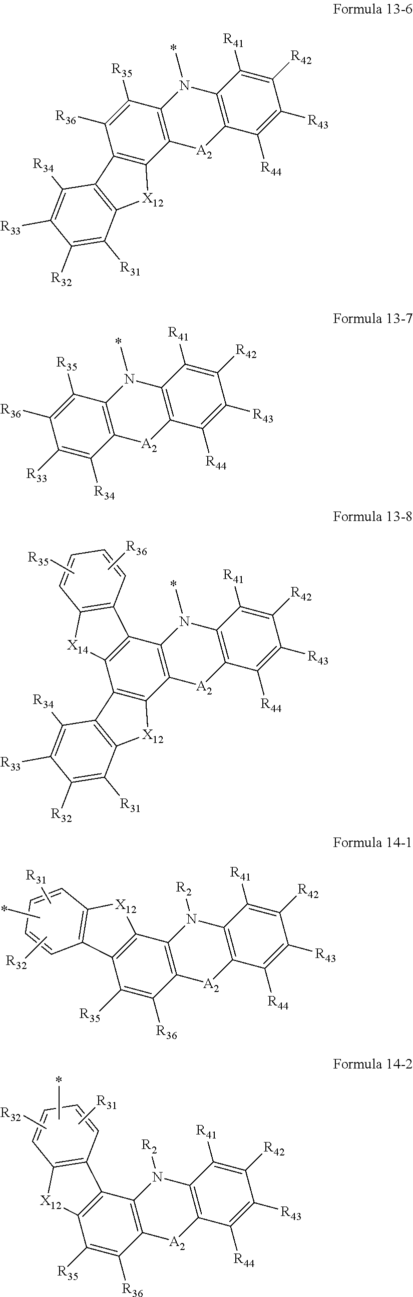 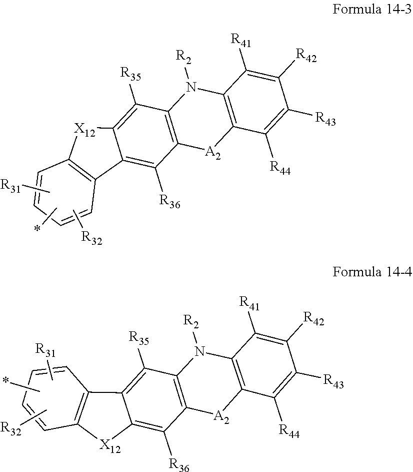 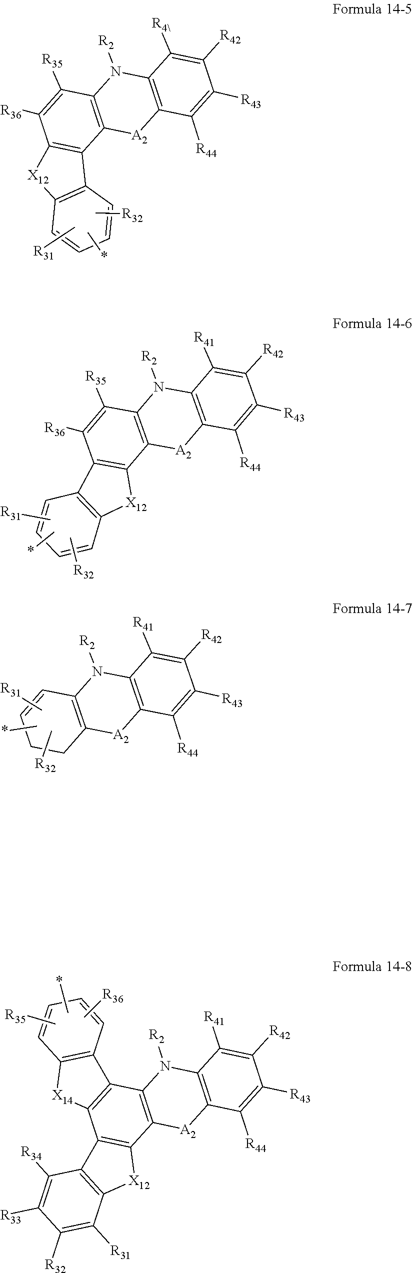
wherein, in Formulae 13-1 to 13-8 and 14-1 to 14-8,
X₁₂ and X₁₄ are each independently selected from C(R₃₇)(R₃₈), N(R₃₉), O, and S,
R₂ and A₂ are the same as those defined in claim 5,
R₃₁ to R₃₉ are each independently the same as R₃₀ defined in claim 5,
R₄₁ to R₄₄ are each independently the same as R₄₀ defined in claim 5, and
* indicates a binding site to an adjacent atom.

7. The organic light-emitting device of claim 5, wherein Ar₁₁ and Ar₁₂ are each independently selected from groups represented by Formulae 17-1 to 17-3: 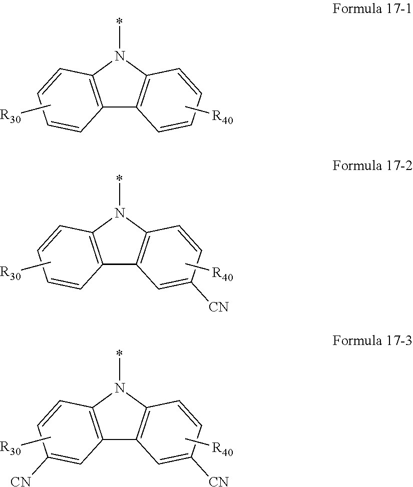
wherein, in Formulae 17-1 to 17-3,
R₃₀ and R₄₀ are each independently selected from:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, and —CFH₂;
a phenyl group, a pyridinyl group, a pyrimidinyl group, a pyrazinyl group, a pyridazinyl group, a triazinyl group, a naphthyl group, a fluorenyl group, a carbazolyl group, a dibenzofuranyl group, and a dibenzothiophenyl group;
a phenyl group, a pyridinyl group, a pyrimidinyl group, a pyrazinyl group, a pyridazinyl group, a triazinyl group, a naphthyl group, a fluorenyl group, a carbazolyl group, a dibenzofuranyl group, and a dibenzothiophenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, —CFH₂, a phenyl group, a pyridinyl group, a pyrimidinyl group, a pyrazinyl group, a pyridazinyl group, a triazinyl group, a naphthyl group, a fluorenyl group, a carbazolyl group, a dibenzofuranyl group, and a dibenzothiophenyl group; and
—Si(Q₁)(Q₂)(Q₃),
wherein Q₁ to Q₃ are each independently selected from hydrogen, a C₁-C₁₀ alkyl group, a C₁-C₁₀ alkoxy group, a phenyl group, and a naphthyl group.

8. The organic light-emitting device of claim 5, wherein L₁₁ to L₁₃ are each independently selected from groups represented by Formulae 3-1 to 3-56, provided that i) at least one L₁₁ in the number of a11, ii) at least one L₁₂ in the number of a12, and iii) at least one L₁₃ in the number of a13 are each independently selected from groups represented by Formulae 3-15 to 3-56: 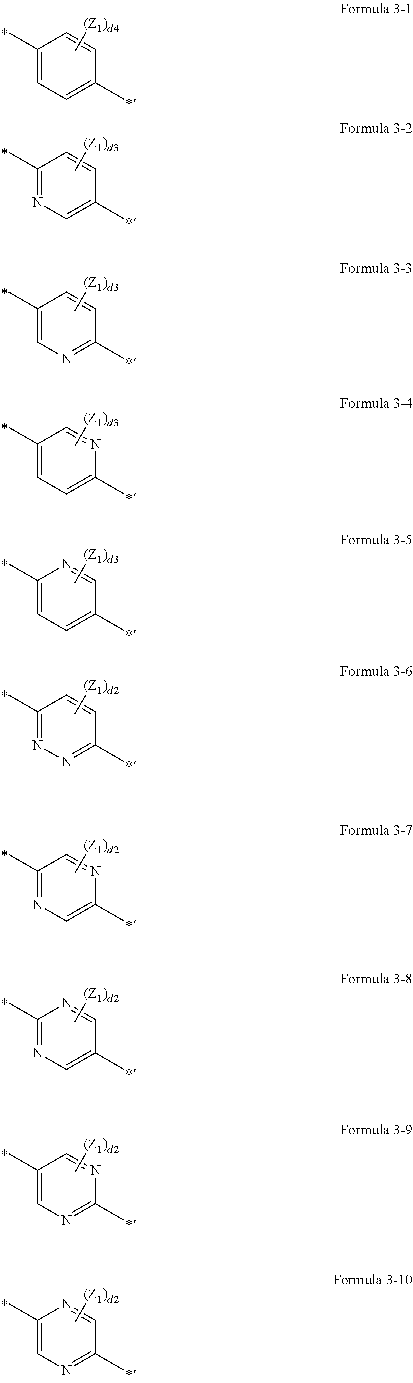 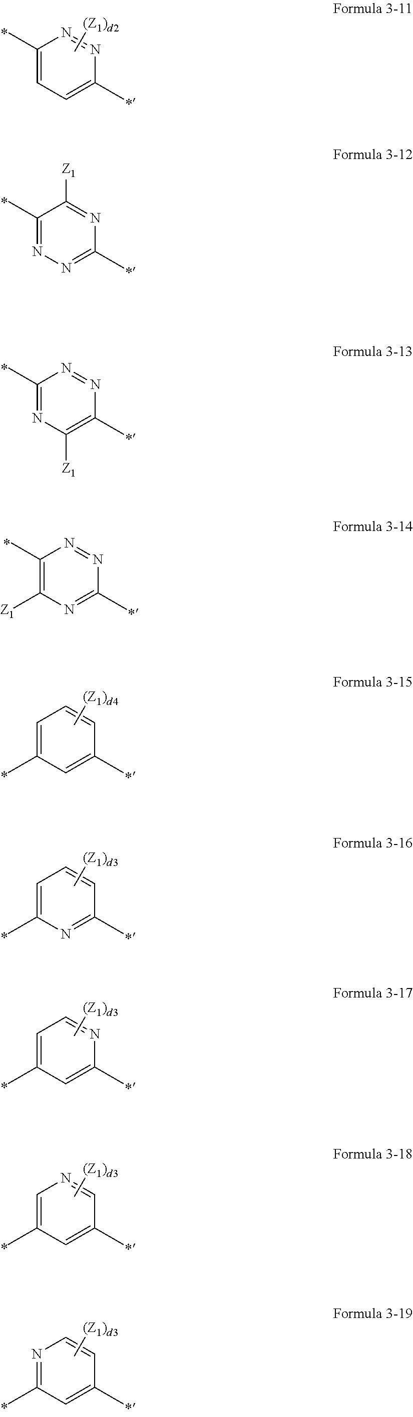 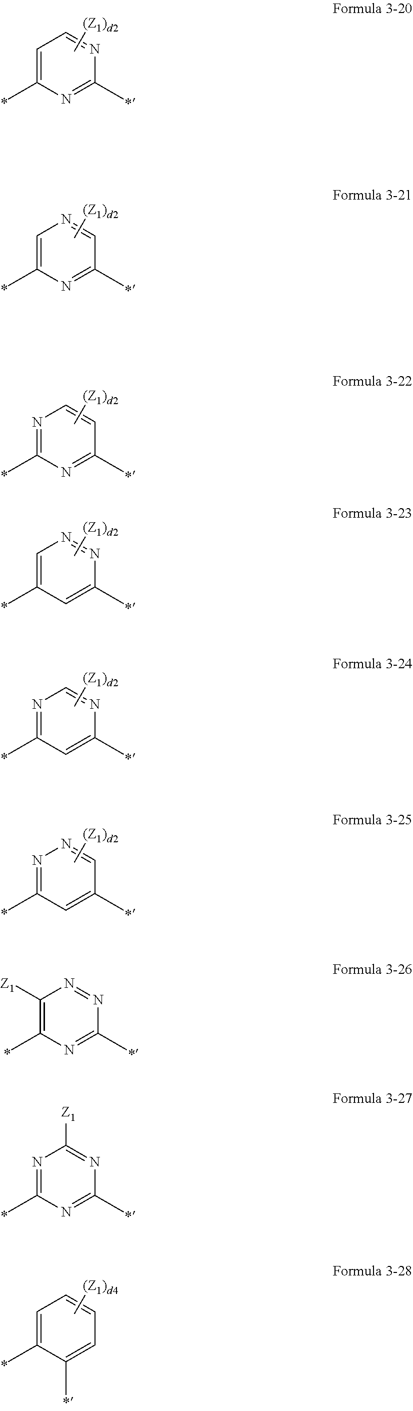 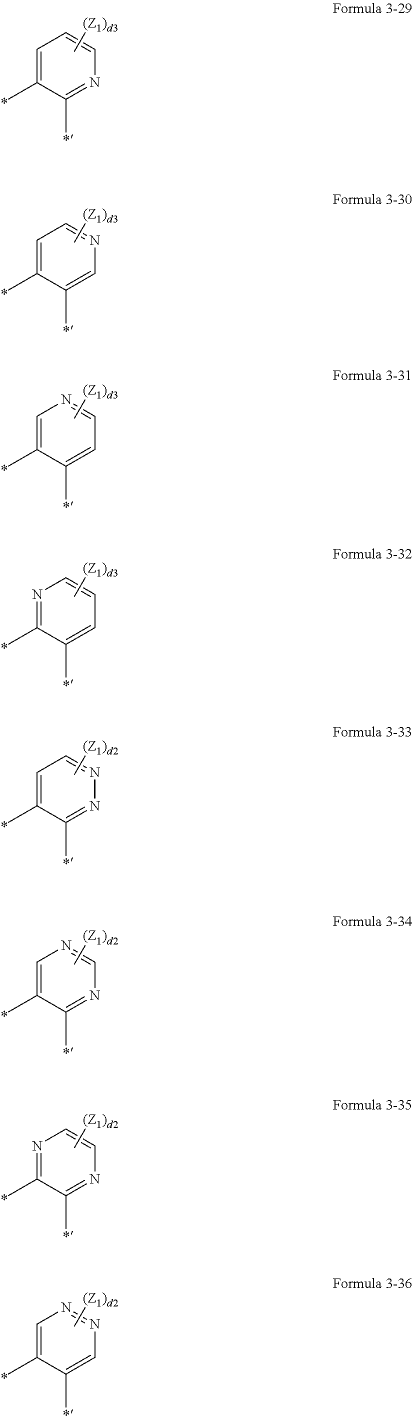 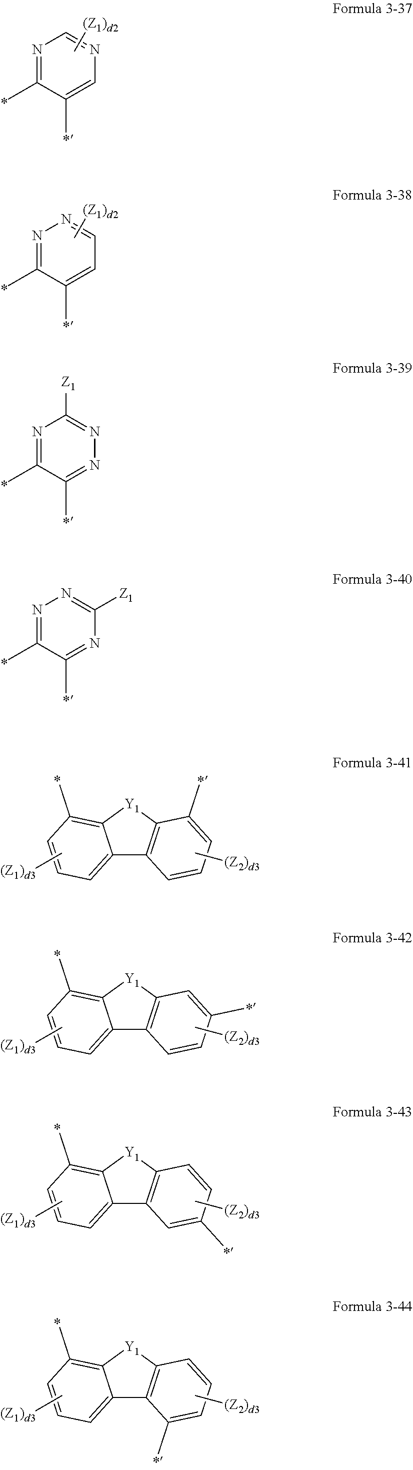 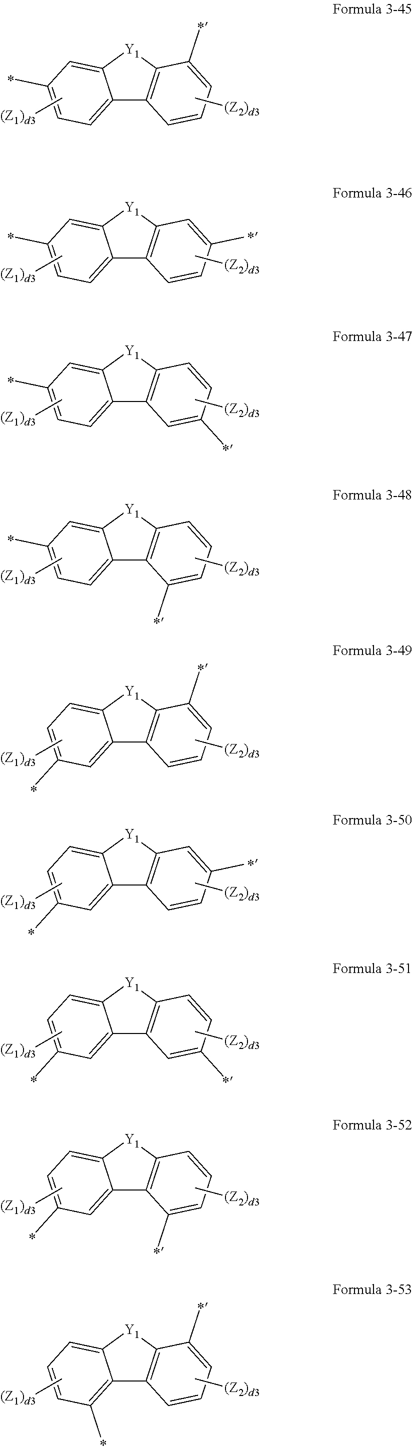 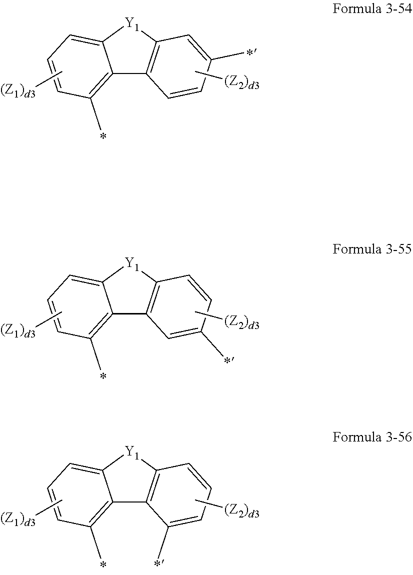
wherein, in Formulae 3-1 to 3-56,
Y₁ is selected from O, S, C(Z₃)(Z₄), and N(Z₅),
Z₁ to Z₅ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, —CFH₂, a phenyl group, a phenyl group substituted with a cyano group, a naphthyl group, a pyridinyl group, a pyrimidinyl group, a pyrazinyl group, a pyridazinyl group, a triazinyl group, a fluorenyl group, a carbazolyl group, a dibenzofuranyl group, a dibenzothiophenyl group, and —Si(Q₁₁)(Q₁₂)(Q₁₃),
wherein Q₁₁ to Q₁₃ are each independently selected from hydrogen, a C₁-C₁₀ alkyl group, a C₁-C₁₀ alkoxy group, a phenyl group, a naphthyl group, a pyridinyl group, a pyrimidinyl group, a pyrazinyl group, a pyridazinyl group, a triazinyl group, a fluorenyl group, a carbazolyl group, a dibenzofuranyl group, and a dibenzothiophenyl group,
d4 is an integer selected from 0 to 4,
d3 is an integer selected from 0 to 3,
d2 is an integer selected from 0 to 2, and
* and *′ each indicate a binding site to an adjacent atom.

9. The organic light-emitting device of claim 5, wherein groups represented by *-(L₁₁)ₐ₁₁-*′, *-(L₁₂)ₐ₁₂-*′, and *-(L₁₃)ₐ₁₃-*′ are selected from groups represented by Formulae 4-1 to 4-39: 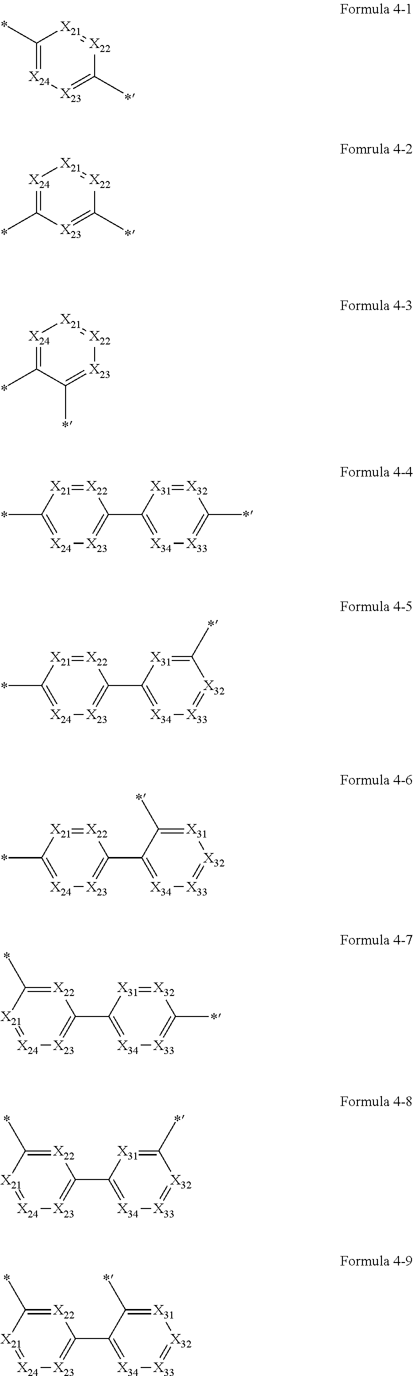 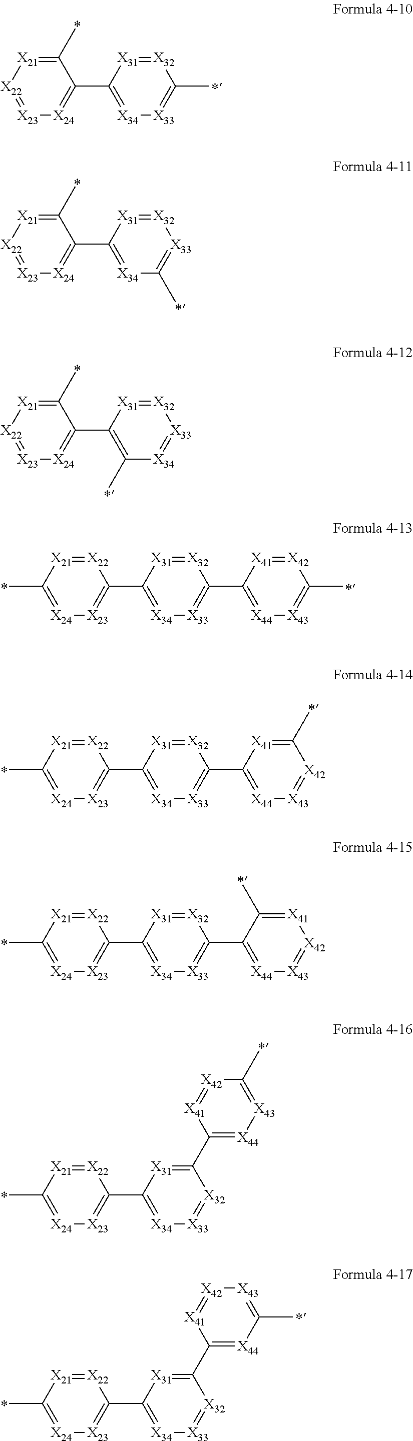 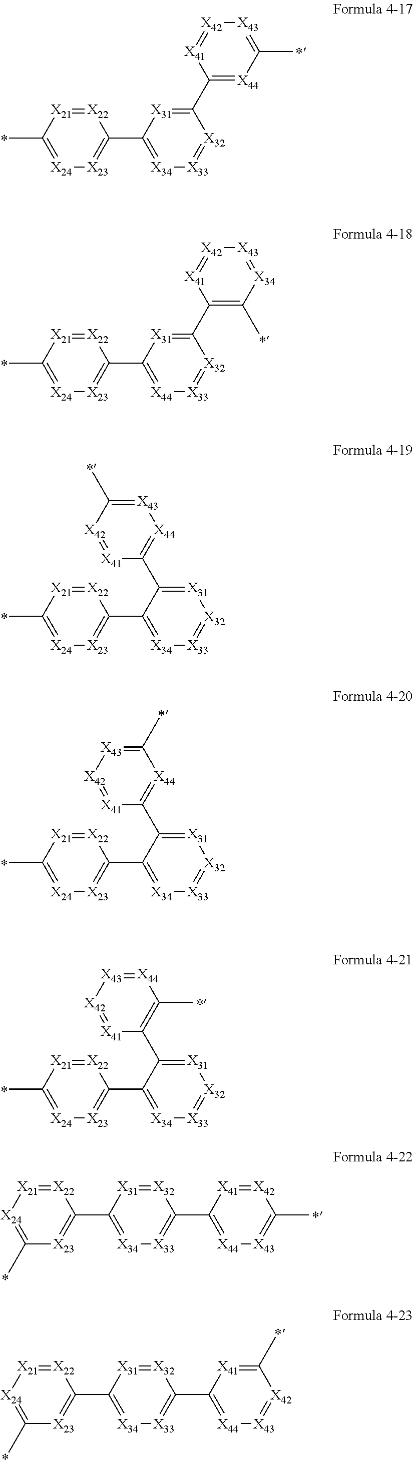 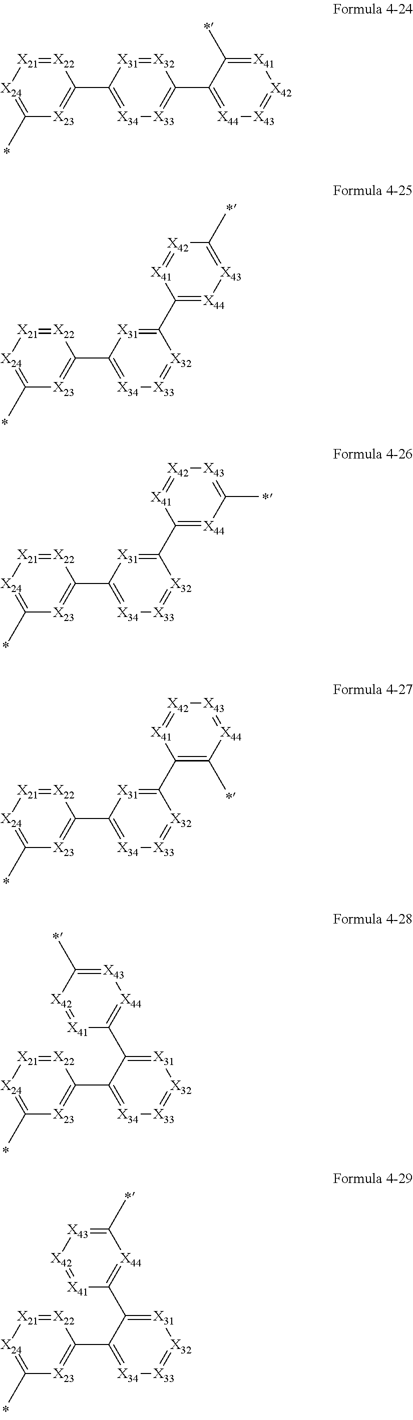 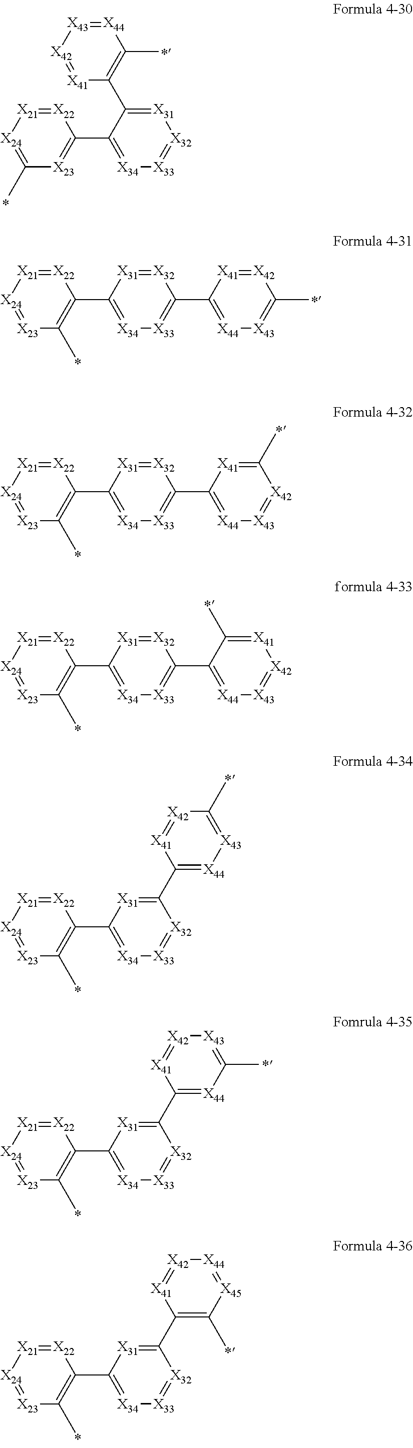 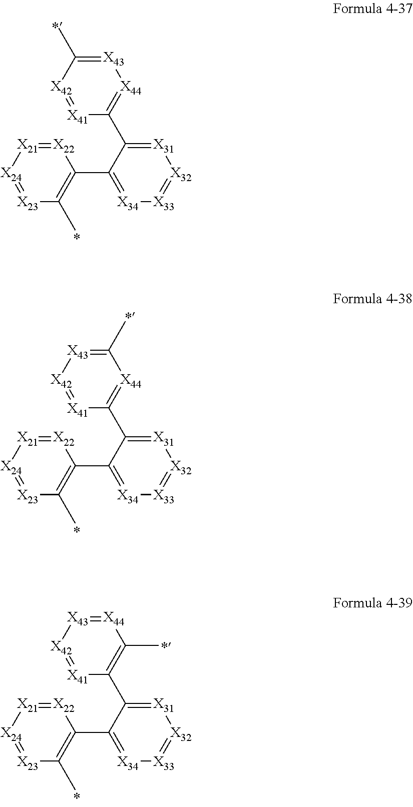
wherein, in Formulae 4-1 to 4-39,
X₂₁ is N or C(Z₂₁), X₂₂ is N or C(Z₂₂), X₂₃ is N or C(Z₂₃), X₂₄ is N or C(Z₂₄), X₃₁ is N or C(Z₃₁), X₃₂ is N or C(Z₃₂), X₃₃ is N or C(Z₃₃), X₃₄ is N or C(Z₃₄), X₄₁ is N or C(Z₄₁), X₄₂ is N or C(Z₄₂), X₄₃ is N or C(Z₄₃), and X₄₄ is N or C(Z₄₄), provided that at least one of X₂₁ to X₂₄ is not N, at least one of X₃₁ to X₃₄ is not N, and at least one of X₄₁ to X₄₄ is not N,
Z₂₁ to Z₂₄, Z₃₁ to Z₃₄, and Z₄₁ to Z₄₄ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, —CFH₂, a phenyl group, a phenyl group substituted with a cyano group, a naphthyl group, a pyridinyl group, a pyrimidinyl group, a pyrazinyl group, a pyridazinyl group, a triazinyl group, a fluorenyl group, a carbazolyl group, a dibenzofuranyl group, a dibenzothiophenyl group, and —Si(Q₁₁)(Q₁₂)(Q₁₃),
wherein Q₁₁ to Q₁₃ are each independently selected from hydrogen, a C₁-C₁₀ alkyl group, a C₁-C₁₀ alkoxy group, a phenyl group, a naphthyl group, a pyridinyl group, a pyrimidinyl group, a pyrazinyl group, a pyridazinyl group, a triazinyl group, a fluorenyl group, a carbazolyl group, a dibenzofuranyl group, and a dibenzothiophenyl group, and
* and *′ each indicate a binding site to an adjacent atom.

10. The organic light-emitting device of claim 5, wherein
i) the acceptor compound is represented by Formula A-1 in which Ar₁₁ and Ar₁₂ are each independently selected from groups represented by Formulae 17-1 to 17-3, and at least one of Ar₁₁ and Ar₁₂ is selected from groups represented by Formulae 17-2 and 17-3;
ii) the acceptor compound is represented by Formula A-1 in which L₁₁ is selected from groups represented by Formulae 3-15 and 3-28, and at least one L₁₁ in the number of a11 is selected from groups represented by Formulae 6-1 to 6-4; or
iii) the acceptor compound is represented by Formula A-2 in which X₁ to X₃ are each N: 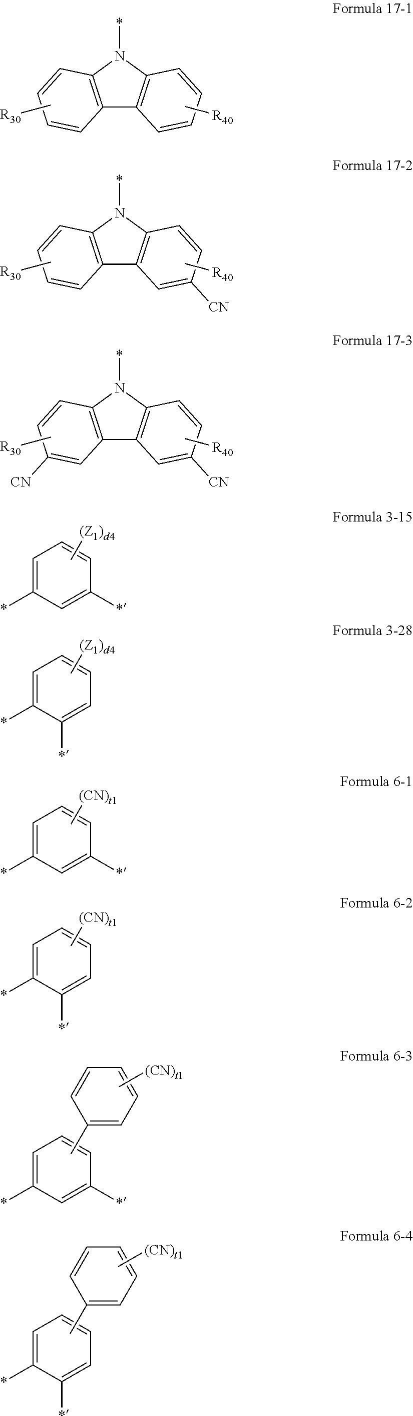
wherein, in Formula 17-1 to 17-3, 3-15, 3-28, and 6-1 to 6-4,
R₃₀ and R₄₀ are each independently selected from:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, and —CFH₂;
a phenyl group, a pyridinyl group, a pyrimidinyl group, a pyrazinyl group, a pyridazinyl group, a triazinyl group, a naphthyl group, a fluorenyl group, a carbazolyl group, a dibenzofuranyl group, and a dibenzothiophenyl group;
a phenyl group, a pyridinyl group, a pyrimidinyl group, a pyrazinyl group, a pyridazinyl group, a triazinyl group, a naphthyl group, a fluorenyl group, a carbazolyl group, a dibenzofuranyl group, and a dibenzothiophenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, —CFH₂, a phenyl group, a pyridinyl group, a pyrimidinyl group, a pyrazinyl group, a pyridazinyl group, a triazinyl group, a naphthyl group, a fluorenyl group, a carbazolyl group, a dibenzofuranyl group, and a dibenzothiophenyl group; and
—Si(Q₁)(Q₂)(Q₃),
Z₁ is selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, —CF₃, —CF₂H, —CFH₂, a phenyl group, a phenyl group substituted with a cyano group, a naphthyl group, a pyridinyl group, a pyrimidinyl group, a pyrazinyl group, a pyridazinyl group, a triazinyl group, a fluorenyl group, a carbazolyl group, a dibenzofuranyl group, a dibenzothiophenyl group, and —Si(Q₁₁)(Q₁₂)(Q₁₃),
d4 is an integer selected from 0 to 4,
t1 is 1 or 2,
wherein Q₁ to Q₃ and Q₁₁ to Q₁₃ are each independently selected from hydrogen, a C₁-C₁₀ alkyl group, a C₁-C₁₀ alkoxy group, a phenyl group, and a naphthyl group, and
* and *′ each indicate a binding site to an adjacent atom.

11. The organic light-emitting device of claim 1, wherein the host comprises at least one selected from Compounds A1 to A11:

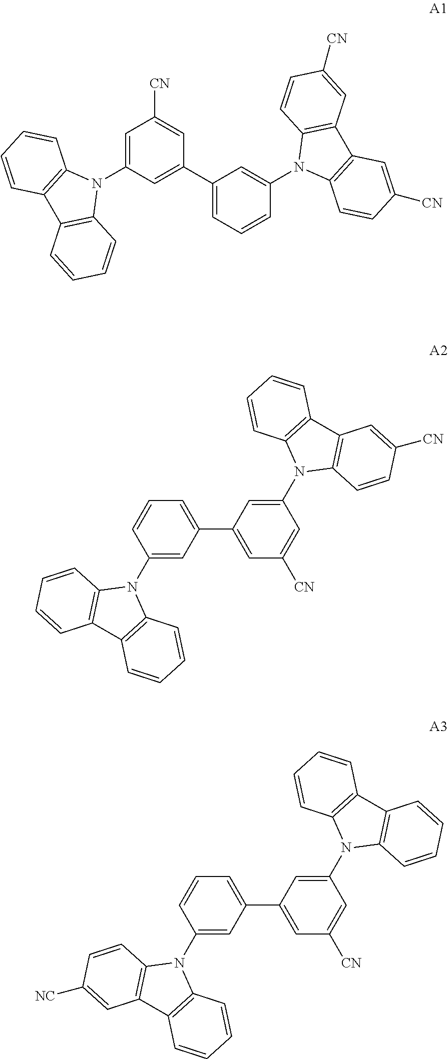 [SMILES: N#Cc1cc(-c2cccc(-n3c4ccc(C#N)cc4c4cc(C#N)ccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

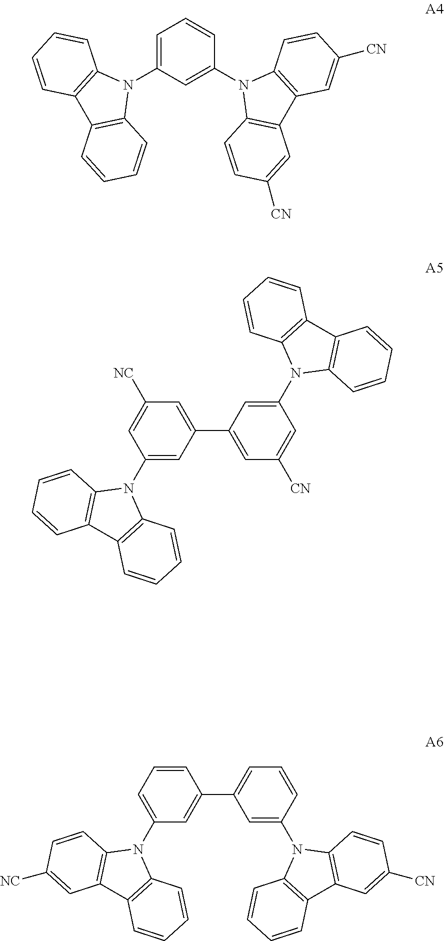 [SMILES: N#Cc1ccc2c(c1)c1cc(C#N)ccc1n2-c1cccc(-n2c3ccccc3c3ccccc32)c1 ; N#Cc1cc(-c2cc(C#N)cc(-n3c4ccccc4c4ccccc43)c2)cc(-n2c3ccccc3c3ccccc32)c1 ; N#Cc1ccc2c(c1)c1ccccc1n2-c1cccc(-c2cccc(-n3c4ccccc4c4cc(C#N)ccc43)c2)c1]

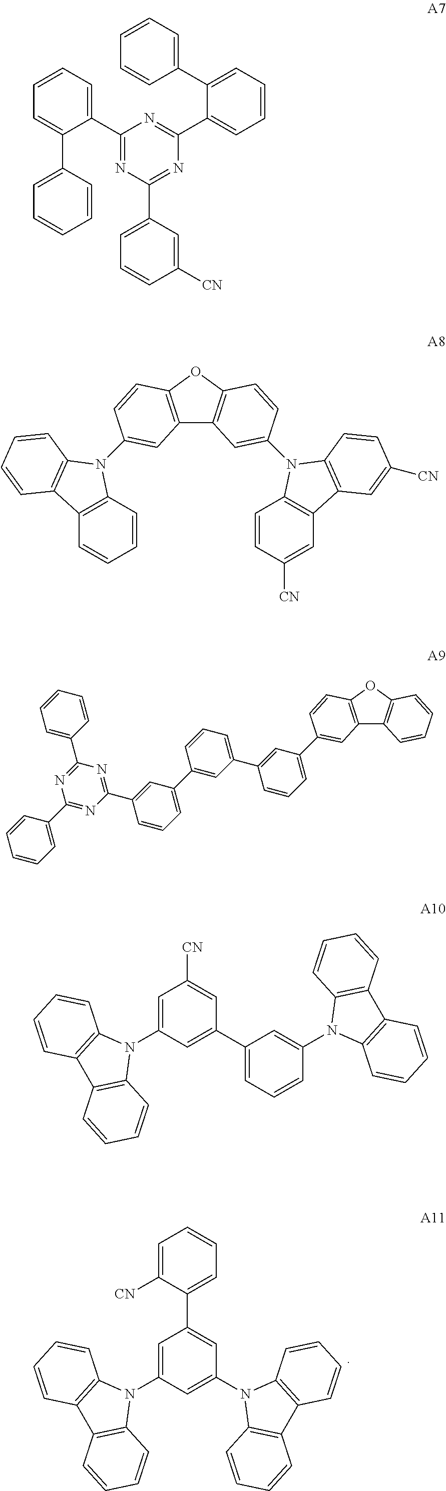

12. The organic light-emitting device of claim 1, wherein the dopant comprises the phosphorescent dopant.

13. The organic light-emitting device of claim 1, wherein the dopant comprises an organometallic compound represented by Formula 81:
M(L₈₁)ₙ₈₁(L₈₂)ₙ₈₂ Formula 81 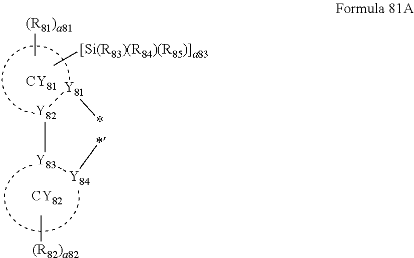
wherein, in Formulae 81 and 81A,
M is selected from iridium (Ir), platinum (Pt), osmium (Os), titanium (Ti), zirconium (Zr), hafnium (Hf), europium (Eu), terbium (Tb), thulium (Tm), and rhodium (Rh),
L₈₁ is a ligand represented by Formula 81A, n81 is an integer selected from 1 to 3; when n81 is 2 or greater, at least two L₈₁ groups are identical to or different from each other,
L₈₂ is an organic ligand, n82 is an integer selected from 0 to 4; when n82 is 2 or greater, at least two L₈₂ groups are identical to or different from each other,
Y₈₁ to Y₈₄ are each independently carbon (C) or nitrogen (N),
Y₈₁ and Y₈₂ are bound via a single bond or a double bond, Y₈₃ and Y₈₄ are bound via a single bond or a double bond,
CY₈₁ and CY₈₂ are each independently selected from a C₅-C₃₀ carbocyclic group and a C₁-C₃₀ heterocyclic group,
CY₈₁ and CY₈₂ are optionally and additionally bound via an organic linking group,
R₈₁ to R₈₅ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —Si(Q₈₁)(Q₈₂)(Q₈₃), —N(Q₈₄)(Q₈₅), —B(Q₈₆)(Q₈₇), and —P(═O)(Q₈₈)(Q₈₉),
a81 to a83 are each independently an integer selected from 0 to 5,
when a81 is 2 or greater, at least two R₈₁ groups are identical to or different from each other,
when a82 is 2 or greater, at least two R₈₂ groups are identical to or different from each other,
when a81 is 2 or greater, R₈₁ groups that are adjacent to each other are optionally bound to form a saturated or unsaturated ring,
when a82 is 2 or greater, R₈₂ groups that are adjacent to each other are optionally bound to form a saturated or unsaturated ring,
in Formula 81A, * and *′ each indicate a binding site to M in Formula 81, and
at least one substituent of the substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₇-C₆₀ arylalkyl group, substituted C₁-C₆₀ heteroaryl group, substituted C₁-C₆₀ heteroaryloxy group, substituted C₁-C₆₀ heteroarylthio group, substituted C₂-C₆₀ heteroarylalkyl group, substituted monovalent non-aromatic condensed polycyclic group, and substituted monovalent non-aromatic condensed heteropolycyclic group is selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, and —Si(Q₁)(Q₉₂)(Q₉₃),
wherein Q₈₁ to Q₈₉ and Q₉₁ to Q₉₃ are each independently selected from hydrogen, deuterium, a C₁-C₆₀ alkyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

14. The organic light-emitting device claim 13, wherein
Y₈₁ is N, Y₈₂ and Y₈₃ are each C, Y₈₄ is N or C, and
CY₈₁ and CY₈₂ are each independently selected from a cyclopentadiene group, a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicene group, a coronene group, an ovalene group, a pyrrole group, an isoindole group, an indole group, an indazole group, a pyrazole group, an imidazole group, a triazole group, an oxazole group, an isoxazole group, an oxadiazole group, a thiazole group, an isothiazole group, a thiadiazole group, a purine group, a furan group, a thiophene group, a pyridine group, a pyrimidine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, a benzofuran group, a benzothiophene group, an iso-benzothiazole group, a benzoxazole group, an isobenzoxazole group, a benzocarbazole group, a dibenzocarbazole group, an imidazopyridine group, an imidazopyrimidine group, a dibenzofuran group, a dibenzothiophene group, a dibenzothiophene sulfone group, a carbazole group, a dibenzosilole group, a 2,3-dihydro-1H-imidazole group, and a 2,3-dihydro-1H-imidazopyrazine group.

15. The organic light-emitting device claim 13, wherein, in Formula 81A,
Y₈₁, Y₈₃, and Y₈₄ are each C,
Y₈₂ is N,
CY₈₁ is selected from a) a condensed ring in which i) a 5-membered ring including at least one N as a ring-forming atom is condensed with ii) a 6-membered ring selected from a benzene group, a pyridine group, a pyrazine group, a pyrimidine group, and a pyridazine group; and b) a 5-membered ring including at least one N as a ring-forming atom, and
CY₈₂ is selected from a benzene group, a naphthalene group, a fluorene group, a dibenzofuran group, a dibenzothiophene group, a pyridine group, a pyrimidine group, a quinoline group, and an isoquinoline group.

16. The organic light-emitting device claim 13, wherein R₈₁ and R₈₂ are each independently selected from:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, and a C₁-C₂₀ alkoxy group;
a C₁-C₂₀ alkyl group and a C₁-C₂₀ alkoxy group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group; and
—B(Q₈₆)(Q₈₇) and —P(═O)(Q₈₈)(Q₈₉),
wherein Q₈₆ to Q₈₉ are each independently selected from
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, and —CD₂CDH₂;
an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group; and
an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a phenyl group, and a naphthyl group, each substituted with at least one selected from deuterium, a C₁-C₁₀ alkyl group, and a phenyl group.

17. The organic light-emitting device claim 13, wherein, in Formula 81A, at least one R₈₁ in the number of a81, at least one R₈₂ in the number of a82, or any combination thereof is a cyano group.

18. The organic light-emitting device claim 13, wherein, in Formula 81, L₈₁ is selected from ligands represented by Formulae 81A-1 to 81A-8: 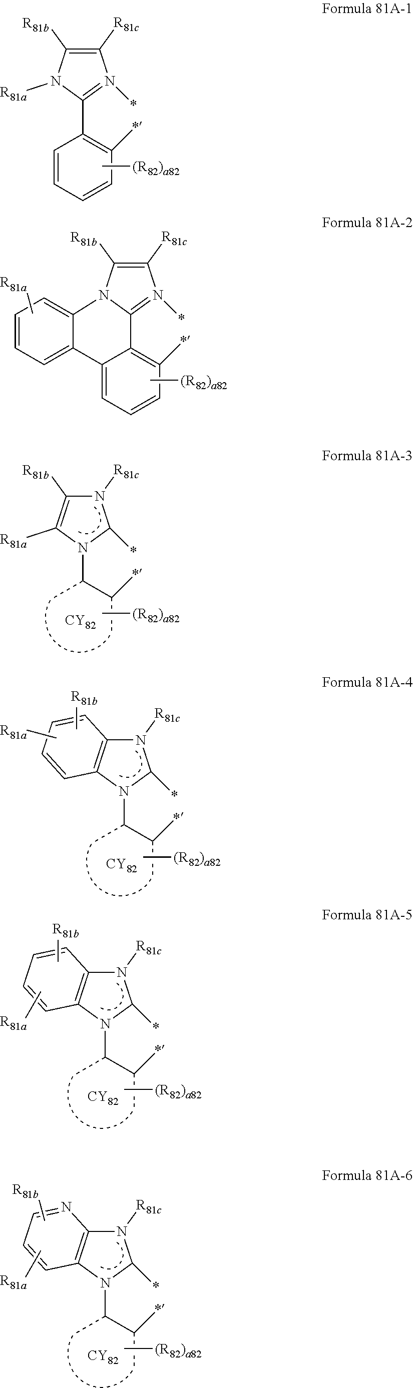 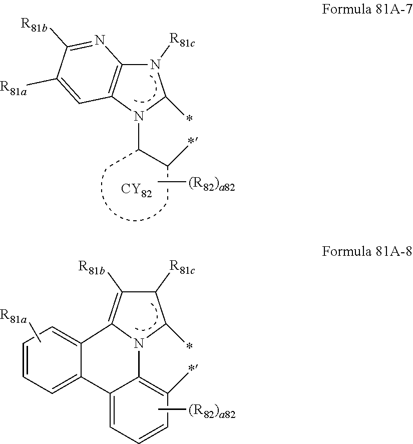
wherein, in Formulae 81A-1 to 81A-8,
CY₈₂, R₈₂, a82, *, and *′ are the same as those defined in claim 13, and
R₈₁ₐ, R_{81b}, and R_{81c} are each the same as R₈₁ as defined in claim 13.

19. The organic light-emitting device of claim 18, wherein, in Formulae 81A-1 to 81A-8, CY₈₂ is selected from a benzene group, a naphthalene group, a fluorene group, a dibenzofuran group, a dibenzothiophene group, a pyridine group, a pyrimidine group, a quinoline group, and an isoquinoline group.

20. The organic light-emitting device of claim 18, wherein, in Formulae 81A-1 to 81A-8, at least one of R₈₁ₐ, R_{81b}, R_{81c}, and R₈₂ in the number of a82 is each a cyano group.

21. The organic light-emitting device of claim 1, wherein, the dopant is selected from following compounds: [chemical structure]
